(19) United States
(12) Patent Application Publication
(10) Pub. No.: US 2007/0020479 A1
(43) Pub. Date: Jan. 25, 2007

(54) Luminescent-polymer composition

(76) Inventors: Yasunori Uetani, Tsukuba-shi (JP); Akira Kamabuchi, Ashiya-shi (JP); Satoshi Kobayashi, Tsukuba-shi (JP); Hirotoshi Nakanishi, Mishima-gun (JP)

Correspondence Address: SUGHRUE MION, PLLC, 2100 PENNSYLVANIA AVENUE, N.W., SUITE 800, WASHINGTON, DC, 20037, US

(21) Appl. No.: 10/556,463

(22) PCT Filed: May 11, 2004
(86) PCT No.: PCT/JP04/06598

§ 371 Date: Nov. 10, 2005

(30) Foreign Application Priority Data
May 12, 2003 (JP) 2003132664
Nov. 28, 2003 (JP) 2003399143
Mar. 31, 2004 (JP) 2004104335

(51) Int. Cl. H01L 51/54; C09K 11/06; H05B 33/14

(52) U.S. Cl. 428/690; 428/917; 313/504; 313/506; 257/40; 257/E51.027; 252/301.35; 252/500

(57) ABSTRACT

A light-emitting polymer composition comprising a light-emitting polymer and an ion pair, wherein the ion pair has a negative ion of a specific structure in which one group 13 atom and is bonding to an aryl group having an electron-withdrawing group, or a heterocyclic group having an electron-withdrawing group, directly or through a connecting group; or two or more group 13 atoms, and all the atoms are respectively bonding to an aryl group having an electron-withdrawing group, or a heterocyclic group having an electron-withdrawing group, directly or through a connecting group.

### TECHNICAL FIELD

The present invention relates to a light-emitting polymer composition, a light-emitting polymer solution composition, and a polymer light-emitting device (polymer LED) using thereof.

### BACKGROUND TECHNOLOGY

Unlike a low molecular weight material, a high molecular weight light-emitting material (light-emitting polymer) is soluble in a solvent, can form a light emitting layer of a light-emitting device by a coating method, and thus coincide with the demand of large area formation of a device. For this reason, in recent-years, various polymer light-emitting materials are proposed (for example, Advanced Materials Vol. 12 1737-1750 (2000)).

Meanwhile, it is desired for a light-emitting device to have long-life, that is, small deterioration of luminance by driving.

However, when a light-emitting polymer is used as a material for a light emitting layer of light-emitting device, the life-time of the device has been not yet satisfactory.

### DISCLOSURE OF THE INVENTION

The object of the present invention is to provide a composition which can give a long-life light-emitting device, when used for a light emitting layer of light-emitting device.

As the result of intensive studies in order to solve the above problems, the present inventors found a composition comprising a light-emitting polymer, and an ion pair which contains, as the negative ion, a group 13 atom connecting with an aryl group having an electron-withdrawing group, or a monovalent heterocyclic group having an electron-withdrawing group directly or through a connecting group; or contains two or more group 13 atoms, all of the atoms, each respectively being connected with an aryl group having an electron-withdrawing group, or a monovalent heterocyclic group having an electron-withdrawing group directly or through a connecting group; and found that when said composition is used as a material for light emitting device, the life-time of said device become long, and reached to the present invention.

That is, the present invention provides a light-emitting polymer composition containing a light-emitting polymer and an ion pair, and the negative ion of the ion pair is represented by the below formula (1a), (1b), (2), or (3). 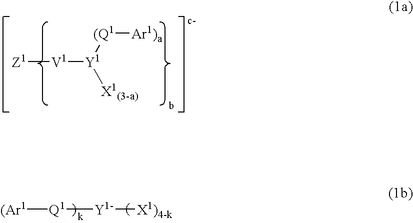
(wherein, Y¹ represents a group 13 atom; Ar¹ represents an aryl group having an electron-withdrawing group, or a monovalent heterocyclic group having an electron-withdrawing group; Q¹ represents an oxygen atom or a direct bond; X¹ represent a halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, substituted silyloxy group, substituted silylthio group, substituted silylamino group, substituted amino group, amide group, acid imide group, acyloxy group, monovalent heterocyclic group, heteroaryloxy group, heteroarylthio group, cyano group, or nitro group; a represents an integer of 1-3, k represents an integer of 1-4, V¹ represents a group 16 atom, divalent aliphatic hydrocarbon group, divalent aromatic hydrocarbon group, bidentate heterocyclic group, —C≡N—, —N═N═N—, or a direct bond; b represents an integer of 2-6; and Z¹ represents -M′(=O)p- (wherein, M′ represents an atom of group 3, group 4, group 5, group 6, group 7, group 8, group 9, group 10, group 11, group 12, group 13, group 14, group 15, group 16, or group 17; and p represents an integer of 0-2), or Z¹ represents a b-valent aliphatic hydrocarbon group, a b-valent aromatic hydrocarbon group, a bidentate heterocyclic group, —C≡N—, —N═N═N—, —NH—, —NH₂—, —OH—, or a direct bond. However, when b=2, Z¹ is —C≡N—, —N═N═N—, —NH—, —NH₂—, or —OH—; Z¹ and V¹ are different from each other, and when Q¹ and Ar¹ exist in plural, they may be the same or different from each other; a plurality of V¹ may be the same or different; and c represents an integer of 1-6), 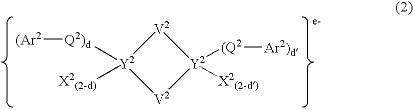
(wherein, Y² represents a group 13 atom; Ar² represents an aryl group having an electron-withdrawing group, or a monovalent heterocyclic group having an electron-withdrawing group; Q² represents an oxygen atom or a direct bond; X² represent a halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, substituted silyl oxy group, substituted silylthio group, substituted silylamino group, substituted amino group, amide group, acid imide group, acyloxy group, monovalent heterocyclic group, heteroaryloxy group, heteroarylthio group, cyano group, or nitro group; d and d′ each independently represent 1 or 2; V² represents a group 16 atom, divalent aliphatic hydrocarbon group, divalent aromatic hydrocarbon group, bidentate heterocyclic group, —C≡N— or —N═N—; a plurality of Y², Ar², Q² and V² may be the same or different; when X² exists in plural, they may be the same or different; and e represents an integer of 1-6), 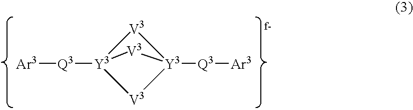
(wherein, Y³ represents a group 13 atom; Ar³ represents an aryl group having an electron-withdrawing group, or a monovalent heterocyclic group having an electron-withdrawing group; Q³ represents an oxygen atom or a direct bond; V³ represents a group 16 atom, divalent aliphatic hydrocarbon group, divalent aromatic hydrocarbon group, bidentate heterocyclic group, —C ≡N—, or —N═N—; a plurality of Y³, Ar³, Q³ and V³ espectively may be the same or different; and f represents an integer of 1-6).

In addition to the above light-emitting polymer composition, the present invention relates to a light-emitting polymer solution composition which further contains a solvent.

### BEST MODE FOR CARRYING OUT THE INVENTION

As for the ion pair used for the composition of the present invention, the negative ion is represented by the above formula (1a), (1b), (2), or (3).

Y¹ in formulas (1 a) and (1b) represents a group 13 atom, preferably, boron, aluminum and gallium, and more preferably, boron.

Ar¹ in formulas (1 a) and (1b) represents an aryl group having an electron-withdrawing group, or a monovalent heterocyclic group having an electron-withdrawing group.

The electron-withdrawing group means an atom or atomic group which withdraw electron by resonance effect or inductive effect, and examples thereof include a halogen atom, nitro group, nitroso group, cyano group, acyl group, carboxyl group, alkyloxy carbonyl group, aryloxy carbonyl group, arylalkyloxy carbonyl group, heteroaryloxy carbonyl group, perfluoroalkyl group, etc.

In the electron-withdrawing group, as the halogen atoms, a fluorine atom, a chlorine atom, a bromine atom, and an iodine atom are exemplified, and a fluorine atom is preferable.

Acyl group has usually about 2 to 20 carbon atoms, and concrete examples thereof include acetyl group, propionyl group, butyryl group, isobutyryl group, pivaloyl group, benzoyl group, the trifluoroacetyl group, pentafluorobenzoyl group, etc.

Alkyloxy carbonyl group has usually about 2 to 20 carbon atoms, and concrete examples thereof include methoxycarbonyl group, ethoxycarbonyl group, propyloxycarbonyl group, i-propyloxycarbonyl group, butoxycarbonyl group, i-butoxy carbonyl group, t-butoxycarbonyl group, pentyloxycarbonyl group, hexyloxycarbonyl group, cyclohexyloxycarbonyl group, heptyloxycarbonyl group, octyloxycarbonyl group, 2-ethyl hexyloxycarbonyl group, nonyloxycarbonyl group, decyloxy carbonyl group, 3,7-dimethyloctyloxycarbonyl group, lauryl oxycarbonyl group, trifluoromethoxycarbonyl group, pentafluoroethoxycarbonyl group, perfluorobutoxycarbonyl group, perfluorohexyloxycarbonyl group, perfluorooctyloxy carbonyl group, etc.

Aryloxy carbonyl group has usually about 7 to 60 carbon atoms, and concrete examples thereof include a phenoxycarbonyl group, C₁-C₁₂ alkyloxyphenoxycarbonyl group, C₁-C₁₂ alkylphenoxy carbonyl group, 1-naphtyloxycarbonyl group, 2-naphtyloxy carbonyl group, pentafluorophenyloxycarbonyl group, etc.

Arylalkyloxycarbonyl group has usually about 8 to 60 carbon atoms, and concrete examples thereof include phenyl-C₁-C₁₂ alkyloxycarbonyl group, C₁-C₁₂ alkyloxyphenyl-C₁-C₁₂ alkyloxy carbonyl group, C₁-C₁₂ alkylphenyl-C₁-C₁₂ alkyloxycarbonyl group, 1-naphtyl-C₁-C₁₂ alkyloxycarbonyl group, 2-naphtyl-C₁-C₁₂ alkyloxy carbonyl group, etc.

Heteroaryloxycarbonyl group (a group represented by Q⁴-O(C═O)— and Q⁴ represent a monovalent heterocyclic group) has usually about 2 to 60 carbon atoms, and concrete examples thereof include thienyloxy carbonyl group, C₁-C₁₂ alkylthienyl oxy carbonyl group, pyroryloxycarbonyl group, furyloxy carbonyl group, pyridyloxycarbonyl group, C₁-C₁₂ alkylpyridyl oxycarbonyl group, imidazolyloxycarbonyl group, pyrazolyloxy carbonyl group, triazolyloxycarbonyl group, oxazolyloxy carbonyl group, thiazoleoxycarbonyl group, thiadiazoleoxy carbonyl group, etc.

Perfluoroalkyl group means a linear, branched or cyclic alkyl group in which all the hydrogen atoms on the alkyl group are replaced by fluorines, and has usually about 1 to 20 carbon atoms. Concrete examples thereof include trifluoromethyl group, perfluoroethyl group, perfluoropropyl group, hepta fluoro-i-propyl group, perfluorobutyl group, trifluoro-i-butyl group, 1,1-bistrifluoro methyl-2,2,2-trifluoroethyl group, perfluoropentyl group, perfluorohexyl group, perfluorocyclohexyl group, perfluoro heptyl group, perfluorooctyl group, perfluorononyl group, perfluorodecyl group, perfluoro lauryl group, etc.

Next, in Ar¹ of formula (1a) and (1b), the aryl group having an electron-withdrawing group, the monovalent heterocyclic group having an electron-withdrawing group, an aryloxy group having an electron-withdrawing group, and a monovalent hetero aryloxy group having an electron-withdrawing group will be explained.

Aryl group having an electron-withdrawing group has usually about 6 to 60 carbon atoms, and concrete examples thereof include a phenyl group, C₁-C₁₂ alkyloxy phenyl group (C₁-C₁₂ shows the number of carbon atoms 1-12. hereafter the same), C₁-C₁₂ alkylphenyl group, 1-naphtyl group, 2-naphtyl group, etc., which are substituted with one or more of the above electron-withdrawing groups.

Monovalent heterocyclic group having an electron-withdrawing group has usually about 2 to 60 carbon atoms, and concrete examples thereof include thienyl group, C₁-C₁₂ alkylthienyl group, pyroryl group, furyl group, pyridyl group, C₁-C₁₂ alkylpyridyl group, imidazolyl group, pyrazolyl group, triazolyl group, oxazolyl group, thiazole group, thiadiazole group, etc., which are substituted with one or more of the above electron-withdrawing groups.

Concrete examples of Ar¹ include the following groups (I)-(V).
(I) Aryl Group Having an Electron-Withdrawing Group: 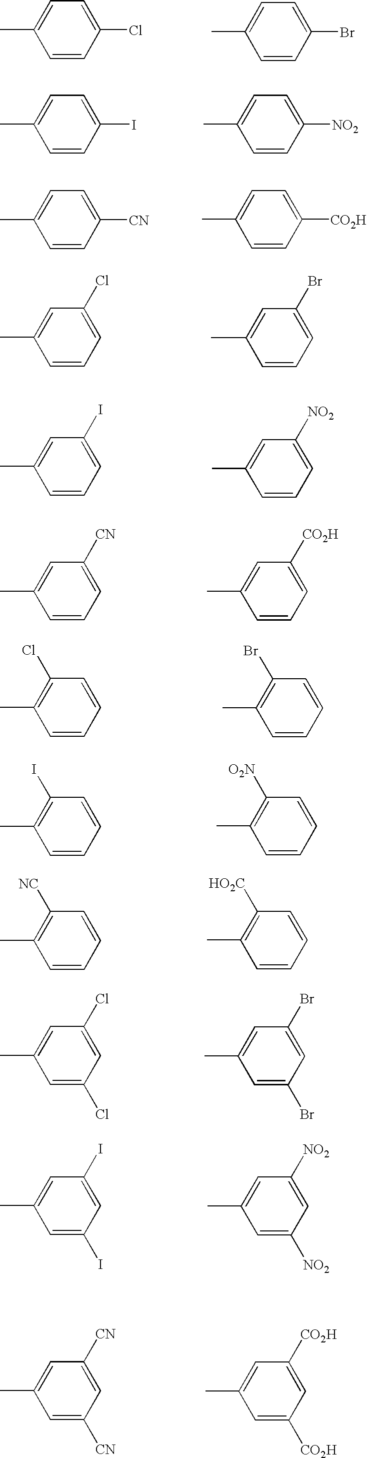 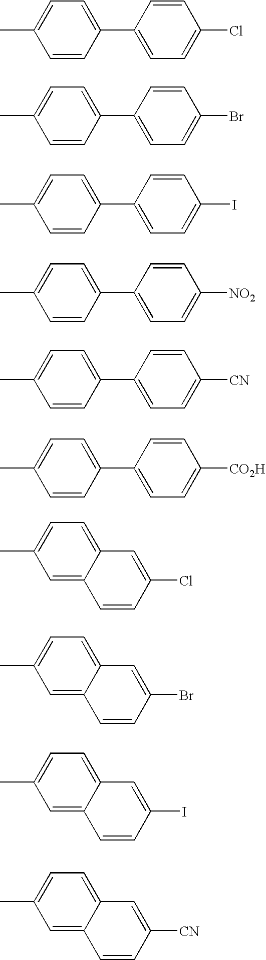
(II) Monovalent Heterocyclic Group Having an Electron-Withdrawing Group: 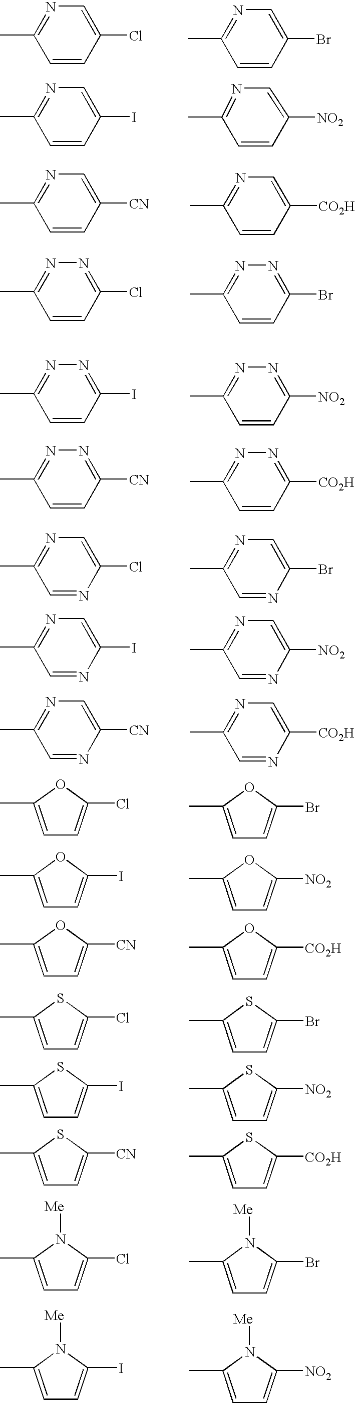 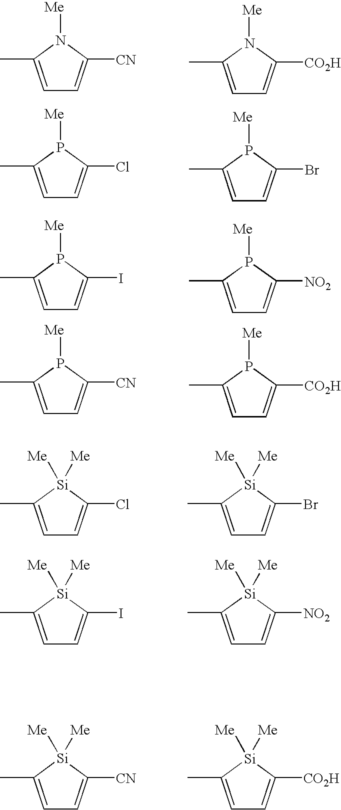
(III) Aryl Group Having a Fluorine Atom or Trifluoromethyl Group as the Electron-Withdrawing Group: 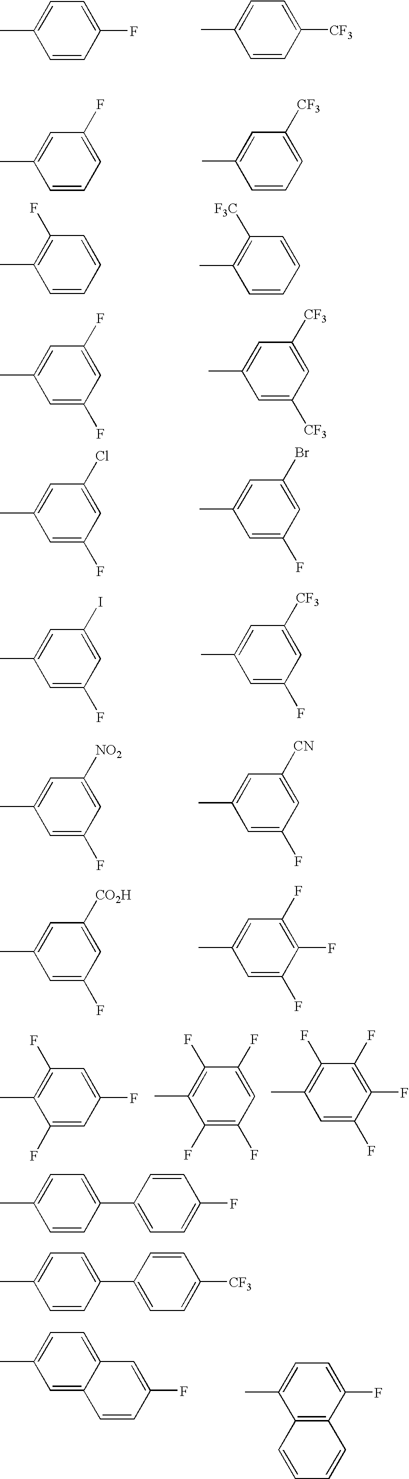 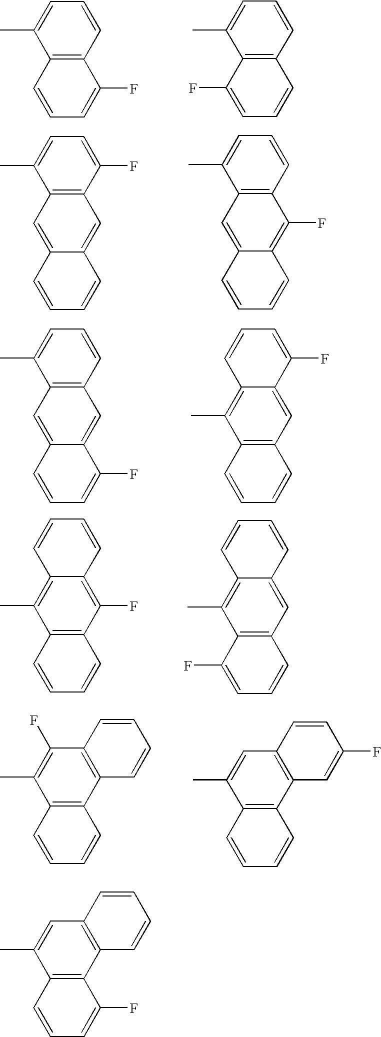
(IV) Monovalent Heterocyclic Group Having a Fluorine Atom or Trifluoromethyl Group as the Electron-Withdrawing Group: 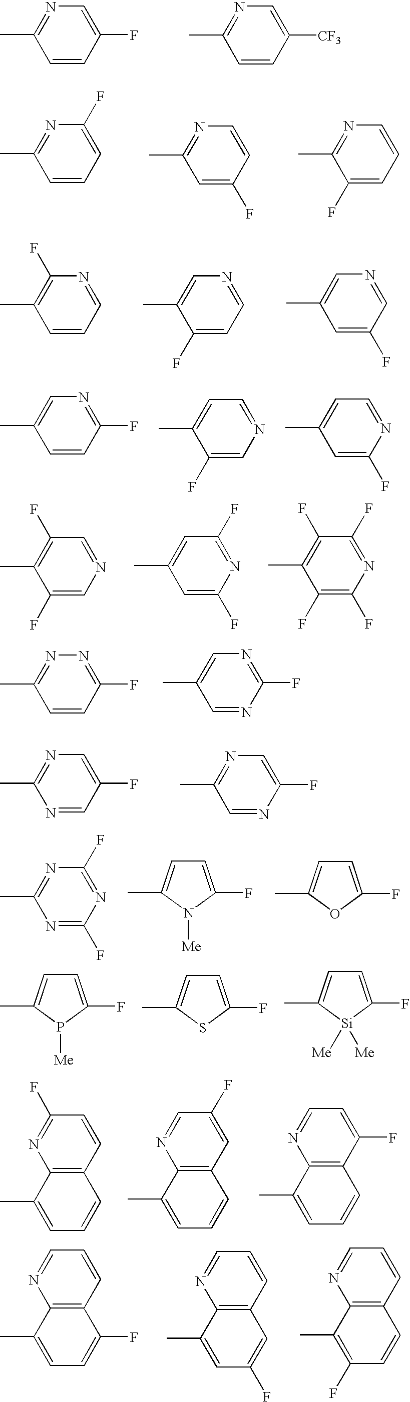 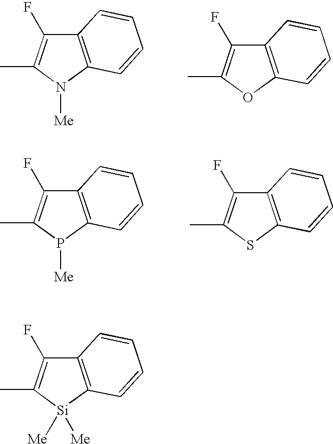
(V) Perfluoroaryl Group, Perfluoro Aryloxy Group:

Examples of the perfluoroaryl group include pentafluoro phenyl group, heptafluoro-1-naphtyl group, hepta fluoro-2-naphtyl group, nonafluoro-1-biphenyl group, nonafluoro-2-biphenyl group, nonafluoro-1-anthracenyl group, nonafluoro-2-anthracenyl group, and nonafluoro-9-anthracenyl group.

As the aryl group having an electron-withdrawing group, and monovalent heterocyclic group having an electron-withdrawing group, those having a fluorine atom or trifluoromethyl group are preferable (the above formulas (III), (IV), and (V)), and perfluoroaryl group (the above formula (V)) is more preferable.

Q¹ in formulas (1a) and (1b) represents an oxygen atom or a direct bond.

X¹ in formula (1a) and (1b) represents a halogen atom, alkyl group, alkyloxy group, alkylthio group, aryl group, aryloxy group, arylthio group, arylalkyl group, the arylalkyloxy group, arylalkylthio group, alkenyl group, alkynyl group, arylalkenyl group, arylalkynyl group, substituted silyloxy group, substituted silylthio group, substituted silylamino group, substituted amino group, amide group, acidimide group, acyloxy group, monovalent heterocyclic group, heteroaryloxy group, heteroarylthio group, cyano group, or nitro group.

As the halogen atom in X¹, fluorine, chlorine, bromine, and iodine are exemplified.

The alkyl group may be any of linear, branched or cyclic, and may have one or more substituents. The number of carbon atoms is usually about 1 to 20, and specific examples thereof include methyl group, ethyl group, propyl group, i-propyl group, butyl group, and i-butyl group, t-butyl group, pentyl group, hexyl group, cyclohexyl group, heptyl group, octyl group, 2-ethyl hexyl group, nonyl group, decyl group, 3,7-dimethyloctyl group, lauryl group, trifluoromethyl group, pentafluoroethyl group, perfluorobutyl group, perfluorohexyl group, perfluorooctyl group, etc.

The alkyloxy group may be any of linear, branched or cyclic, and may have one or more substituents. The number of carbon atoms is usually about 1 to 20, and specific examples thereof include methoxy group, ethoxy group, propyloxy group, i-propyloxy group, butoxy group, i-butoxy group, t-butoxy group, pentyloxy group, hexyloxy group, cyclohexyloxy group, heptyloxy group, octyloxy group, 2-ethylhexyloxy group, nonyl oxy group, decyloxy group, 3,7-dimethyloctyloxy group, lauryl oxy group, trifluoromethoxy group, pentafluoroethoxy group, perfluorobutoxy group, perfluorohexyloxy group, perfluorooctyloxy group, methoxymethyloxy group, 2-methoxyethyloxy group, etc.

The alkylthio group may be any of linear, branched or cyclic, and may have one or more substituents. The number of carbon atoms is usually about 1 to 20, and specific examples thereof include methylthio group, ethylthio group, propylthio group, i-propylthio group, butylthio group, i-butylthio group, t-butylthio group, pentylthio group, hexylthio group, cyclo hexylthio group, heptylthio group, octylthio group, 2-ethyl hexylthio group, nonylthio group, decylthio group, 3,7-dimethyloctylthio group, laurylthio group, trifluoro methylthio group, etc.

The aryl group may have one or more substituents. The number of carbon atoms is usually about 3 to 60, and specific examples thereof include phenyl group and C₁-C₁₂ alkyloxyphenyl group (C₁-C₁₂ shows the number of carbon atoms 1-12. hereafter the same), C₁-C₁₂ alkylphenyl group, 1-naphtyl group, 2-naphtyl group, pentafluoro phenyl group, etc.

The aryloxy group may have a substituent on the aromatic ring. The number of carbon atoms is usually about 3 to 60, and specific examples thereof include phenoxy group, C₁-C₁₂ alkyloxy phenoxy group, C₁-C₁₂ alkylphenoxy group, 1-naphtyloxy group, 2-naphtyloxy group, pentafluorophenyloxy group, etc.

The arylthio group may have a substituent on the aromatic ring. The number of carbon atoms is usually about 3 to 60, and specific examples thereof include phenylthio group, C₁-C₁₂ alkyloxyphenylthio group, C₁-C₁₂ alkylphenylthio group, 1-naphthylthio group, 2-naphthylthio group, pentafluoro phenylthio group, etc.

The arylalkyl group may have a substituent, and number of carbon atoms is usually about 7 to 60, and specific examples thereof include phenyl-C₁-C₁₂ alkyl group, C₁-C₁₂ alkyloxy phenyl-C₁-C₁₂ alkyl group, C₁-C₁₂ alkylphenyl-C₁-C₁₂ alkyl group, 1-naphtyl-C₁-C₁₂ alkyl group, 2-naphtyl-C₁-C₁₂ alkyl group, etc.

The arylalkyloxy group may have a substituent, and number of carbon atoms is usually about 7 to 60, and specific examples thereof include phenyl-C₁-C₁₂ alkyloxy group, C₁-C₁₂ alkyloxy phenyl-C₁-C₁₂ alkyloxy group, C₁-C₁₂ alkyl phenyl-C₁-C₁₂ alkyloxy group, 1-naphtyl-C₁-C₁₂ alkyloxy group, 2-naphtyl-C₁-C₁₂ alkyloxy group, etc.

The arylalkylthio group may have the substituent, and number of carbon atoms is usually about 7 to 60, and specific examples thereof include phenyl-C₁-C₁₂ alkylthio group, C₁-C₁₂ alkyloxyphenyl-C₁-C₁₂ alkylthio group, C₁-C₁₂ alkylphenyl-C₁-C₁₂ alkylthio group, 1-naphtyl-C₁-C₁₂ alkylthio group, 2-naphtyl-C₁-C₁₂ alkylthio group, etc.

The alkenyl group has usually about 2 to 20 carbon atoms, and specific examples thereof include vinyl group, 1-propylenyl group, 2-propylenyl group, 3-propylenyl group, butenyl group, pentenyl group, hexenyl group, heptenyl group, octenyl group, and cyclohexenyl group.

The alkenyl group also include alkadienyl groups, such as 1,3-butadienyl group.

The alkynyl group has usually about 2 to 20 carbon atoms, and specific examples thereof include ethynyl group, 1-propynyl group, 2-propynyl group, butynyl group, pentynyl group, hexynyl group, heptenyl group, octynyl group, and cyclohexyl ethynyl group. The alkynyl group alos include alkydienyl groups, such as 1,3-butadiynyl group.

The arylalkenyl group has usually about 8 to 50 carbon atoms The aryl and alkenyl in the arylalkenyl group are respectively the same as the above described aryl group and alkenyl group. Concrete examples thereof include 1-arylvinyl group, 2-aryl vinyl group, 1-aryl-1-propylenyl group, 2-aryl-1-propylenyl group, 2-aryl-2-propylenyl group, 3-aryl-2-propylenyl group, etc. Moreover, aryl alkadienyl groups, such as 4-aryl 1,3-butadienyl group, are also included.

The arylalkynyl group has usually about 8 to 50 carbon atoms. The aryl and alkynyl in the arylalkenyl group are respectively the same as the above described aryl group and alkenyl group. Concrete examples thereof include arylethynyl group, 3-aryl-1-propionyl group, 3-aryl-2-propionyl group, etc. Moreover, arylalkadiynyl groups, such as 4-aryl-1,3-butadiynyl, are also included.

As the substituted silyloxy group, silyloxy groups (H₃SiO—) substituted with 1, 2, or 3 groups selected from an alkyl group, aryl group, arylalkyl group, and monovalent heterocyclic group, are exemplified. The alkyl group, aryl group, arylalkyl group, or monovalent heterocyclic group may have substituents.

The substituted silyloxy group has usually about 1 to 60 carbon atoms, preferably about 3 to 30 carbon atoms, and specific examples thereof include trimethylsilyloxy group, triethylsilyloxy group, tri-n-propylsilyloxy group, tri-1-propylsilyloxy group, t-butylsilyldimethylsilyloxy group, triphenylsilyloxy group, tri-p-xylylsilyloxy group, tribenzylsilyloxy group, diphenylmethylsilyloxy group, t-butyldiphenylsilyloxy group, dimethylphenylsilyloxy group, etc.

As the substituted silylthio group, silylthio groups (H₃SiS—) substituted with 1, 2, or 3 groups selected from an alkyl group, aryl group, arylalkyl group, and monovalent heterocyclic group, are exemplified. The alkyl group, aryl group, arylalkyl group, or monovalent heterocyclic group may have substituents.

The substituted silylthio group has usually about 1 to 60 carbon atoms, preferably about 3 to 30 carbon atoms, and specific examples thereof include trimethylsilylthio group, triethylsilylthio group, tri-n-propylsilylthio group, tri-i-propylsilylthio group, t-butylsilyldimethylsilylthio group, triphenylsilylthio group, tri-p-xylylsilylthio group, tribenzylsilylthio group, diphenylmethylsilylthio group, t-butyldiphenyl silylthio group, dimethylphenylsilylthio group, etc.

As the substituted silylamino group, silylamino groups (H₃SiNH— or (H₃Si)₂N—) substituted with 1 to 6 groups selected from an alkyl group, aryl group, arylalkyl group, and monovalent heterocyclic group, are exemplified. The alkyl group, aryl group, arylalkyl group, or monovalent heterocyclic group may have substituents.

The substituted silylamino group has usually about 1 to 120 carbon atoms, preferably about 3 to 60 carbon atoms, and specific examples thereof include trimethylsilylamino group, triethylsilylamino group, tri-n-propylsilylamino group, tri-i-propylsilylamino group, t-butylsilyldimethyl silylamino group, triphenylsilylamino group, tri-p-xylyl silylamino group, tribenzylsilylamino group, diphenylmethyl silylamino group, t-butyldiphenylsilylamino group, dimethylphenylsilylamino group, di(trimethylsilyl)amino group, di(triethylsilyl)amino group, di(tri-n-propylsilyl)amino group, di(tri-1-propylsilyl)amino group, di(t-butyl silyldimethylsilyl)amino group, di(triphenylsilyl)amino group, di(tri-p-xylylsilyl)amino group, di(tribenzylsilyl)amino group, di(diphenylmethylsilyl)amino group, di(t-butyl diphenylsilyl)amino group, di(dimethylphenylsilyl)amino group, etc.

As the substituted amino group, amino groups substituted with 1 or 2 groups selected from an alkyl group, aryl group, arylalkyl group, and monovalent heterocyclic group, are exemplified. The alkyl group, aryl group, arylalkyl group, or monovalent heterocyclic group may have substituents.

The substituted amino group has usually about 1 to 40 carbon atoms, and specific examples thereof include methylamino group, dimethylamino group, ethylamino group, diethylamino group, propylamino group, dipropylamino group, isopropylamino group, diisopropylamino group, butylamino group, isobutylamino group, t-butylamino group, pentylamino group, hexylamino group, cyclohexylamino group, heptylamino group, octylamino group, 2-ethylhexylamino group, nonylamino group, decylamino group, 3,7-dimethyloctylamino group, laurylamino group, cyclopentyl amino group, dicyclopentylamino group, cyclohexylamino group, dicyclohexylamino group, pyrrolidyl group, piperidyl group, ditrifluoromethylamino group, phenylamino group, diphenyl amino group, C₁-C₁₂ alkyloxyphenylamino group, di(C₁-C₁₂ alkyloxy phenyl)amino group, di(C₁-C₁₂ alkylphenyl)amino group, 1-naphtylamino group, 2-naphtylamino group, pentafluoro phenylamino group, pyridylamino group, pyridazinylamino group, pyrimidylamino group, pyrazylamino group, triazylamino group, phenyl-C₁-C₁₂ alkylamino group, C₁-C₁₂ alkyloxyphenyl-C₁-C₁₂ alkylamino group, C₁-C₁₂ alkylphenyl-C₁-C₁₂ alkylamino group, di(C₁-C₁₂ alkyloxyphenyl-C₁-C₁₂ alkyl)amino group, di(C₁-C₁₂ alkyl phenyl-C₁-C₁₂ alkyl)amino group, 1-naphtyl-C₁-C₁₂ alkylamino group, 2-naphtyl-C₁-C₁₂ alkylamino group, etc.

The amide group has usually about 2 to 20 carbon atoms, and specific examples thereof include formamide group, acetamide group, propioamide group, butyroamide group, benzamide group, trifluoroacetamide group, pentafluoro benzamide group, diformamide group, diacetoamide group, dipropioamide group, dibutyroamide group, dibenzamide group, ditrifluoro acetamide group, dipentafluorobenzamide group, etc.

Examples of the acid imide group include residual groups in which a hydrogen atom connected with nitrogen atom is removed, and have usually about 2 to 60 carbon atoms, preferably 2 to 20 carbon atoms. As the concrete examples of acid imide group, the following groups are exemplified.

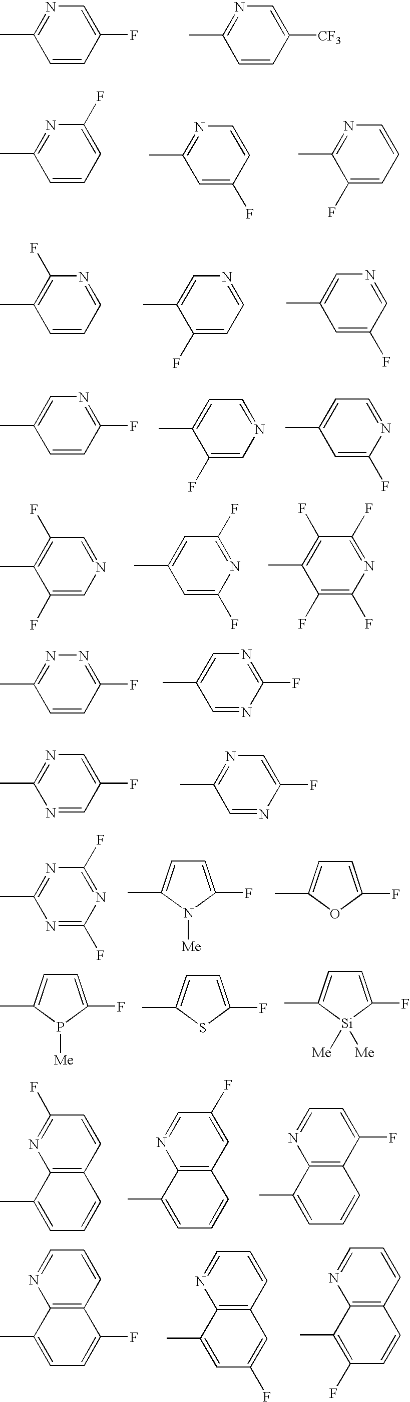

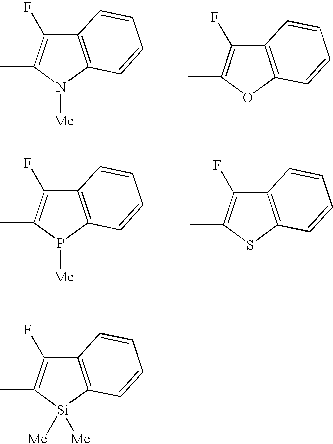

The acyloxy group has usually about 2 to 20 carbon atoms, and specific examples thereof include acetoxy group, propionyloxy group, butyryloxy group, isobutyryloxy group, pivaloyloxy group, benzoyloxy group, trifluoroacetyloxy group, pentafluorobenzoyloxy group, etc.

The monovalent heterocyclic group means an atomic group in which a hydrogen atom is removed from a heterocyclic compound. The number of carbon atoms is usually about 2 to 60, and specific examples thereof include thienyl group, C₁-C₁₂ alkyl thienyl group, pyroryl group, furyl group, pyridyl group, C₁-C₁₂ alkylpyridyl group, imidazolyl group, pyrazolyl group, triazolyl group, oxazolyl group, thiazole group, thiadiazole group, etc.

The heteroaryloxy group (a group represented by Q⁵-O— and Q⁵ represents a monovalent heterocyclic group) has usually about 2 to 20 carbon atoms, and specific examples thereof include thienyloxy group, C₁-C₁₂ alkylthienyloxy group, pyroryloxy group, furyloxy group, pyridyloxy group, C₁-C₁₂ alkylpyridyloxy group, imidazolyloxy group, pyrazolyloxy group, triazolyloxy group, oxazolyloxy group, thiazoleoxy group, thiadiazoleoxy group, etc. As Q5, a monovalent aromatic heterocyclic group is preferable.

The heteroarylthio group (represented by Q⁶-S—. Q⁶ represents a monovalent heterocyclic group) has usualy about 2 to 60 carbon atoms, and concrete examples thereof include thienyl-mercapto group, C₁-C₁₂ alkylthienyl-mercapto group, pyrorylmercapto group, furyl mercapto group, pyridylmercapto group, C₁-C₁₂ alkylpyridylmercapto group, imidazolylmercapto group, pyrazolylmercapto group, triazolylmercapto group, oxazolylmercapto group, thiazolemercapto group, thiadiazole mercapto group, etc. As Q6, a monovalent aromatic heterocyclic group is preferable.

In formula (1a), Z¹ represents -M′(=O)ₚ— (wherein, M′ represents an atom of group 3, group 4, group 5, group 6, group 7, group 8, group 9, group 10, group 11, group 12, group 13, group 14, group 15, group 16, or group 17, and p represents an integer of 0-2), or represents a b-valent aliphatic hydrocarbon group, b-valent aromatic hydrocarbon group, bidentate heterocyclic group, —C≡N—, —N═N═N—, —NH—, —NH₂—, —OH—, or a direct bond. However, when Z¹ is —C≡N—, —N═N═N—, —NH—, —NH₂—, or —OH—, b is 2. Although —C≡N—, —N═N═N—, —NH₂—, and —OH— are positively charged by itself, the description avout charge is omitted. (Chem. Commun., 1999, 1533).

In case Z¹ is -M′(=O)ₚ—, as an atom of group 3, group 4, group 5, group 6, group 7, group 8, group 9, group 10, group 11, group 12, group 13, group 14, group 15, group 16, and group 17 in M′, exemplified are a boron atom, carbon atom, nitrogen atom, oxygen atom, fluorine atom, aluminum atom, silicon atom, phosphorus atom, sulfur atom, chlorine atom, scandium atom, titanium atom, vanadium atom, chromium atom, manganese atom, iron atom, cobalt atom, nickel atom, copper atom, zinc atom, gallium atom, germanium atom, selenium atom, bromine atom, yttrium atom, zirconium atom, molybdenum atom, palladium atom, hafnium atom, tungsten atom, platinum atom, etc., and preferable is the case where the atomic weight is 50 or less.

In the case where M′ is an atom of group 3 excluding oxygen, group 4, group 5, group 6, group 7, group 8, group 9, group 10, group 11, group 12, group 13, group 14, group 15, group 16, and group 17, p can be 1, and when M′ is an atom of group 5, group 6, or group 7, p can be 2.

As the concrete examples where p=1 or 2, —Ti(═O)—, —V(═O)—, —Cr(═O)—, —Cr(═O)₂—, —Zr(═O)—, —Mo(═O)—, —W(═O)—, etc. are exemplified.

The b-valent aliphatic hydrocarbon group in Z¹ represents an atomic group in which b pieces of hydrogen atoms are removed from an aliphatic hydrocarbon, and may be any of linear, branched or cyclic. It may have substituents, and the number of carbon atoms is usually about 1 to 20. Although b is an integer of 2-6, b does not exceed the number of hydrogens of the aliphatic hydrocarbon group.

Concrete examples of the aliphatic hydrocarbon include methane, ethane, propane, cyclopropane, butane, cyclobutane, 2-methylpropane, pentane, cyclopentane, 2-methylbutane, 2,2-dimethylpropane, hexane, cyclohexane, heptane, octane, 2-ethylhexane, nonane, decane, 3,7-dimethyloctane, etc.

Concrete examples of the divalent aliphatic hydrocarbon group (in case of b=2) include methylene group, ethylene group, propylene group, trimethylene group, tetramethylene group, pentamethylene group, 1,3-cyclopentylene group, 1,4-cyclohexylene group, etc.

In case of b is not less than 3 and not more than 6, concrete examples thereof following group.

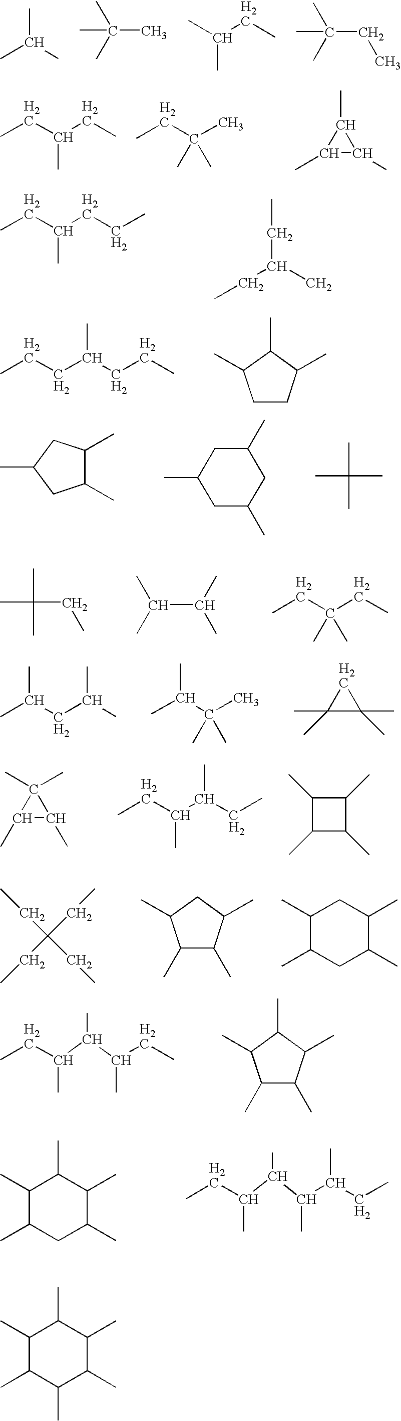

The b-valent aromatic hydrocarbon group in Z¹ represents an atomic group in which b pieces of hydrogen atoms are removed from an aromatic hydrocarbon. It may have substituents on the aromatic ring, and the number of carbon atoms is usually about 6 to 60. b does not exceed the number of hydrogens of the aromatic ring of the aromatic hydrocarbon group.

Concrete examples of the aromatic hydrocarbon include benzene and C₁-C₁₂ alkyloxybenzene (C₁-C₁₂ shows the number of carbon atoms 1-12. hereafter the same), C₁-C₁₂ alkylbenzene, naphthalene, anthracene, phenanthrene, tetracene, pentacene, etc.

In case of b=2 (divalent aromatic hydrocarbon group), it represens an atomic group in which two hydrogen atoms are removed from an aromatic hydrocarbon group, and the number of carbon atoms is usually about 6 to 60, preferably 6 to 20. Examples thereof include phenylene group (for example, following formulas 1-3), naphthalenediyl group (following formulas 4-13), anthracenylene group (following formulas 14-19), biphenylene group (following formulas 20-25), triphenylene group (following formulas 26-28), condensed ring compound group (following formulas 29-38), etc. The number of carbon atoms of substituent R′″ is not counted as the number of carbon atoms of divalent aromatic hydrocarbon group.

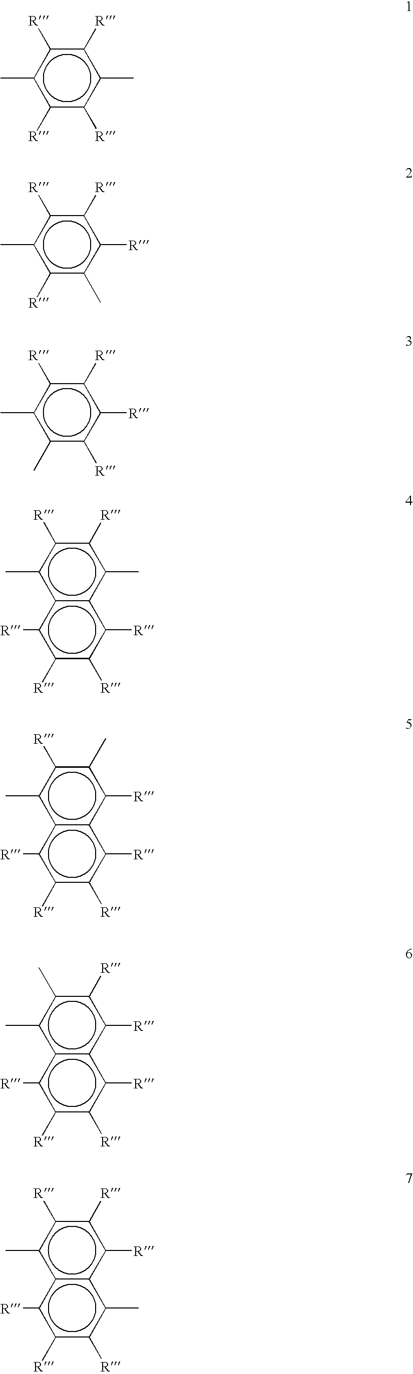

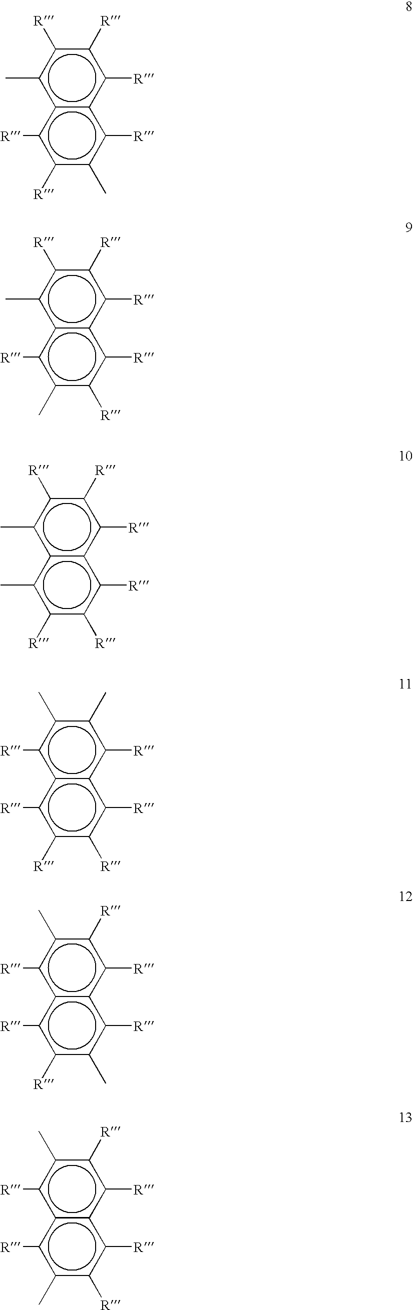

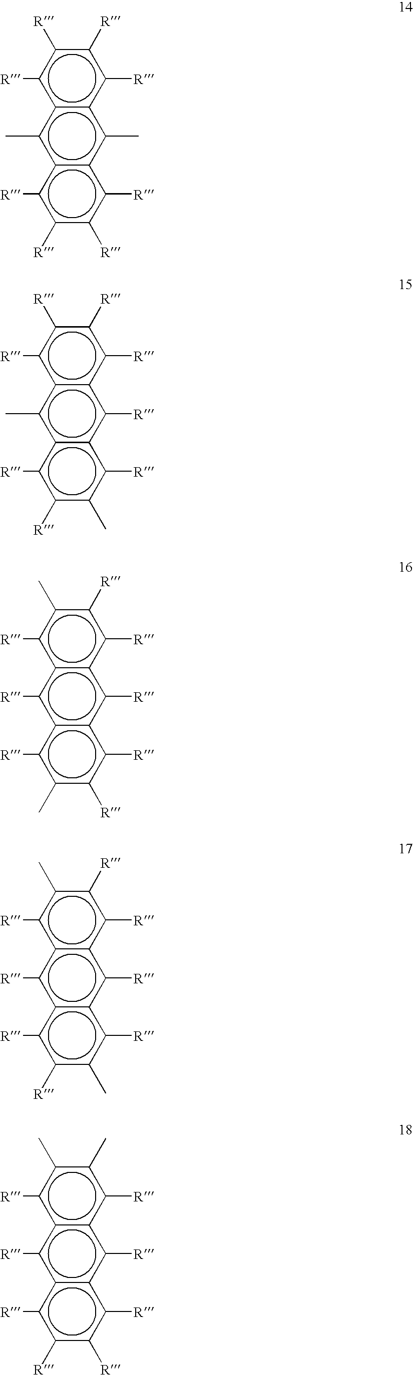

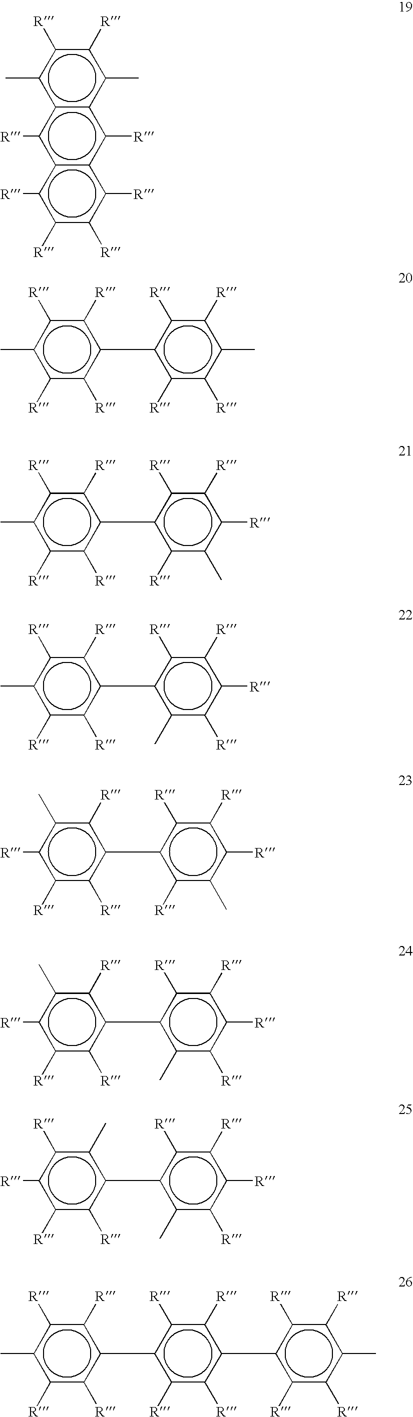

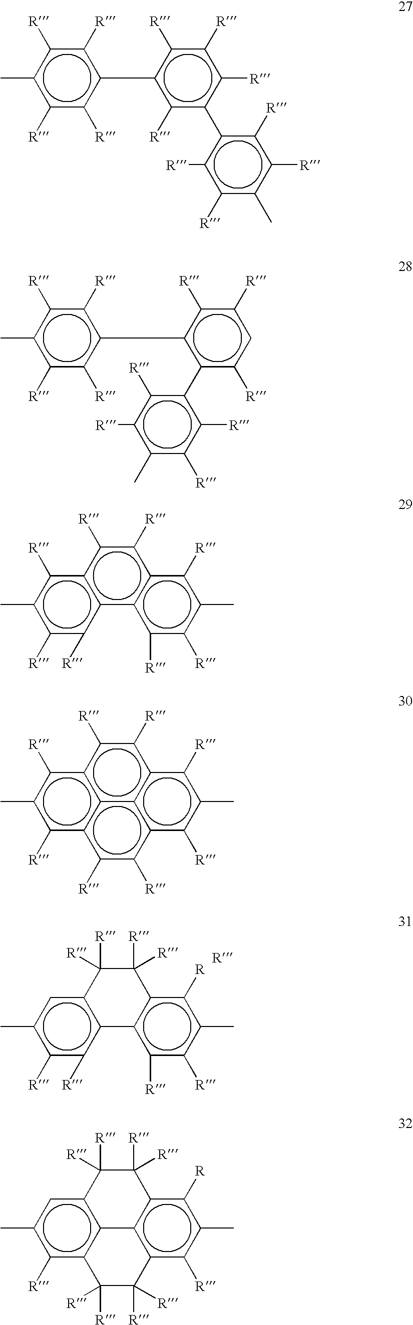

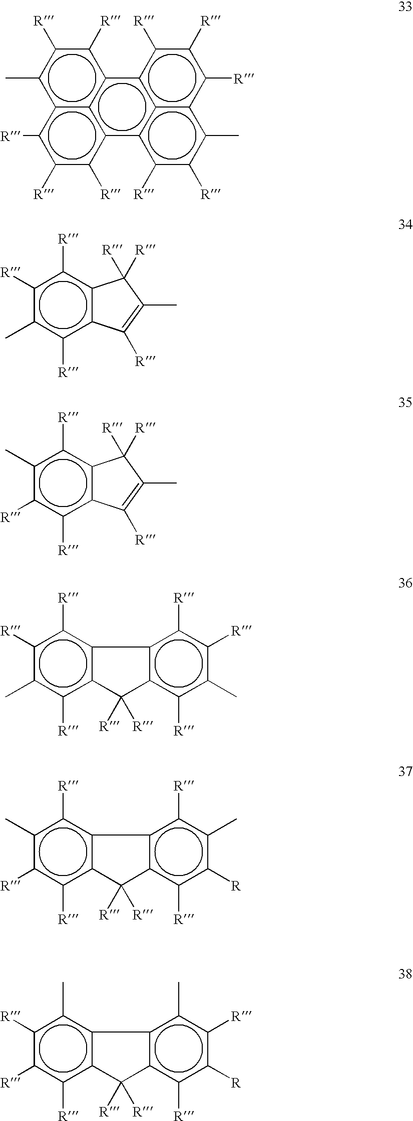

R′″ each independently represents a hydrogen atom, halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, substituted silyloxy group, substituted silylthio group, substituted silylamino group, substituted amino group, amide group, acid imide group, acyloxy group, monovalent heterocyclic group, heteroaryloxy group, heteroarylthio group, acyl group, imine residue, substituted silyl group, alkyloxycarbonyl group, aryloxy carbonyl group, arylalkyloxy carbonyl group, heteroaryloxy carbonyl group, carboxyl group, cyano group, or nitro group.

In case of b is 3 to 6, as the b-valent aromatic hydrocarbon group, exemplified are residues in which (b-2) pieces of R′″s are removed from the above examples (1-38) of the divalent aromatic hydrocarbons.

The b-dentate heterocyclic group in Z¹ means a group derived from a heterocyclic compound, and has b pieces of bonding positions. As the bonding positions, a position which bonds to the next atom by the covalent bond (covalent bond part), and a position which bonds by the coordinate bond (coordinate-bond part) are exemplified.

As the b-dentate heterocyclic group, exemplified are b-dentate atomic groups in which at least one hydrogen atom is removed from a heterocyclic compound. They may have substituents, and the number of carbon atoms is usually about 2 to 60, and preferably 2 to 20.

As the bidentate heterocyclic group (in case of b=2), exemplified are groups having two covalent bond part (divalent heterocyclic group) and groups having one covalent-bond part and one coordinate-bond part (monovalent and bidentate heterocyclic group). As the concrete examples of the divalent heterocyclic group, following are exemplified.

Divalent heterocyclic groups containing nitrogen as a hetero atom; pyridine-diyl group (following formulas 39-44), diaza phenylene group (following formulas 45-48), quinolinediyl group (following formulas 49-63), quinoxalinediyl group (following formulas 64-68), acridinediyl group (following formulas 69-72), bipyridyldiyl group (following formulas 73-75), phenanthrolinediyl group (following formulas 76-78), etc.

Groups having a fluorene structure containing silicon, nitrogen, sulfur, selenium, etc. as a hetero atom (following formulas 79-93). It is preferable to have an aromatic amine monomer containing a nitrogen atom, such as carbazole of formulas 82-84 or triphenylaminediyl group, in view of light emitting efficiency.

5 membered heterocyclic groups containing silicon, nitrogen, sulfur, selenium, etc. as a hetero atom: (following formulas 94-98).

Condensed 5 membered heterocyclic groups containing silicon, nitrogen, sulfur, selenium, etc. as a hetero atom: (following formulas 99-109), benzothiadiazole-4,7-diyl group, benzo oxadiazole-4,7-diyl group, etc.

5 membered heterocyclic groups containing silicon, nitrogen, sulfur, selenium, etc. as a hetero atom, which are connected at the a position of the hetero atom to form a dimer or an oligomer (following formulas 110-118); and

5 membered ring heterocyclic groups containing silicon, nitrogen, oxygen, sulfur, selenium, as a hetero atom is connected with a phenyl group at the a position of the hetero atom (following formulas 112-118).

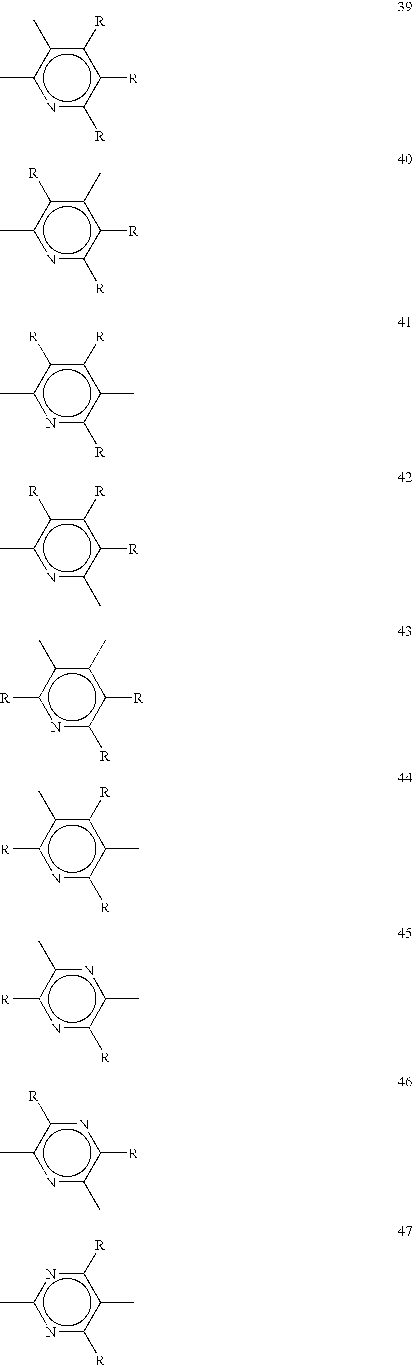

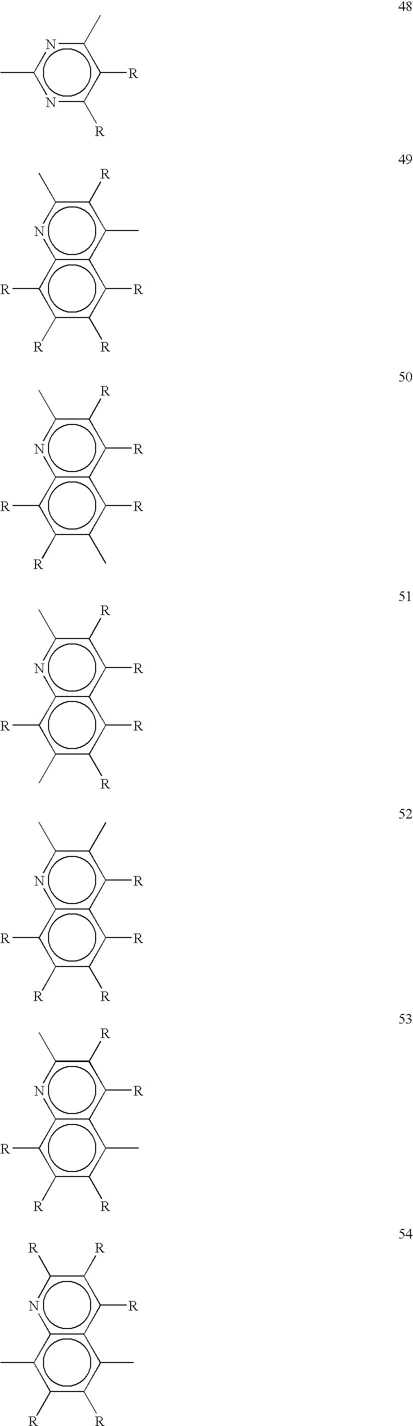

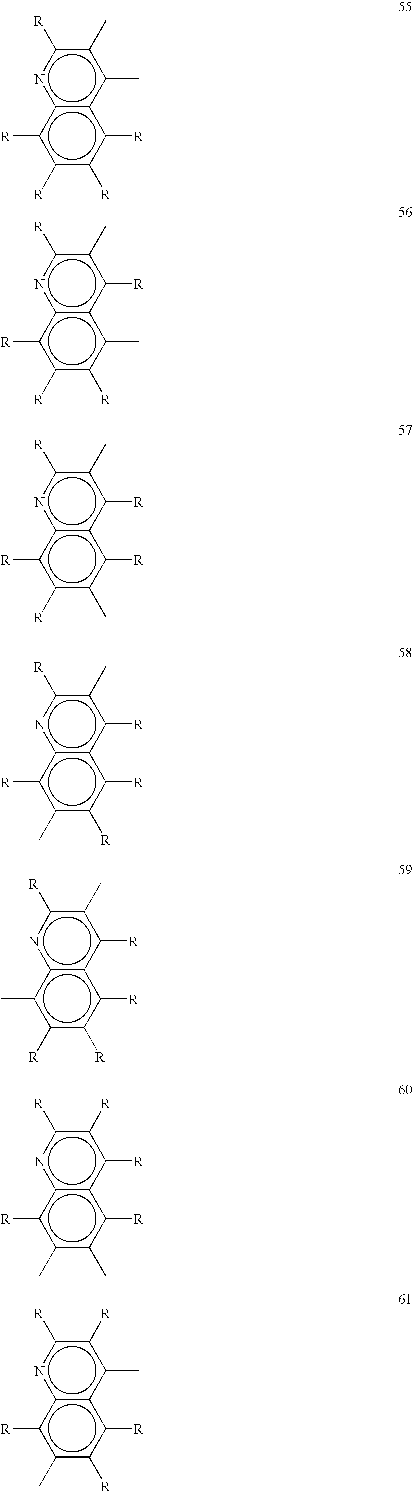

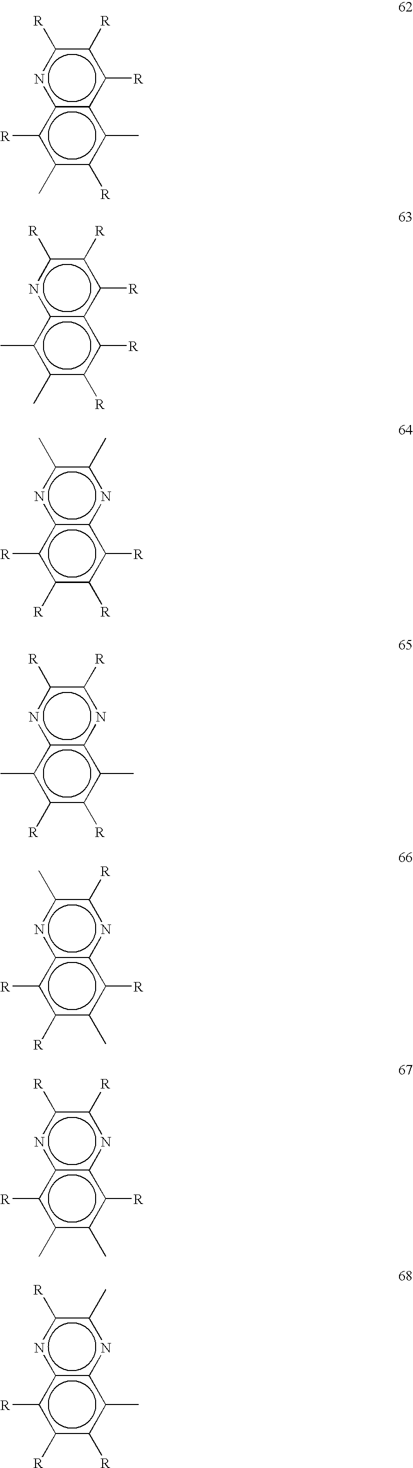

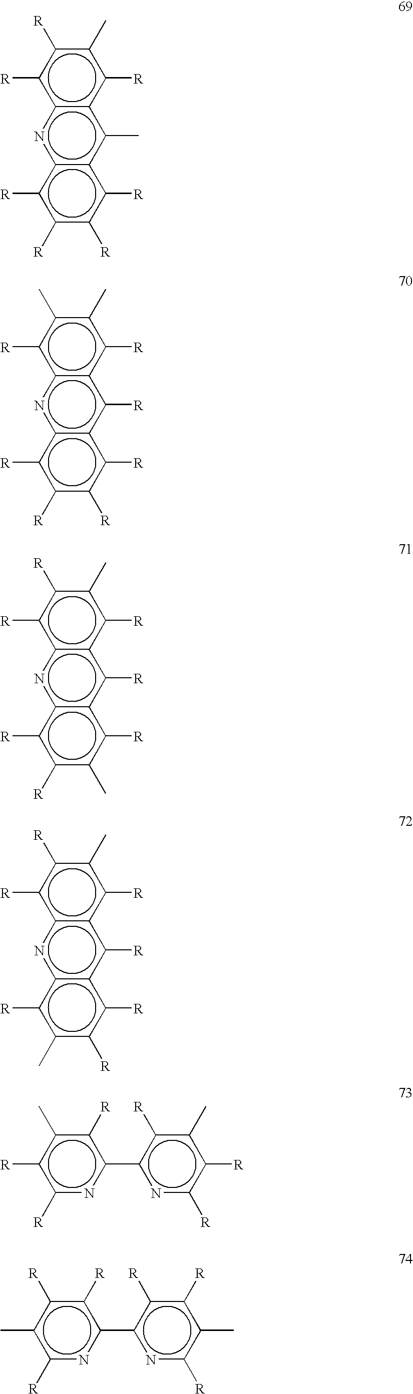

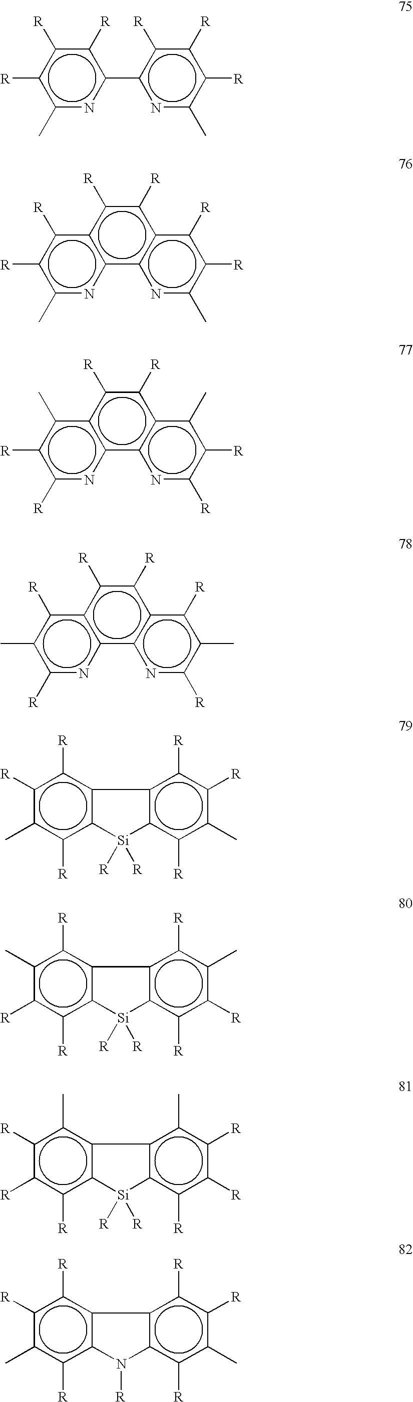

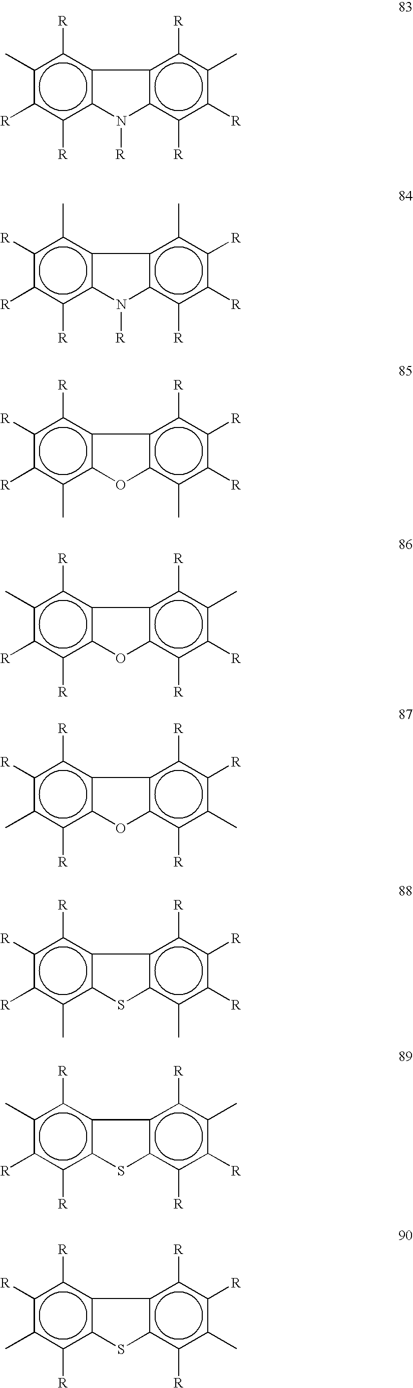

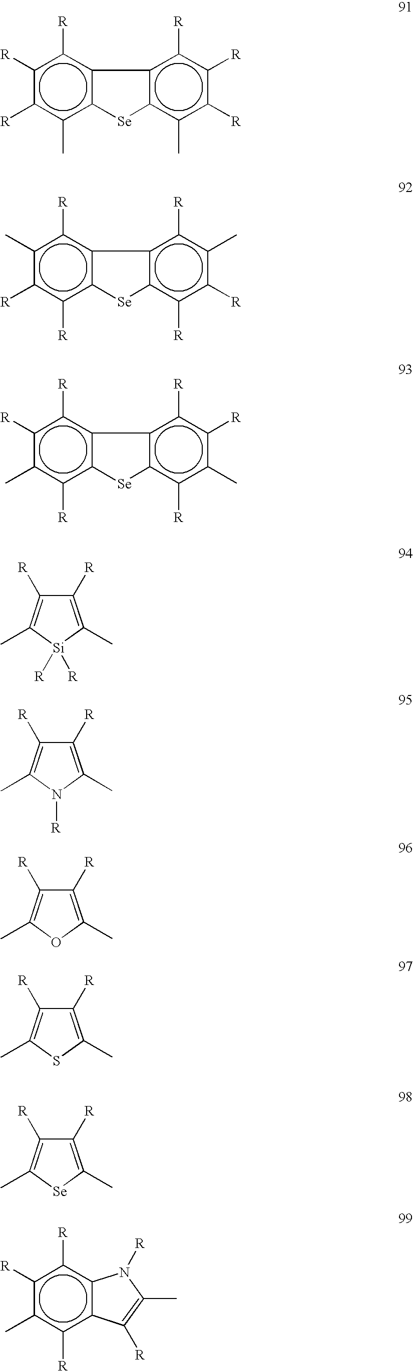

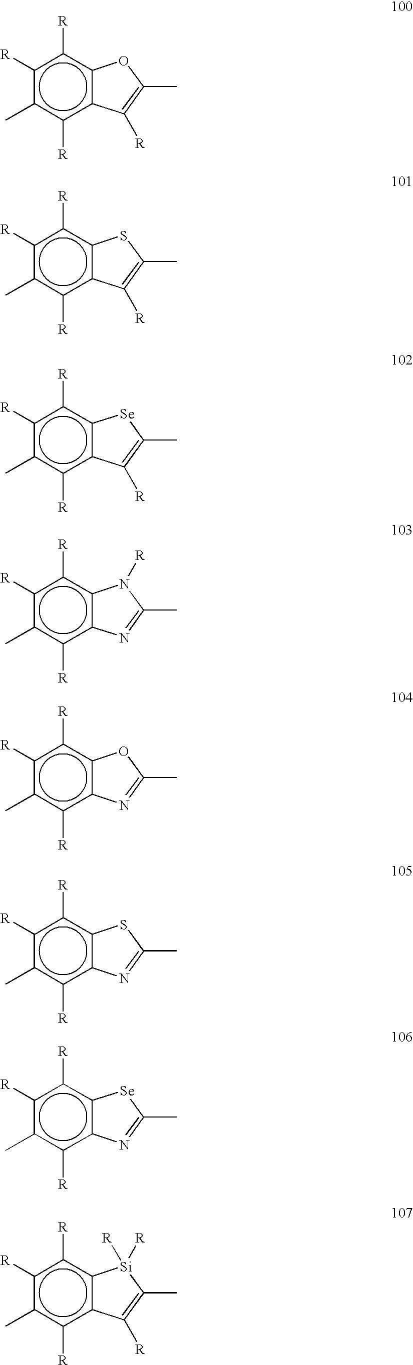

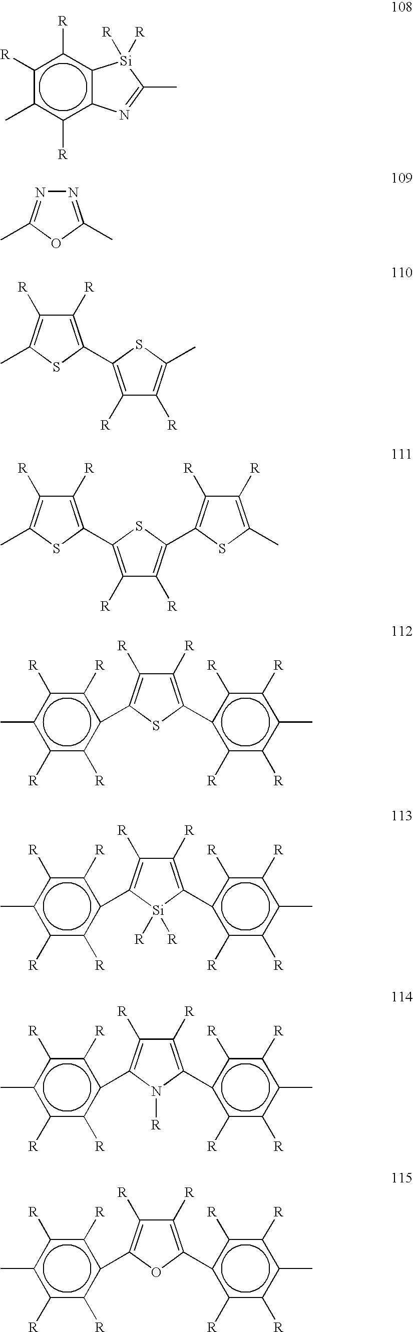

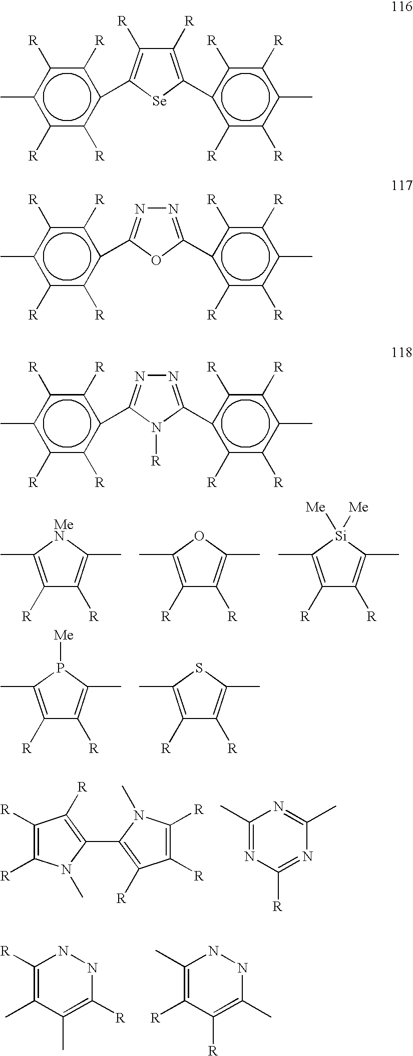

Wherein, R each independently represent a hydrogen atom, halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, substituted silyloxy group, substituted silylthio group, substituted silylamino group, Substituted amino group, amide group, acid imide group, acyloxy group, monovalent heterocyclic group, heteroaryloxy group, heteroarylthio group, acyl group, imine residue, substituted silyl group, alkyloxy carbonyl group, aryloxycarbonyl group, arylalkyloxy carbonyl group, heteroaryloxycarbonyl group, carboxyl group, cyano group, or nitro group.

Concrete examples of the monovalent and bidentate heterocyclic group include: groups derived from the divalent heterocyclic group of the above 39-118 in which one of the connecting bonds is replaced by R, and further has a coordinate bond on the hetero atom; and the following groups.

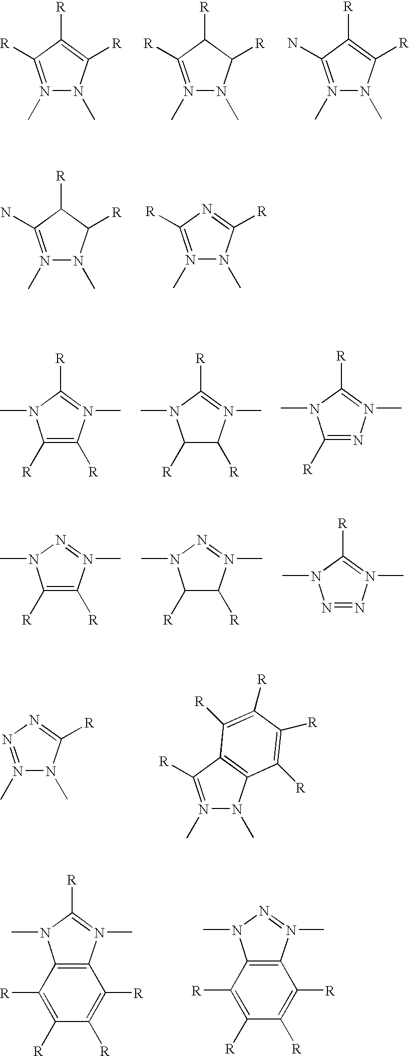

When b is 3-6, as the b-valent heterocyclic group (having b peices of covalent-bond parts), the residue in which (b-2) pieces of hydrogen atoms are removed from the above examples of divalent heterocyclic group.

V¹ in formula (1a) represents a group 16 atom, divalent aliphatic hydrocarbon group, divalent aromatic hydrocarbon group, bidentate heterocyclic group, —C≡N—, —N═N═N—, or a direct bond, and a plurality of V¹ may be the same or different, respectively. Z¹ and V¹ are not the same.

Examples of the group 16 atom in V¹ include an oxygen atom, sulfur atom, selenium atom, and tellurium atom, and preferably an oxygen atom and sulfur atom.

The definition and concrete examples of the divalent aliphatic hydrocarbon group in V¹ are the same as those in the above Z¹.

The definition and concrete examples of the divalent aromatic hydrocarbon group in V¹ are the same as those of the above Z¹.

The definition and concrete examples of the bidentate heterocyclic group in V¹ are the same as those of the above Z¹.

In formula (1a), a represents an integer of not less than 1 and not more than 3, preferably an integer of 2 or 3, and more preferably 3.

In formula (1b), k represents an integer of not less than 1 and not more than 4, preferably an integer of not less than 3 in view of making a long-life device, and more preferably k=4.

In formula (1a), b represents an integer of not less than 2 and not more than 6. However, when V¹ is —C≡N—, —N═N═N— or a direct bond, b is 2.

In formula (1a), c represents an integer of not less than 1 and not more than 6.

Concrete examples of the negative ion represented by the above formula (1a) include negative ions represented by VI or VII described below.

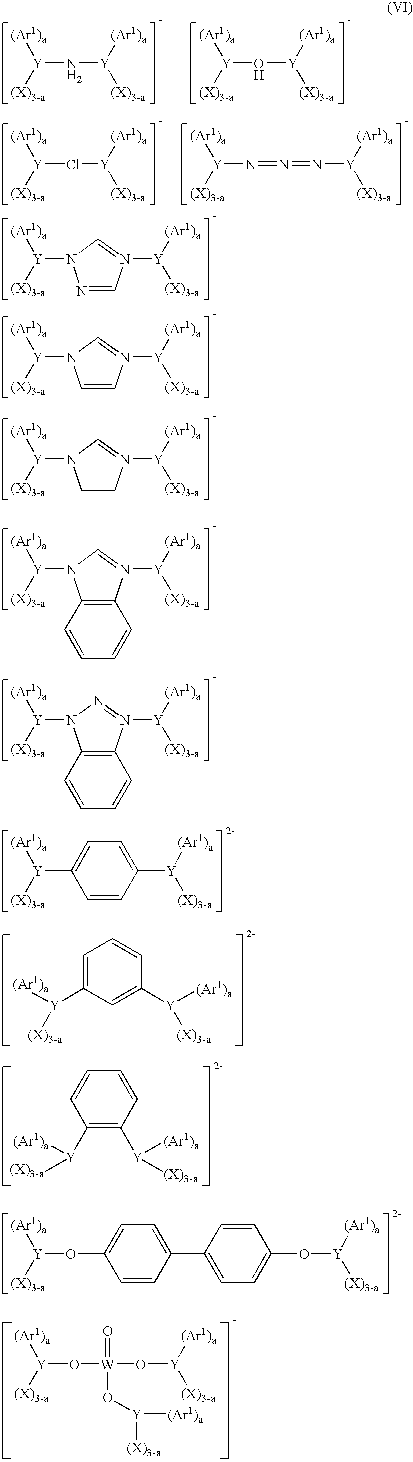

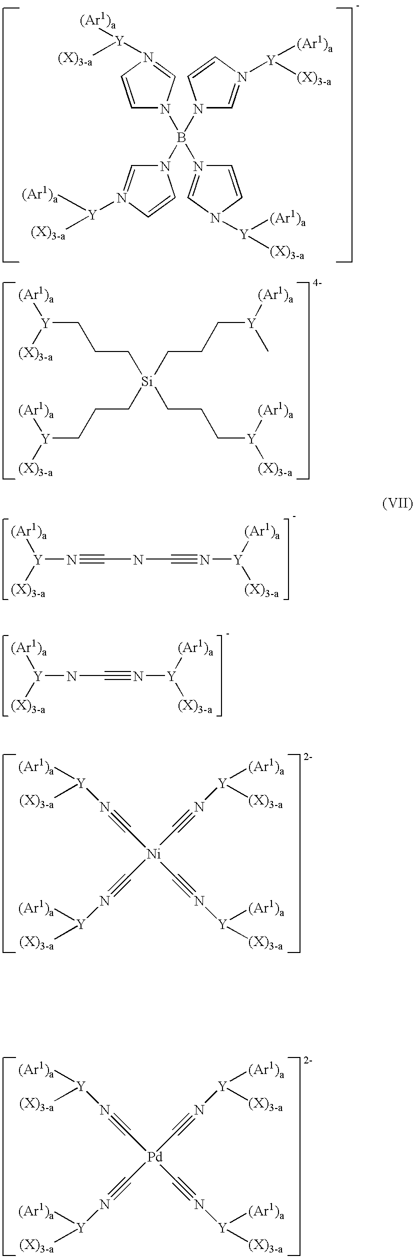

Among the negative ions represented by the above formula (1a), in view of long-life, the case where Ar¹ is a perfluoroaryl group is preferable, and the case where a is 2 or 3, is further preferable.

The case where Z¹ or V¹ is —C≡N—, is more preferable. Concretely, the negative ions represented by the above formula VII are exemplified.

More preferable is the case where the above formula (1a) is the below formula (5-1) or (5-2).
[(C₆F₅)₃B—C≡N—B(C₆F₅)₃]⁻ (5-1)
[M{C≡N—B(C₆F₅)₃}₄]²⁻ (5-2)
(wherein, M represents a nickel atom or a palladium atom.)

Among the negative ions represented by the above formula (1b), in view of long-life, the case where Ar¹ is a perfluoroaryl group is preferable, and the case where k is 3 or 4, is more preferable.

Among the negative ions represented by formula (1b), the case Y is a boron atom is preferable, and the case where it is represented by (1-1) is more preferable in view of long-life. 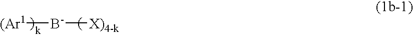
(wherein, Ar¹, X, and k represent the same meaning as the above.)

More preferable is the case where the above formula (1b-1) is represented by the below formula (1b-2).
[B(Ar^{1b})₄]⁻ (1b-2)
(wherein, Ar^{1b} represents a phenyl group substituted by two or more group selected from fluorine and trifluoromethyl group. Ar^{1b}s may be the same or diferent.

In formula (1b-2), the case where all Ar^{1b}s are the same is preferable.

As the examples, exemplifed are those represented by the below formulas (12) and (13), and those represented by formula (12) is preferable.

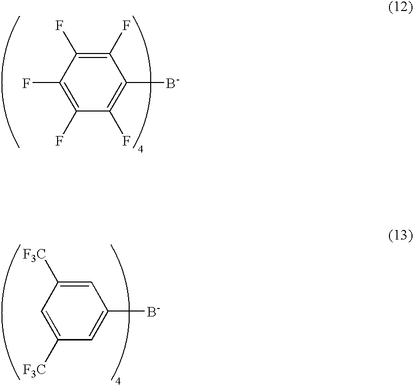

The case where the above formula (1b-1) is represented by the below formula (1b-3) is also preferable.

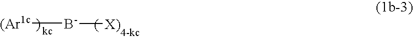

Wherein, X represents the same meaning as the above. Ar^{1c} represents a perfluoroaryl group and f represents an integer of 3 or 4.

Concretely, the following negative ions are exemplified.

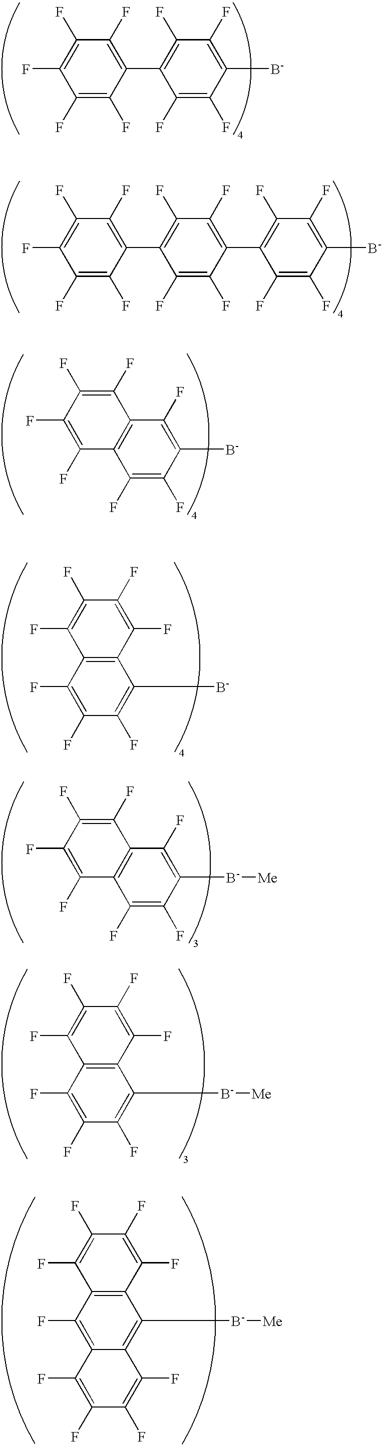

As for the ion pair used for the composition of the present invention, the negative ions are represented by the above formula (1a), (1b), (2) or (3).

Among them, the negative ion of formula (2) represents 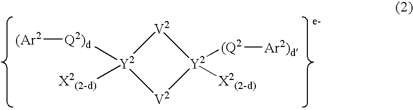
(wherein, Y² represents a group 13 atom and Ar² represents an aryl group having an electron-withdrawing group, or a monovalent heterocyclic group having an electron-withdrawing group. Q² represents an oxygen atom or a direct bond. X² represents a halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, substituted silyloxy group, substituted silylthio group, substituted silylamino group, substituted amino group, amide group, acid imide group, acyloxy group, monovalent heterocyclic group, heteroaryloxy group, heteroarylthio group, cyano group, or nitro group. d and d′ each independently represents 1 or 2. V² represents a group 16 atom, divalent aliphatic hydrocarbon group, divalent aromatic hydrocarbon group, bidentate heterocyclic group, —C≡N— or —N═N—. A plurality of Y², Ar², Q² and V² may be the same or different, and when two or more X² exist, they may be the same or different. e represents an integer of 1-6.).

Concrete examples of group 13 atom in Y² is the same as those of the above Y¹. The definition and the concrete examples of the aryl group having electron-withdrawing group and the monovalent heterocyclic group having electron-withdrawing group in Ar² are the same as those of the above Ar¹.

In X², the definition and the concrete examples of halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, substituted silyloxy group, substituted silylthio group, substituted silylamino group, substituted amino group, amide group, acid imide group, acyloxy group, monovalent heterocyclic group, heteroaryloxy group, and heteroarylthio group, are the same as those of the above X². In V², the definition and the concrete examples of group 16 atom, divalent aliphatic hydrocarbon group, divalent aromatic hydrocarbon group, and bidentate heterocyclic group, are the same as those in the above V¹.

As the negative ion represented by the above formula (2), concretely exemplified are the negative ions represented by below formula VIII.

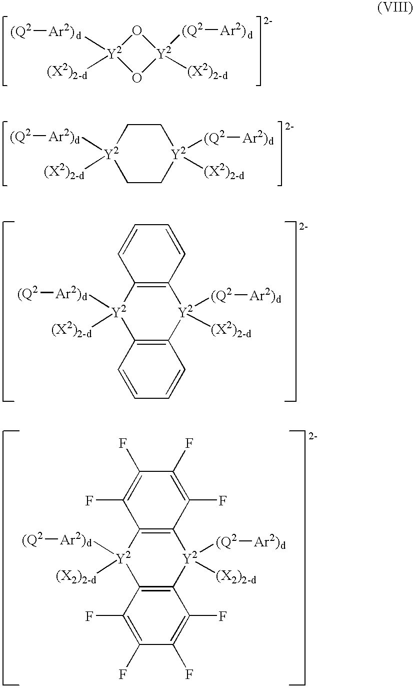

Among the negative ions represented by the above formula (2), the case where Ar² is perfluoro aryl group is preferable in view of long-life, and the case where Ar² is a perfluoro aryl group and d and d′ are 2, is more preferable.

As for the ion pair used for the composition of the present invention, the negative ion is represented by the above formula (1a), (1b), (2), or (3), and among the negative ion of formula (3) represent, 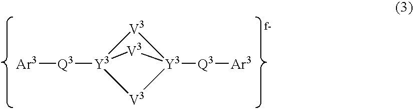
(wherein, Y³ represents a group 13 atom and Ar³ represents an aryl group having an electron-withdrawing group, or a monovalent heterocyclic group having an electron-withdrawing group. Q³ represents an oxygen atom or a direct bond. V³ represent a group 16 atom, divalent aliphatic hydrocarbon group, divalent aromatic hydrocarbon group, bidentate heterocyclic group, —C≡N—, or —N═N—. A plurality of Y³, Ar³, Q³ and V³ are respectively the same or different. f represents an integer of 1-6.).

Concrete examples of group 13 atom in Y³ is the same as those of the above Y¹, and the definition and the concrete examples of the aryl group having the electron-withdrawing group and the monovalent heterocyclic group having an electron-withdrawing group in Ar³ are the same as those of the above Ar¹. In V³, the definition and the concrete examples of group 16 atom, divalent aliphatic hydrocarbon group, divalent aromatic hydrocarbon group, and bidentate heterocyclic group, are the same as those of V¹.

As the negative ion represented by the above formula (3), concretely exemplified are the negative ions represented by below formula IX.

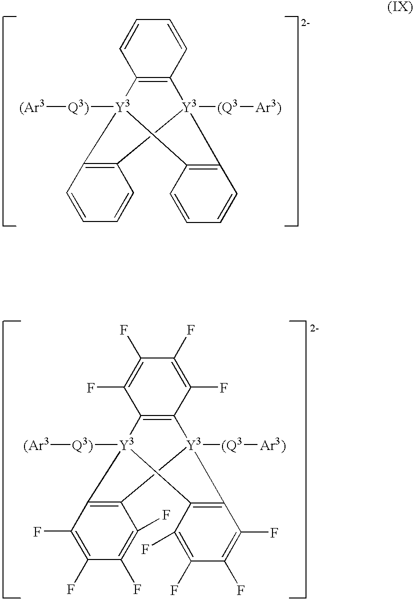

In the above formula VI-IX, substituents may be contained on the aromatic hydrocarbon ring, heterocycle, or hydrocarbon chain.

Among the negative ions represented by the above formula (3), the case where Ar is a perfluoroaryl group is preferable in view of long-life.

Among the negative ions represented by the above formula (1a), (1b), (2), and (3), an ion pair which contains the negative ion represented by (1a) is preferable.

Next, the positive ion of the ion pair contained in the composition of the present invention is described. As the positive ion, exemplified are: carbocation; onium of the element selected from a nitrogen atom, an oxygen atom, a phosphorus atom, a sulfur atom, a chlorine atom, a selenium atom, a bromine atom, a tellurium atom, and an iodine atom; a hydrogen ion, and a metal cation.

The carbocation may be monovalent, or polyvalent such as di-valent or more, and examples thereof include methylium, ethylium, neopentylinium, cyclopropenylium, phenylium, anthrylium, and triphenylmethylium.

The onium of nitrogen atom may be monovalent, or polyvalent such as di-valent or more, and examples thereof include monovalent aliphatic ammonium salts shown by below formulas.

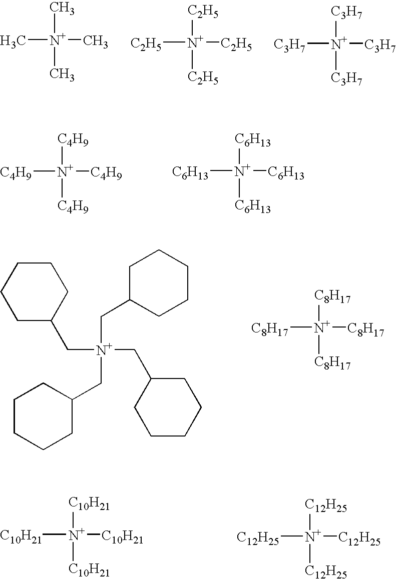

Cyclic aliphatic ammonium salts represented by the below formula,

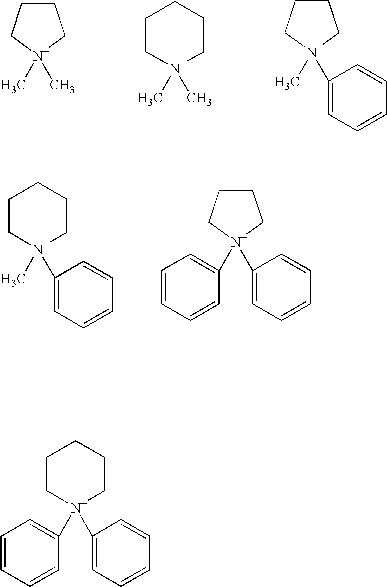

Aromatic ammonium salts represented by the below formula,

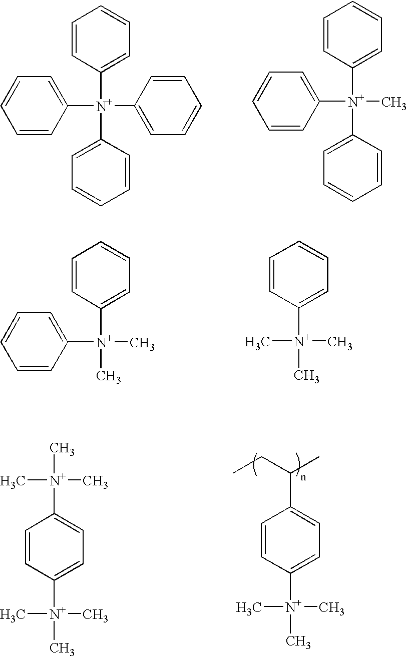

Onium of heterocycles containing nitrogen atom represented by the below formula,

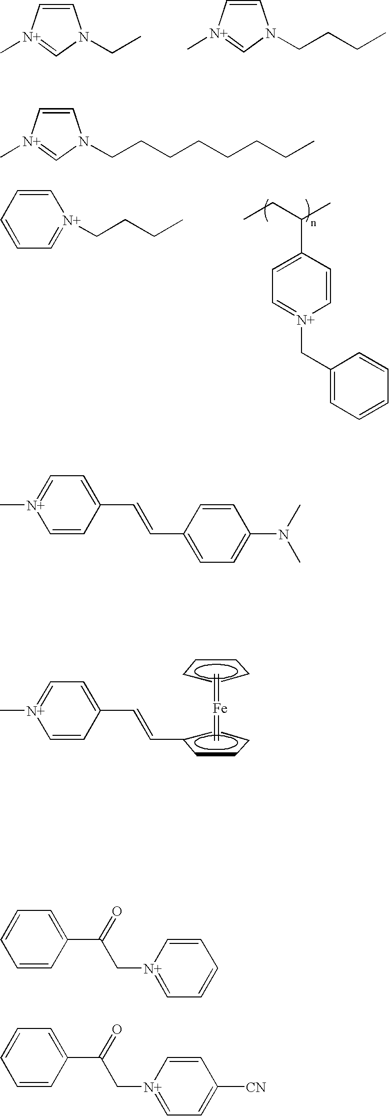

The below formula (6)

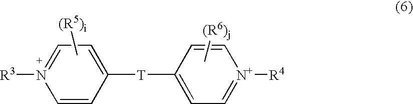

Wherein, R³ and R⁴ each independently represent alkyl group, alkyloxy group, aryl group, aryloxy group, arylalkyl group, arylalkyloxy group, acyl group, acyloxy group, monovalent heterocyclic group, or heteroaryloxy group. R⁵ and R⁶ each independently represent a halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, substituted silyloxy group, substituted silylthio group, substituted silylamino group, substituted amino group, amide group, acid imide group, acyloxy group, monovalent heterocyclic group, heteroaryloxy group, hetero arylthio group, acyl group, imine residue, substituted silyl group, alkyloxycarbonyl group, aryloxycarbonyl group, arylalkyloxycarbonyl group, heteroaryloxycarbonyl group, carboxyl group, cyano group, or nitro group. T represents a direct bond, divalent aliphatic hydrocarbon group, divalent aromatic hydrocarbon group, alkenylene group, ethynylene group, or a divalent heterocyclic group. i and j each independently represent an integer of 0-4. When two or more R⁵ and R⁶ exist, respectively, they may be the same or different.

In R³, R⁴, R⁵, and R⁶, the definition and the concrete examples of halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, substituted silyloxy group, substituted silylthio group, substituted silylamino group, substituted amino group, amide group, acid imide group, acyloxy group, monovalent heterocyclic group, heteroaryloxy group, and heteroarylthio group are the same as those of the above X¹ and X². The definition and the concrete examples of acyl group, alkyloxycarbonyl group, aryloxycarbonyl group, alkylalkyloxycarbonyl group, and heteroaryloxy carbonyl group are the same as those of the electron-withdrawing groups in the above Ar¹, Ar², and Ar³.

Imine residue is a residue in which a hydrogen atom is removed from an imine compound (an organic compound having —N═C— is in the molecule. Examples thereof include aldimine, ketimine, and compounds whose hydrogen atom on N is substituted with an alkyl group etc.), and usually has about 2 to 60 carbon atoms, preferably 2 to 20 carbon atoms. As the concrete examples, groups represented by below structural formulas are exemplified.

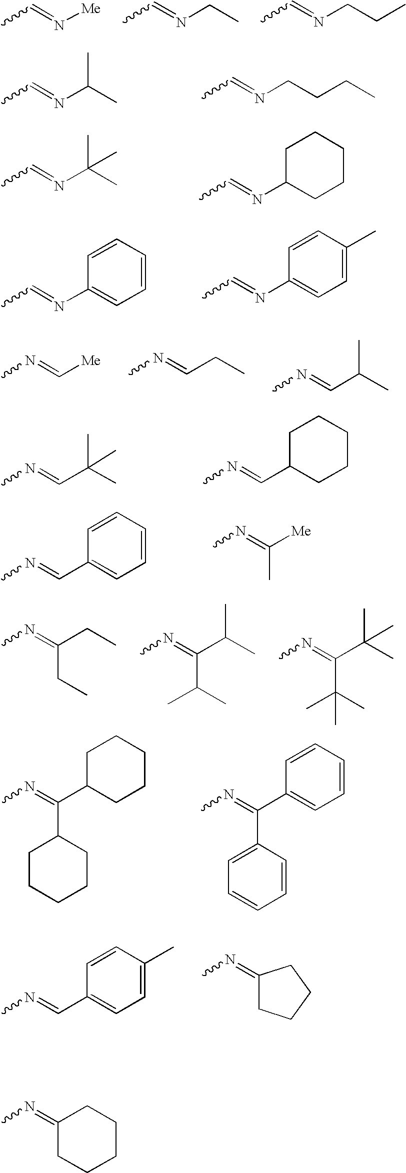

The substituted silyl group represents a silyl group substituted by 1, 2, or 3 groups selected from an alkyl group, aryl group, arylalkyl group, and monovalent heterocyclic group. The number of carbon atoms is usually about 1 to 60, and preferably 3-30. The alkyl group, aryl group, arylalkyl group, or monovalent heterocyclic group may have substituents. Examples thereof include trimethylsilyl group, triethylsilyl group, tri-n-propylsilyl group, tri-i-propylsilyl group, t-butylsilyldimethylsilyl group, triphenylsilyl group, tri-p-xylylsilyl group, tribenzylsilyl group, diphenylmethyl silyl group, t-butyldiphenylsilyl group, dimethylphenylsilyl group, etc.

The definition and the concrete examples of the divalent aliphatic hydrocarbon group and divalent aromatic hydrocarbon group in T of the above formula (6) are the same as those of the above V¹, V², and V³.

The divalent heterocyclic group means an atomic group in which two hydrogen atoms are removed from a heterocyclic compound, and the number of carbon atoms is usually about 2 to 60, and preferably 2 to 20. Substituent may be contained on the divalent heterocyclic group, and the number of carbon atoms of the substituent is not counted as the number of carbon atoms of divalent heterocycle.

As the concrete examples of the divalent heterocyclic group, the groups exemplified for the above Z¹ are exemplified.

The alkenylene group has usually about 20 to 20 carbon atoms, and examples thereof include vinylene group, propylene group, etc. The alkenylene group include alkadienylene groups, such as 1,3-butadienylene group.

The alkynylene group usually has about 2 to 20 carbon atoms, and exemples thereof include ethynylene group etc. The alkynylene group also includes a group having two triple bonds, for example, 1,3-butanediynylene group.

As the concrete example of formula (6), the following is exemplified.

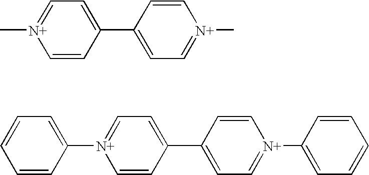

The case where the positive ion of the ion pair is a divalent positive ion represented by the above formula (6), is preferable in view of luminescence strength.

The onium of oxygen atom may be monovalent, or polyvalent such as di-valent or more, and examples thereof include trimethyl oxonium, triethyl oxonium, tripropyl oxonium, tributyl oxonium, trihexyl oxonium, triphenyl oxonium, pyrrylinium, chromenylium, and xanthylium.

The onium of phosphorus atom may be monovalent, or polyvalent such as di-valent or more, and examples thereof include tetramethyl phosphonium, tetraethyl phosphonium, tetrapropyl phosphonium, tetrabutyl phosphonium, tetrahexyl phosphonium, tetraphenyl phosphonium, triphenylmethyl phosphonium, and methyltriphenyl phosphonium.

The onium of sulfur atom may be monovalent, or polyvalent such as di-valent or more, and examples thereof include aliphatic sulfoniums, such as trimethyl sulfonium, triethyl sulfonium, tripropyl sulfonium, tributyl sulfonium, and trihexyl sulfonium; aromatic sulfoniums, such as triphenyl sulfonium, tri(4-methylphenyl)sulfonium, and tri(4-t-butyl phenyl)sulfonium, methyldiphenyl sulfonium, dimethylphenyl sulfonium, and oniums of the following formulas.

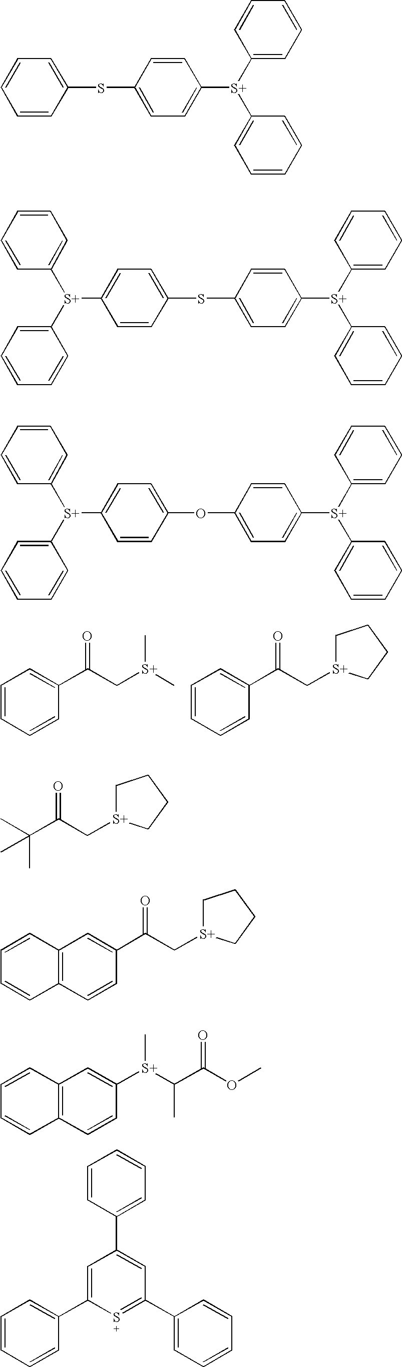

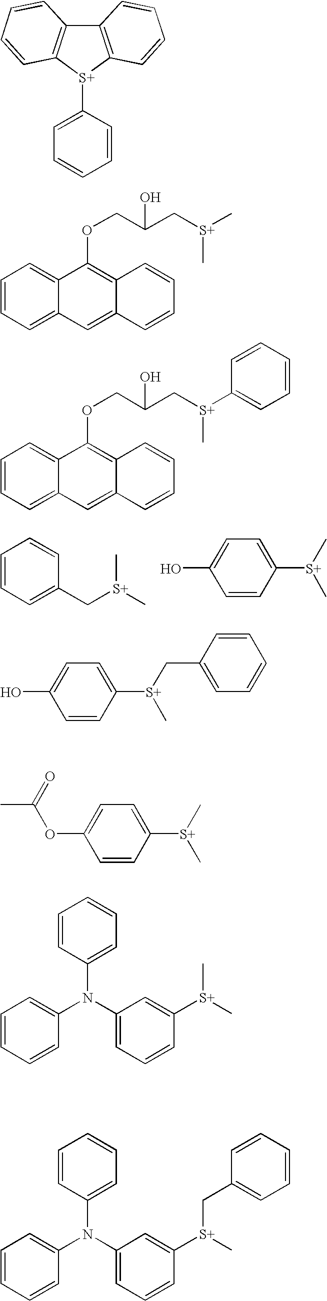

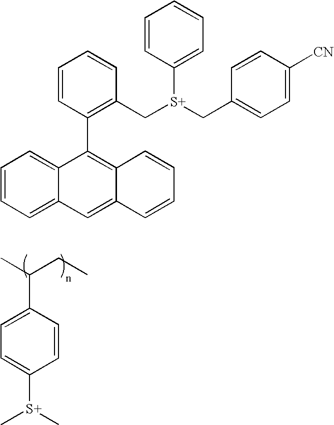

The onium of chlorine atom may be monovalent, or polyvalent such as di-valent or more, and examples thereof include dimethyl chloronium, diethyl chloronium, dipropyl chloronium, dibutyl chloronium, diphenyl chloronium, and methylphenyl chloronium.

The onium of selenium atom may be monovalent, or polyvalent such as di-valent or more, and examples thereof include trimethyl selenium, triethyl selenium, tripropyl selenium, tributyl selenium, trihexyl selenium, triphenyl selenium, tri(4-methylphenyl)selenium, tri(4-t-butyl phenyl)selenium, methyldiphenyl selenium, and dimethylphenyl selenium.

The onium of bromine atom atom may be monovalent, or polyvalent such as di-valent or more, and examples thereof include dimethyl bromonium, diethyl bromonium, dipropyl bromonium, dibutyl bromonium, diphenyl bromonium, and methylphenyl bromonium.

The onium of tellurium atom may be monovalent, or polyvalent such as di-valent or more, and examples thereof include trimethyl telluronium, triethyl telluronium, tripropyl telluronium, tributyl telluronium, trihexyl telluronium, triphenyl telluronium, tri(4-methylphenyl)telluronium, tri(4-t-butylphenyl)telluronium, methyldiphenyl telluronium, and dimethylphenyl telluronium.

The onium of iodine atom may be monovalent, or polyvalent such as di-valent or more, and examples thereof include dimethyl iodonium, diethyl iodonium, dipropyl iodonium, dibutyl iodonium, diphenyl iodonium, di(t-butylphenyl)iodonium, 4-methylphenyl-4-(1-methylethyl)phenyl iodonium, methylphenyl iodonium, or oniums of the below formulas.

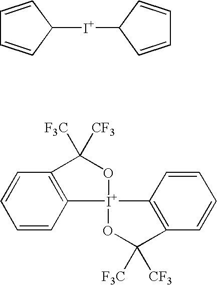

Examples of the metal cation include a cation of alkali metal, a cation of alkaline-earth metal, a cation of rare-earth element, a cation of a transition metal, etc., and they may be monovalent, or polyvalent such as di-valent or more.

Since optical quenching by heavy atom effect may occur, it is preferable that the atomic weight is less than 50.

Concrete examples of the cation of alkali metal include lithium ion, sodium ion, potassium ion, rubidium ion, cesium ion, and francium ion.

Concrete examples of the cation of alkaline earth metal include beryllium ion, magnesium ion, calcium ion, strontium ion, barium ion, (MgCl)⁺, and (MgBr)⁺ and (MgI)⁺.

Concrete examples of the cation of rare-earth elements include scandium ion and yttrium ion. Concrete examples of the cation of the transition metal include titanium ion, zirconium ion, hafnium ion, vanadium ion, chromium ion, [bis(η⁵-benzene)Cr]⁺, manganese ion, iron ion, [(η⁵-cyclopentadienyl)(η⁶-benzene)Fe]⁺, [(η⁵-cyclopentadienyl)(η⁶-toluene)Fe]⁺ and [(η⁵-cyclopentadienyl)(η⁶-1-methyl naphthalene)Fe]⁺, [(η⁵-cyclopentadienyl)(η⁶-cumene)Fe]⁺, [bis(η⁵-mesitylene)Fe]⁺, cobalt ion, nickel ion, copper ion, zinc ion, etc.

As the ion pair used for the present invention, following compounds are specifically exemplified.

As those whose positive ion is carbocation, following ion pairs are exemplified.

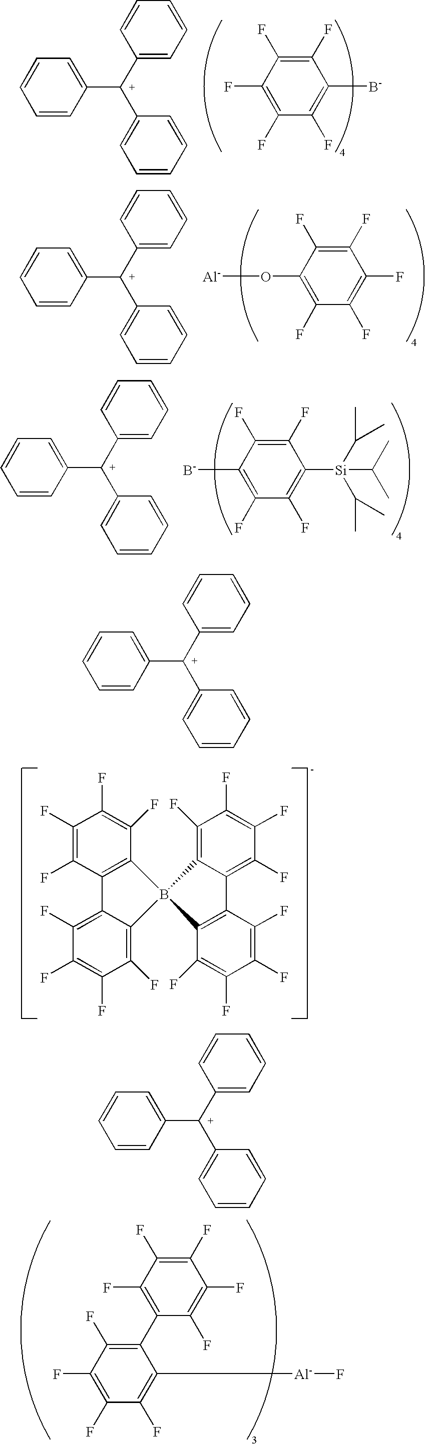

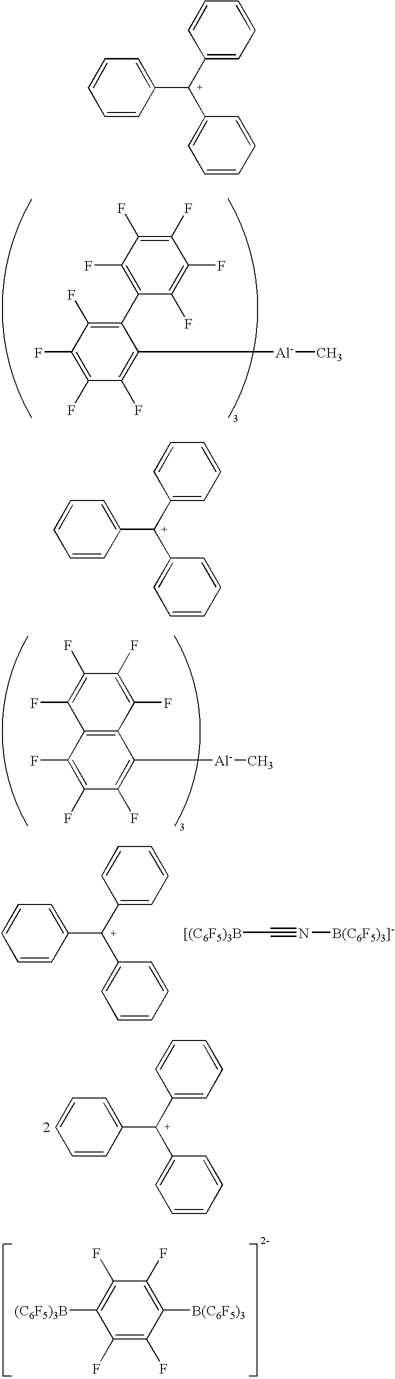

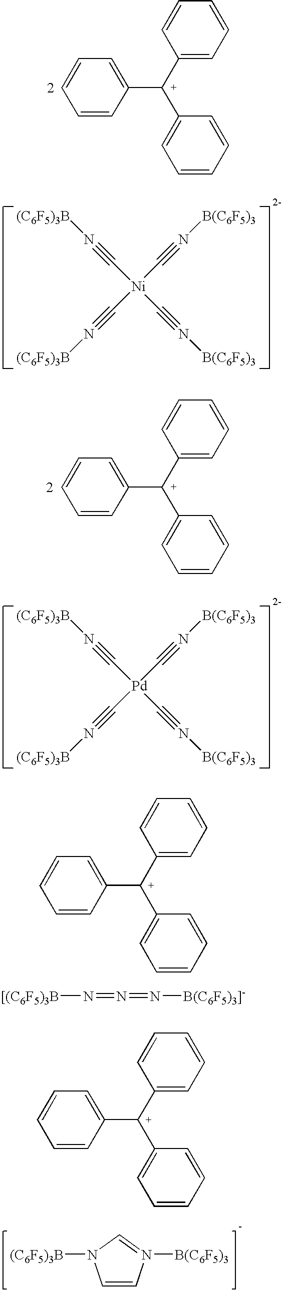

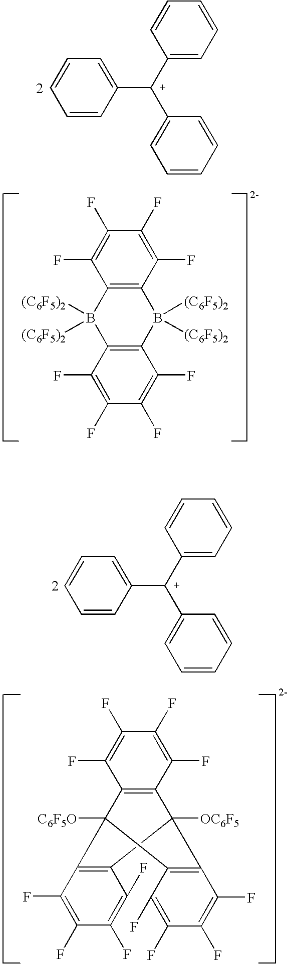

As those whose positive ion is onium of nitrogen atom, exemplifeid are those of aromatic ammonium salts, those of aliphatic ammonium salts, those of aromatic aminium salts, and those of aromatic diazonium salts. Examples of those of aromatic ammonium salts include 1-benzyl-2-cyanopyridinium tetrakis(pentafluorophenyl)borate, 1-(naphtyl methyl)-2-cyanopyridinium tetrakis(pentafluorophenyl)borate, N,N-dimethylanilinium tetrakis(pentafluorophenyl)borate, 1-butyl-3-methylimidazolium tetrakis(pentafluorophenyl)borate, 1-ethyl-3-methylimidazolium tetrakis(pentafluorophenyl)borate, 1-octyl-3-methylimidazolium tetrakis(pentafluoro phenyl)borate, tris(4-bromophenyl)aminium tetrakis(pentafluorophenyl)borate.

Examples of those of aliphatic ammonium salts include tetrabutylammonium, tetrakis(pentafluorophenyl)borate, tetraethylammonium tetrakis(pentafluorophenyl)borate.

Examples of those of aromatic aminium salts include tris(4-bromophenyl)aminium, tetrakis(pentafluorophenyl)borate, N,N,N′,N′-tetraphenyl-4,4′-biphenylene diaminium bis(tetrakis(pentafluorophenyl)borate).

Examples of those of aromatic diazonium salts include phenyldiazonium tetrakis(pentafluorophenyl)borate.

Examples of those of aromatic ammonium salts include new compounds represented by the below formula (10). 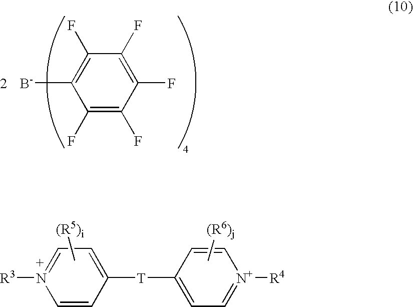
wherein, R³, R⁴, R⁵, R⁶, and T represent the same meaning as the above.

Compounds represented by the above formula (10), the following compounds are exemplified.

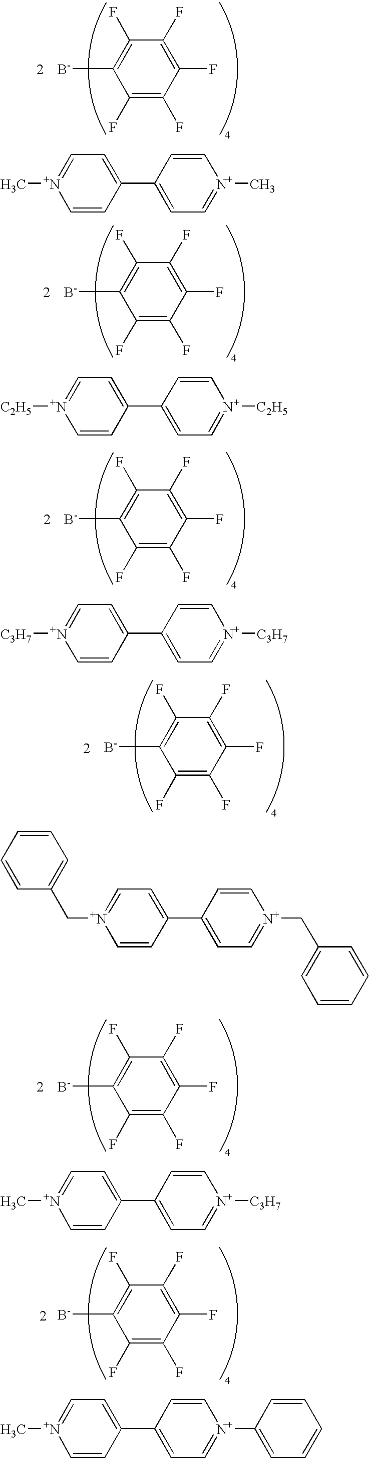

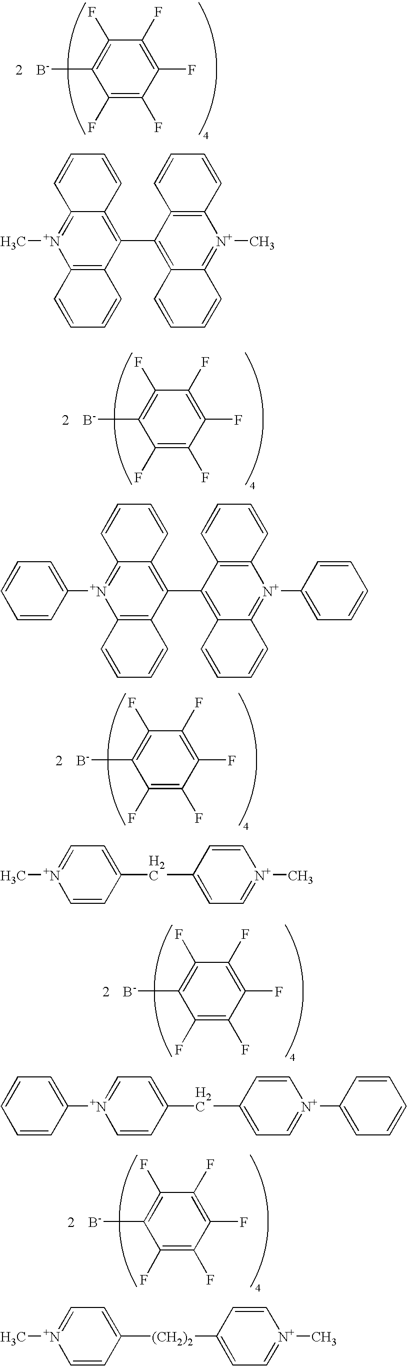

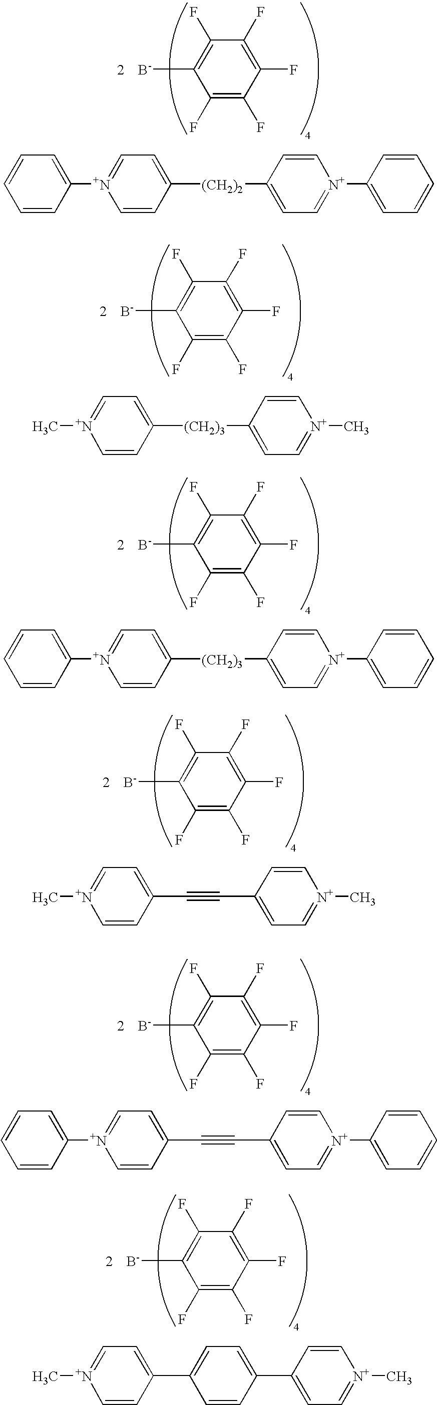

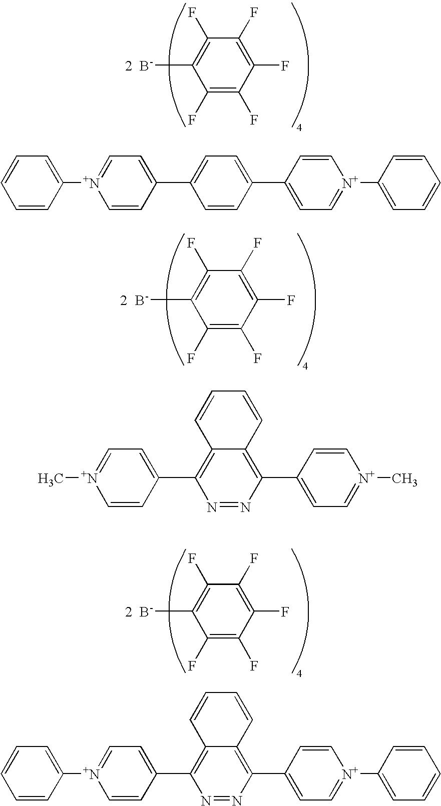

Compounds represented by formula (10) can be produced, for example, by reacting a compound represented by the below formula (11), with Li[B(C₆F₅)₄].n(Et₂O). 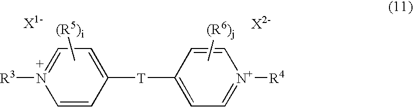
[wherein R³, R⁴, R⁵, R⁶ and T represent the same meaning as above. X¹⁻ and X²⁻ each independently represent a halide ion, alkylsulfonate ion, and arylsulfonate ion.]

As the halide ion, fluoride ion, chloride ion, bromide ion, and iodide ion are exemplified.

As the alkylsulfonate ion, methanesulfonate ion, ethane sulfonate ion, and trifluoromethanesulfonate ion are exemplified.

As the arylsulfonate ion, benzenesulfonate ion and p-toluenesulfonate ion are exemplified.

As those of the aromatic ammonium salts, the following ion pairs are additionally exemplified.

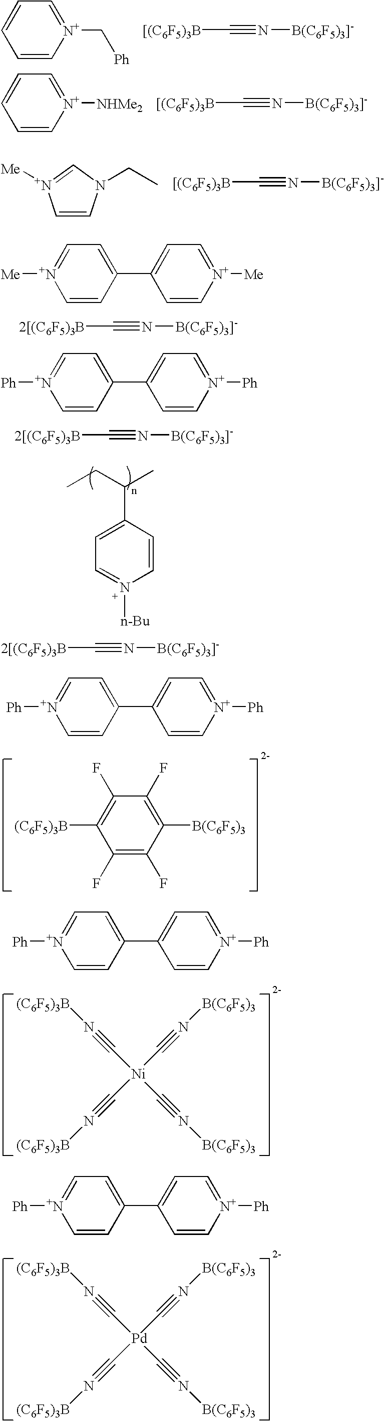

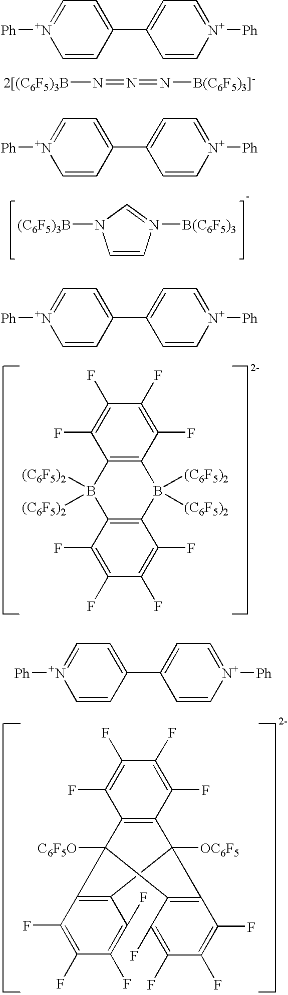

As those of the aliphatic ammonium salts, the following ion pairs are additionally exemplified.

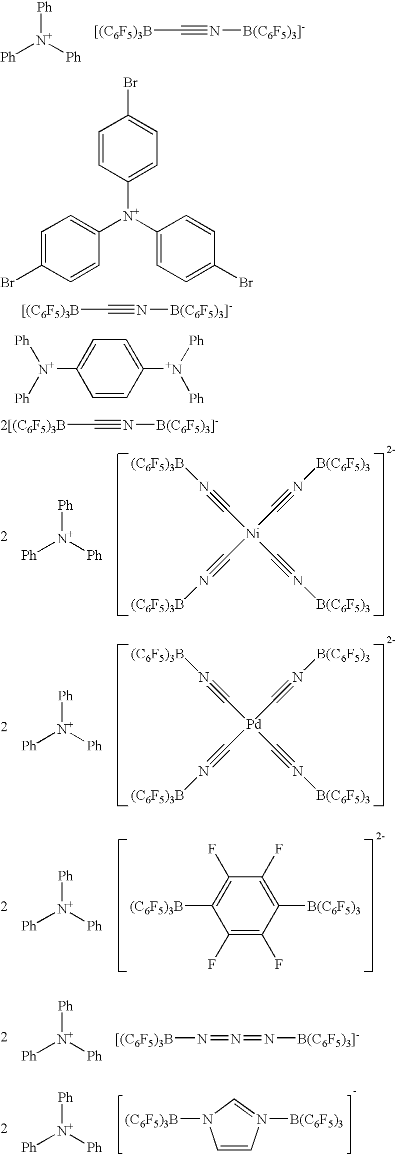

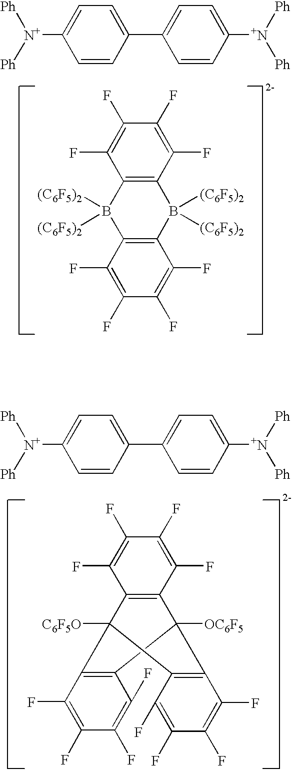

As those of the aromatic aminium salts, the following ion pairs are additionally exemplified.

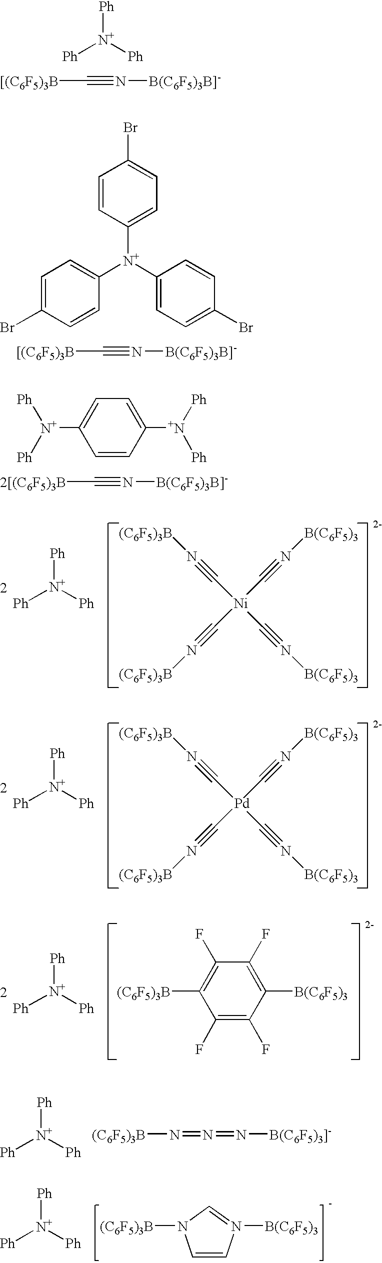

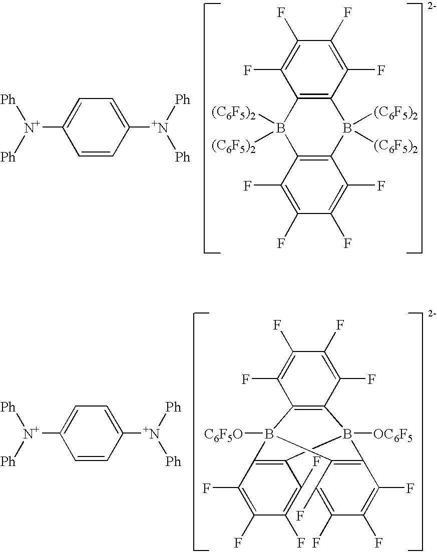

As those of the aromatic diazonium salts, the following ion pairs are additionally exemplified.

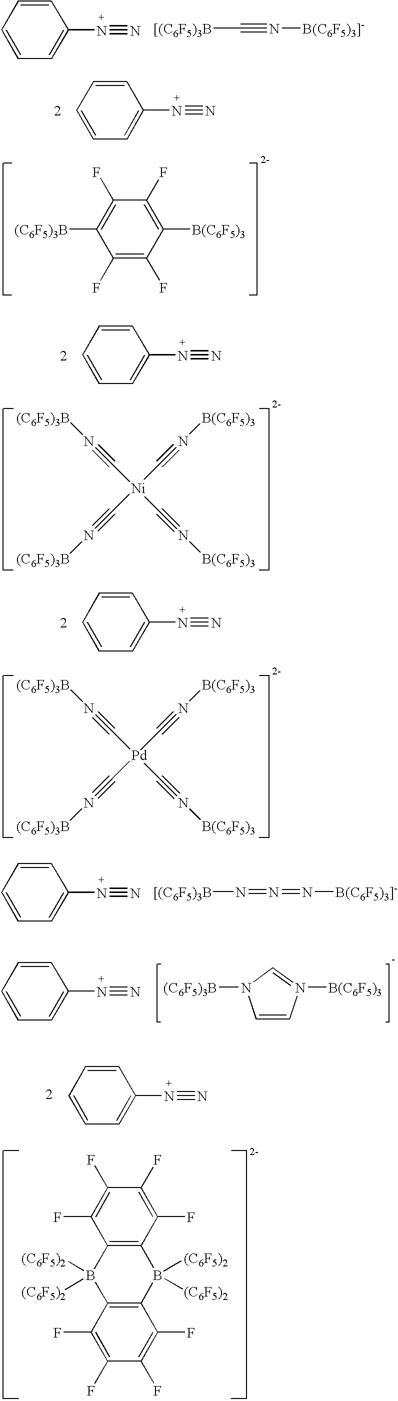

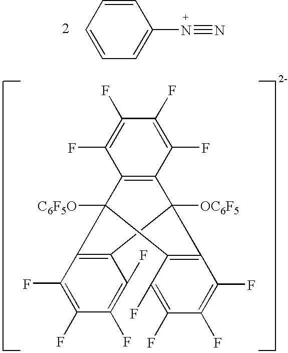

As those whose positive ion is onium of phosphorus atom, tetraphenylphosphonium tetrakis(pentafluorophenyl)borate is exemplified. As those whose positive ion is onium of phosphorus atom, the following ion pairs are additionally exemplified.

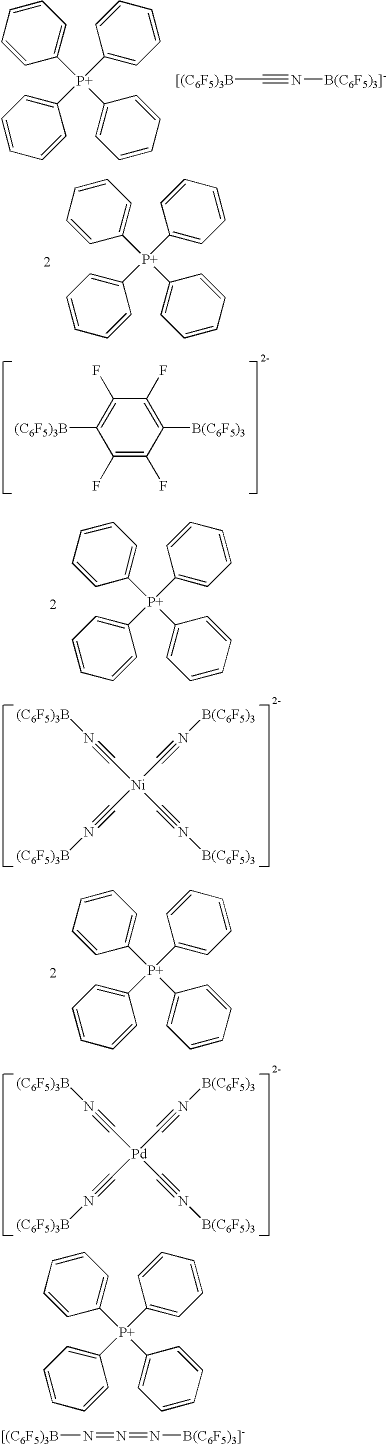

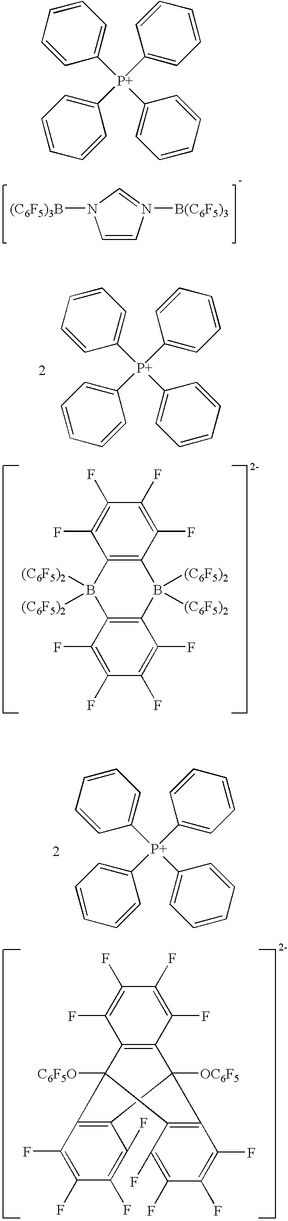

As those whose positive ion is onium of sulfur atom, those of aromatic sulfonium salts are exemplified. Examples thereof include bis[4-(diphenylsulfonio)phenyl]sulfide tetrakis (pentafluorophenyl)borate, diphenyl-4-(phenylthio)phenyl sulfonium tetrakis(pentafluorophenyl)borate, triphenyl sulfonium tetrakis(pentafluorophenyl)borate, bis[4-(di(4-(2-hydroxyethoxy))phenylsulfonio)phenyl]sulfide tetrakis (pentafluorophenyl)borate. As those whose positive ion is onium of sulfur atom, the following ion pairs are additionally exemplified.

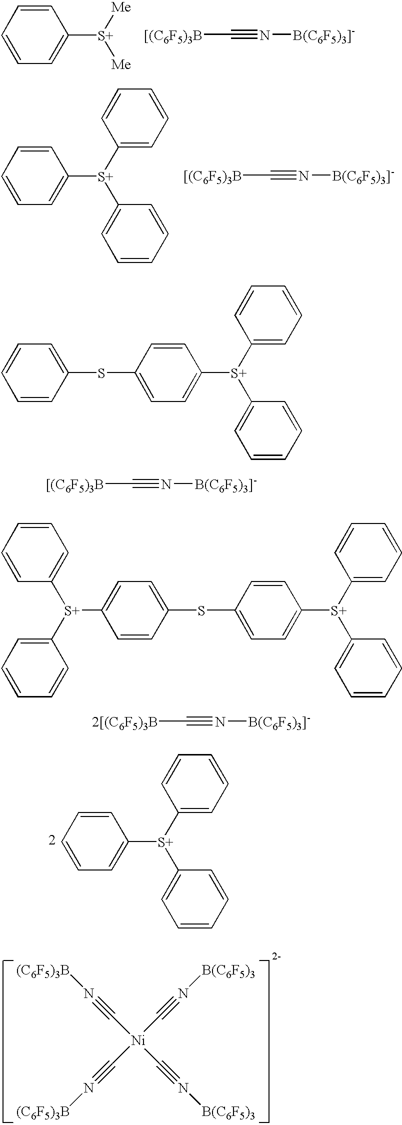

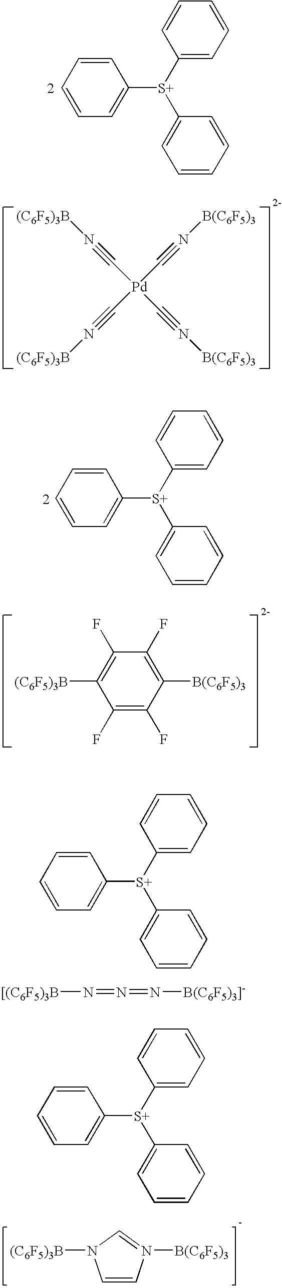

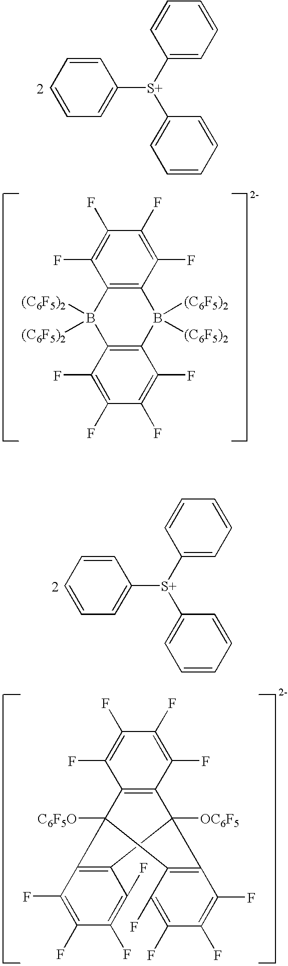

As those whose positive ion is onium of iodine atom, those of aromatic iodonium salts are exemplified. Examples thereof include diphenyl iodonium tetrakis(pentafluorophenyl)borate, bis(dodecyl phenyl)iodonium tetrakis(pentafluorophenyl)borate, 4-methylphenyl-4-(1-methylethyl)phenyl iodonium tetrakis(pentafluorophenyl)borate [“Rhodrsil photoinitiator PI-2074” light polymerization initiator, commercially available by Rhodia]. As those whose positive ion is onium of iodine atom, the following ion pairs are additionally exemplified.

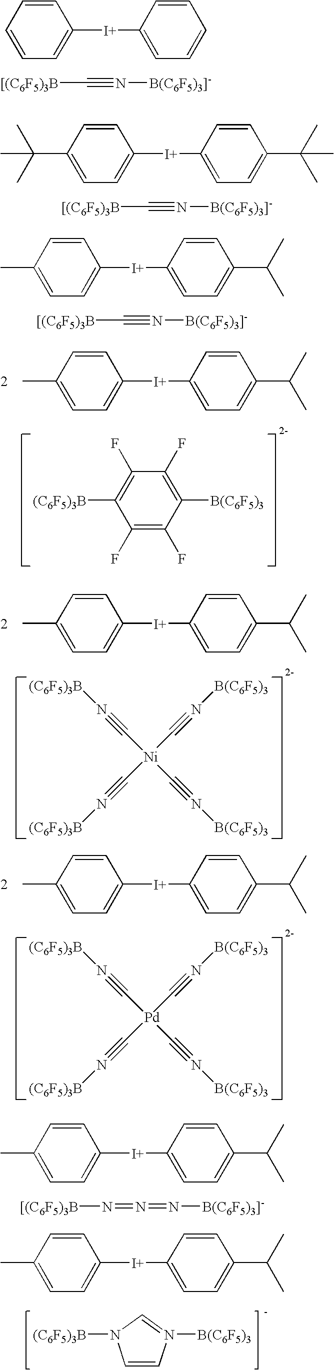

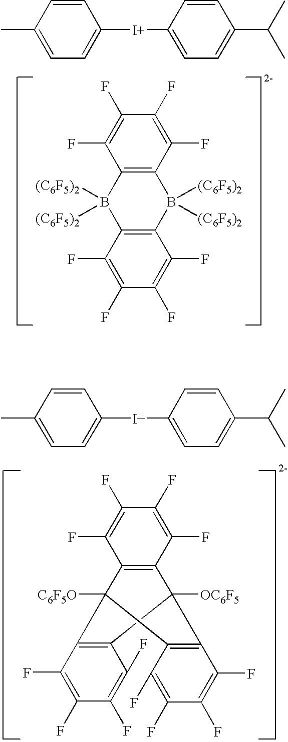

As those whose positive ion is a metal cation, examples thereof include (2,4-cyclopentadiene-1-yl)[(1-methyl ethyl)benzene]-Fe(II) tetrakis(pentafluorophenyl)borate. As those whose positive ion is a metal cation, the following ion pairs are additionally exemplified.

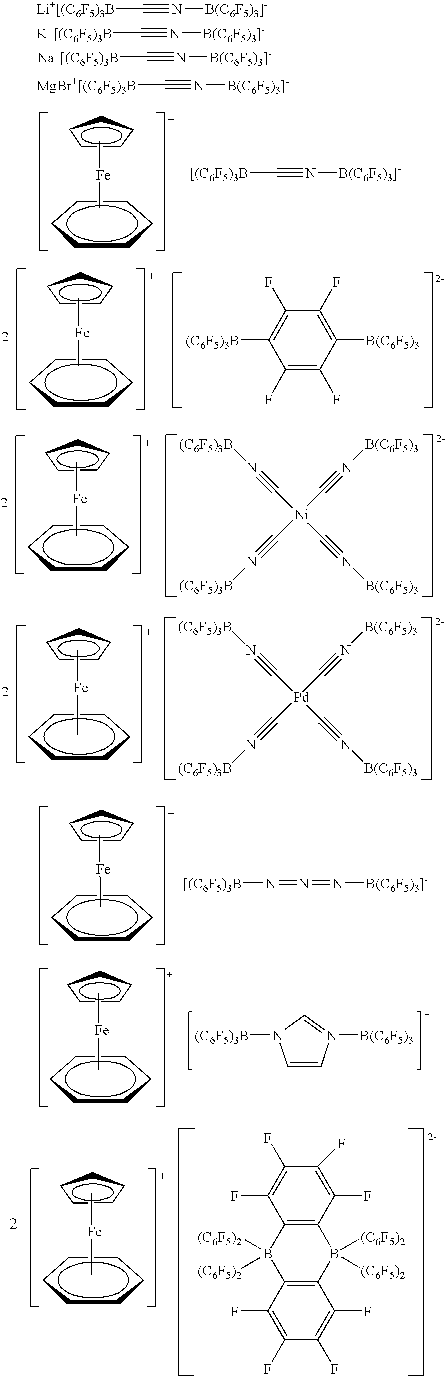

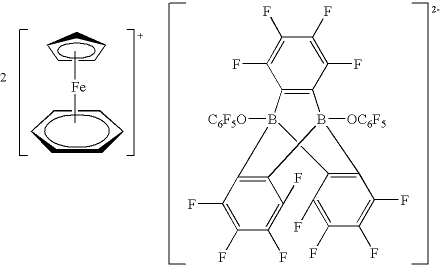

The present invention provides a new ion pair wherein the negative ion is represented by the following structural formula (5-1), and the positive ion is a pyridinium cation, a phosphonium cation, or a iodonium cation.
[(C₆F₅)₃B—C≡N—B(C₆F₅)₃]⁻ (5-1)

Concrete examples are shown below.

As the ion pair whose positive ion is a pyridinium cation, the following compounds are exemplified.

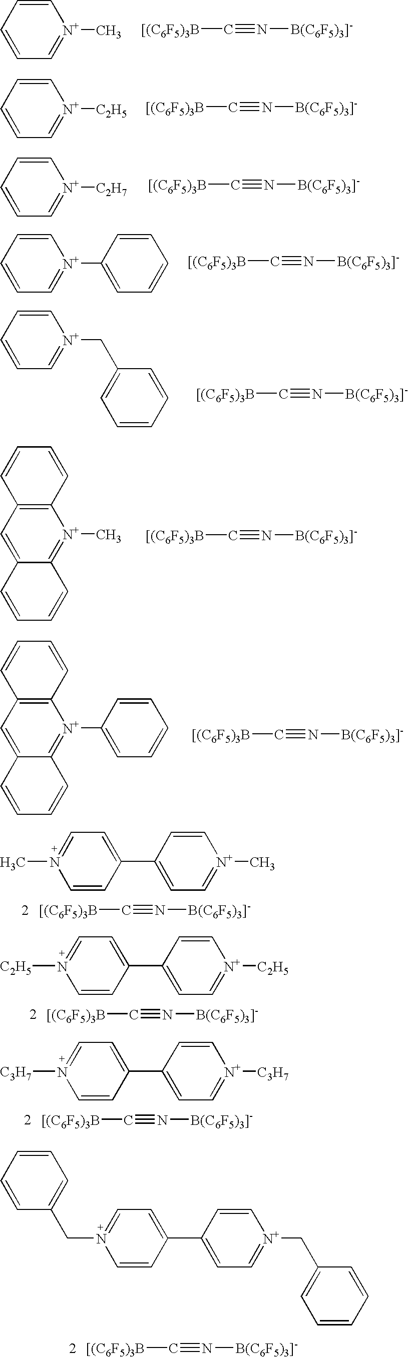

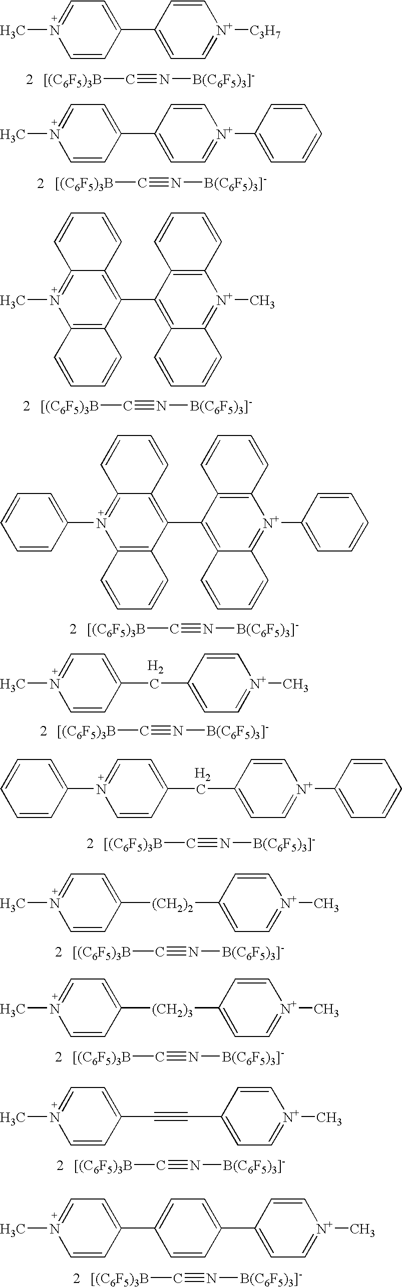

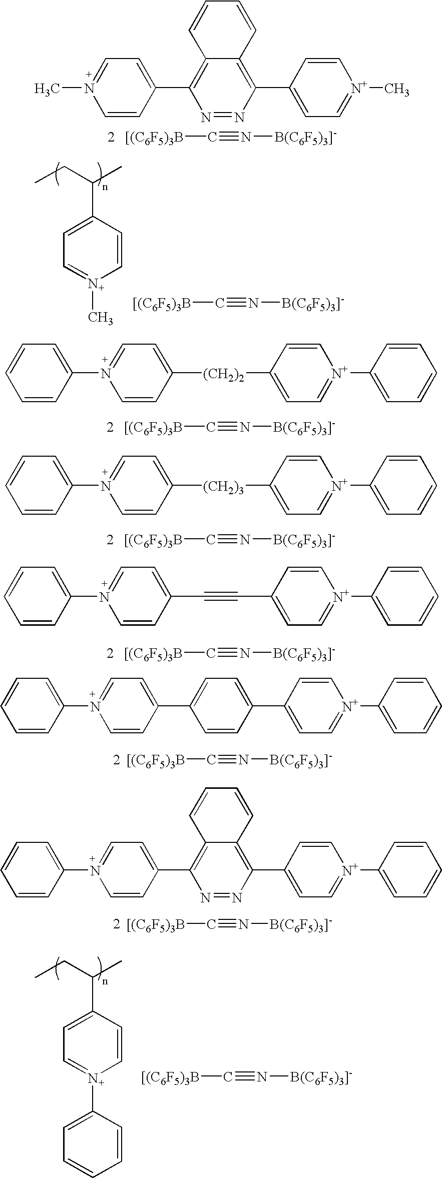

As the ion pair whose positive ion is a phosphonium cation, the following compounds are exemplified.

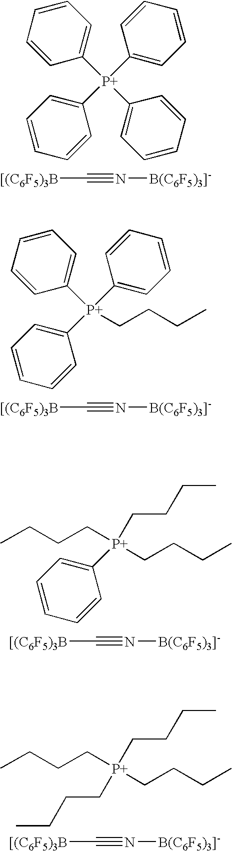

As the ion pair whose positive ion is a iodonium cation, the following compounds are exemplified.

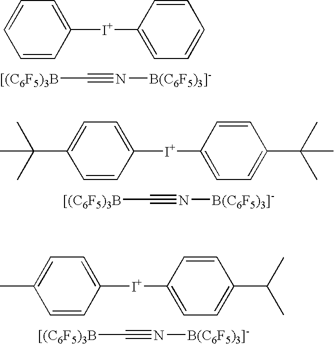

The above pyridinium salt, phosphonium salt, and iodonium salt can be produced, for example, by reacting a compound represented by the below formula (7-1), with K[(C₆F₅)₃B—C≡N—B(C₆F₅)₃] represented by the below formula (7-1).
E¹⁺X¹⁻ (7-1)
wherein, E¹⁺ represents a pyridinium cation, a phosphonium cation, or a iodonium cation. X¹⁻ represents a halide ion, alkylsulfonate ion, and arylsulfonate ion.

As the halide ion, fluoride ion, chloride ion, bromide ion, and iodation thing ion are exemplified.

As the alkylsulfonate ion, methanesulfonate ion, ethane sulfonate ion, and trifluoromethanesulfonate ion are exemplified.

As the arylsulfonate ion, benzene sulfonate ion and p-toluene sulfonate ion are exemplified.

The present invention provides a new ion pair wherein the negative ion is represented by the following structural formula (5-2), and the positive ion is a pyridinium cation, a quarternary ammonium cation, a phosphonium cation, an oxonium cation, a sulfonium cation, or a iodonium cation.
[M{C≡N—B(C₆F₅)₃}₄]²⁻ (5-22)
(wherein, M represents a nickel atom or a palladium atom.)

Concrete examples are shown below.

As the ion pair whose positive ion is a pyridinium cation, the following compounds are exemplified.

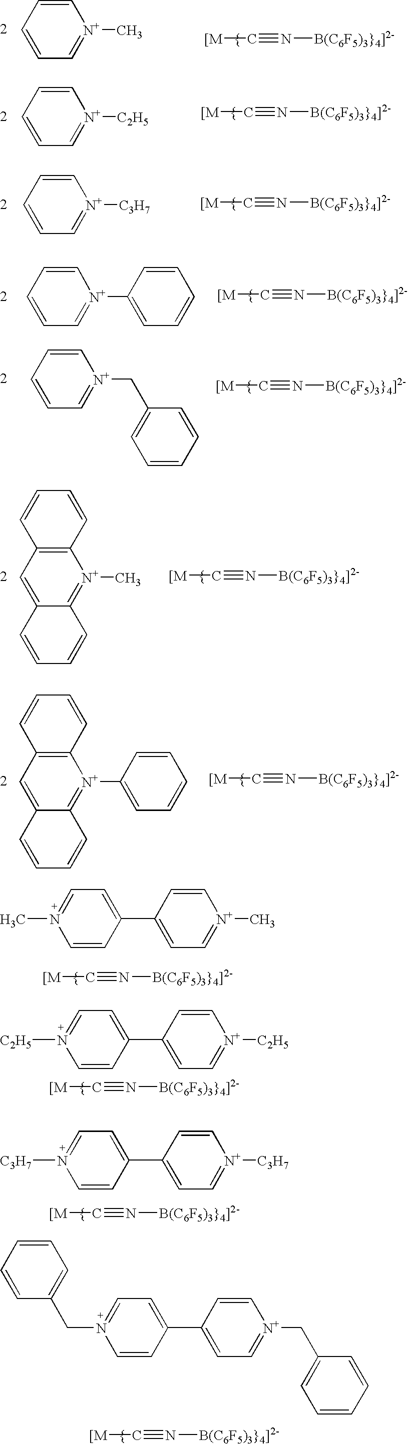

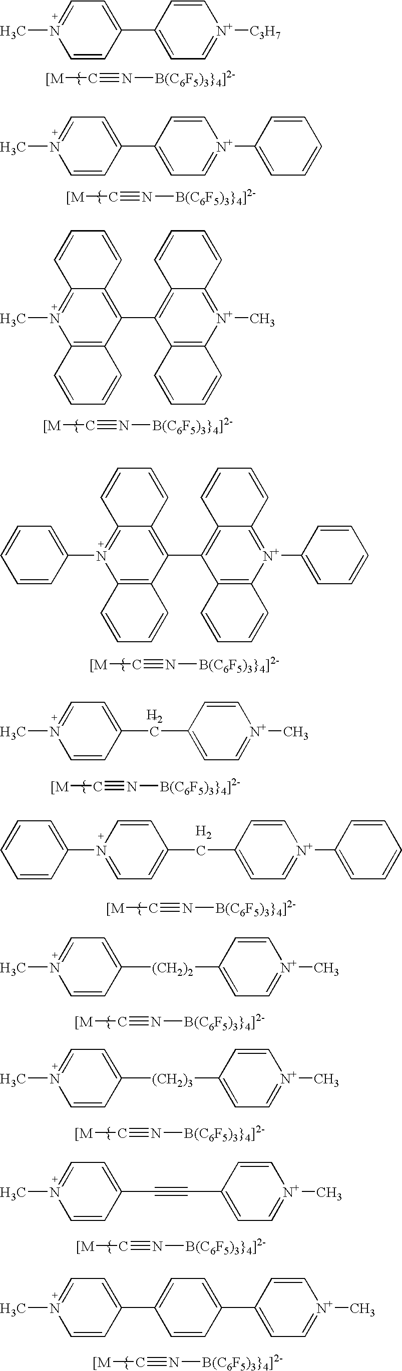

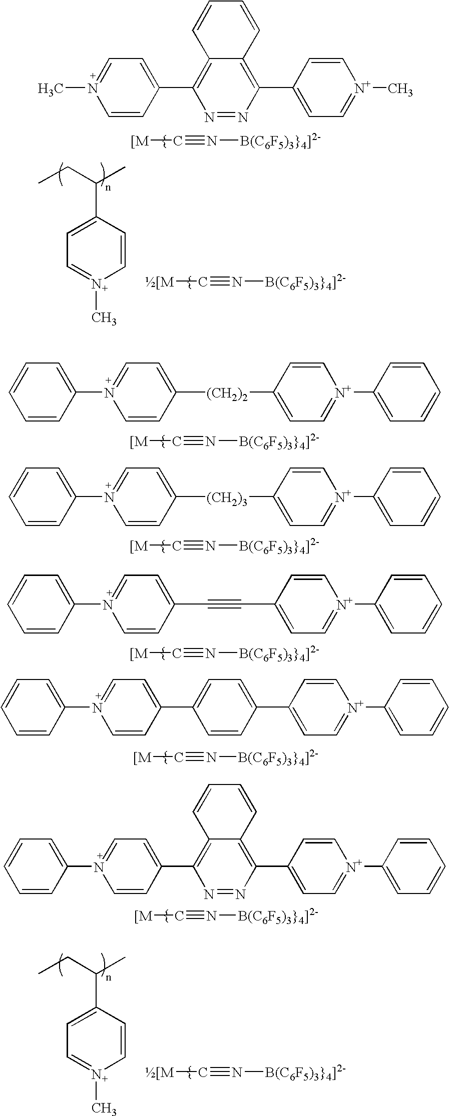

As the ion pair whose positive ion is a quarternary ammonium cation, the following compounds are exemplified.

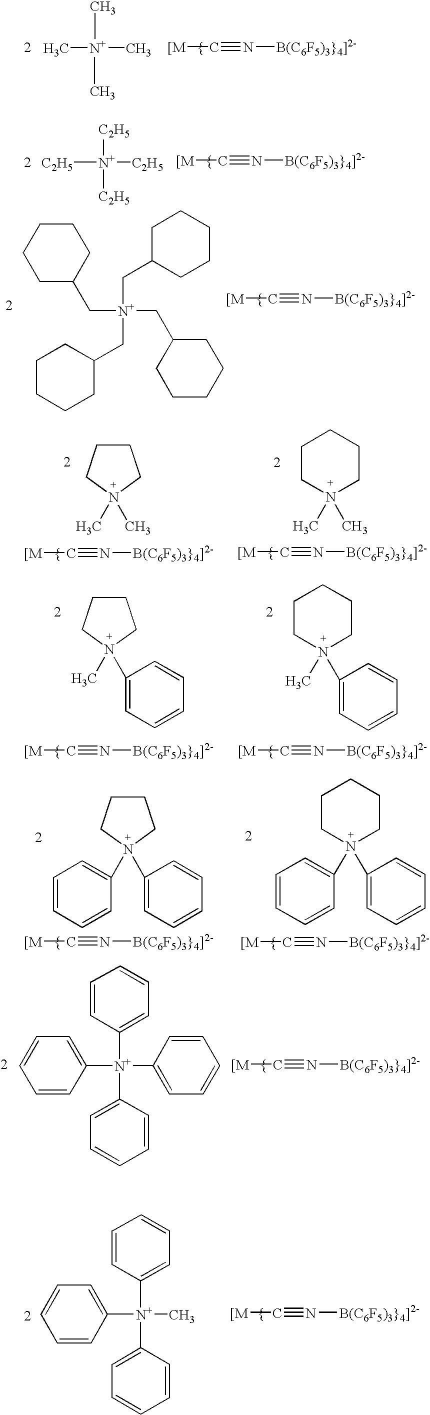

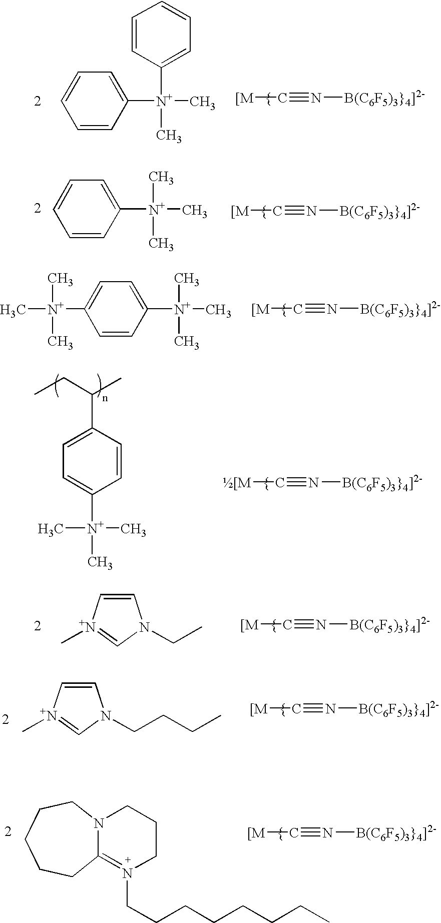

As the ion pair whose positive ion is a phosphonium cation, the following compounds are exemplified.

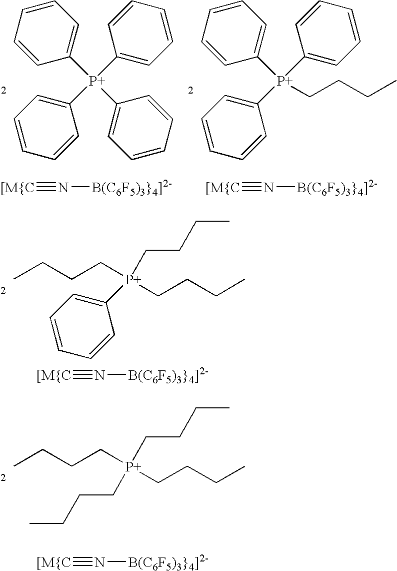

As the ion pair whose positive ion is a oxonium cation, the following compounds are exemplified.

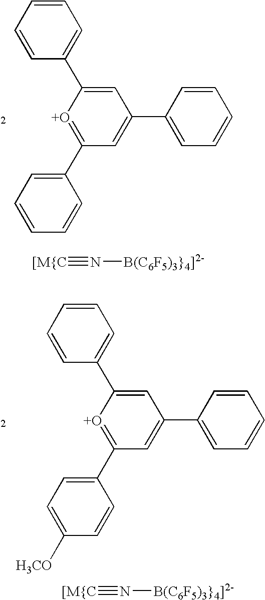

As the ion pair whose positive ion is a sulfonium cation, the following compounds are exemplified.

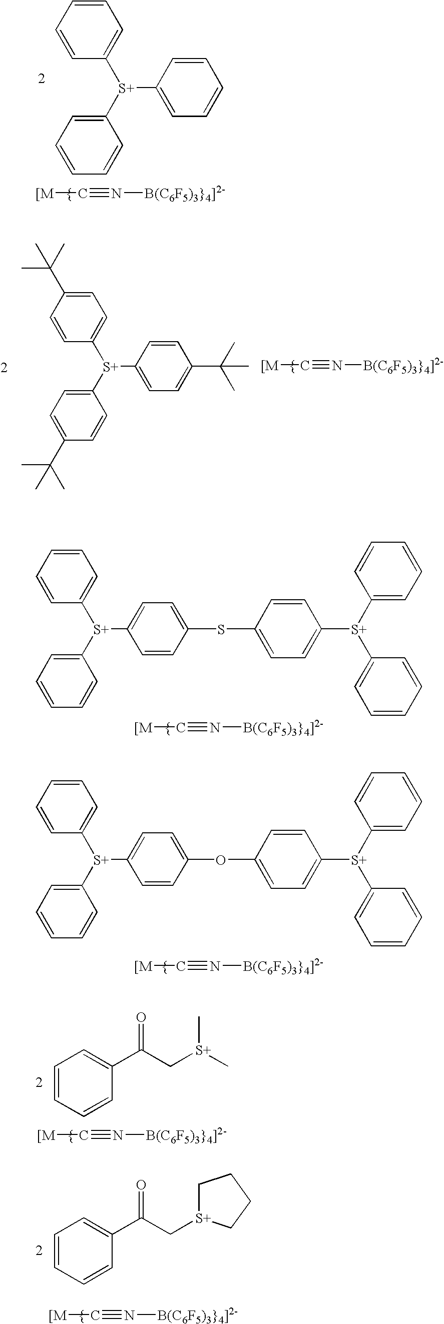

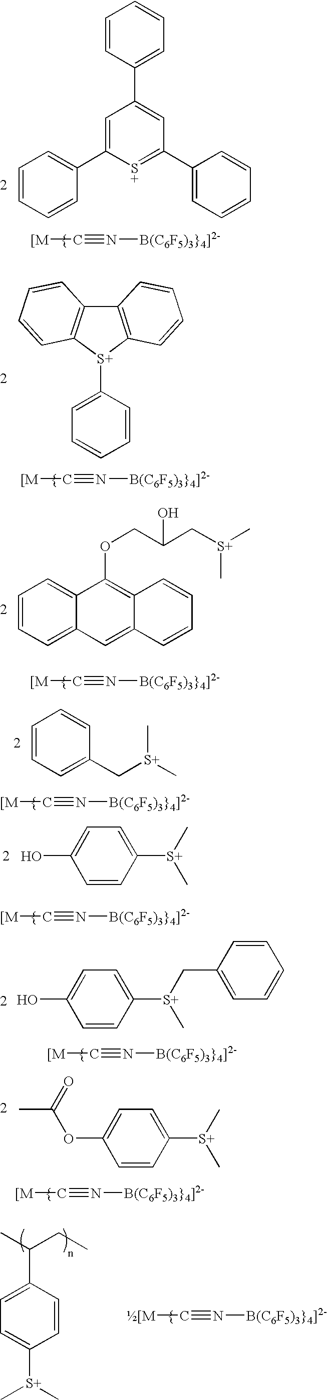

As the ion pair whose positive ion is a iodonium cation, the following compounds are exemplified.

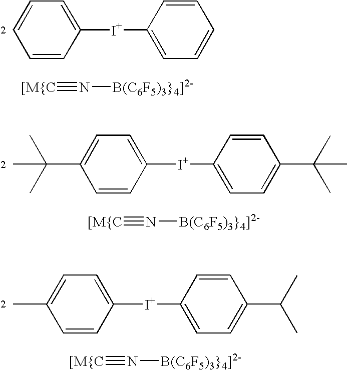

The above pyridinium salt, phosphonium salt, and iodonium salt can be produced, for example, by reacting a compound represented by the below formula (7-2), with K₂[M{C≡N—B(C₆F₅)₃}₄]
E²⁺X²⁻ (7-2)
wherein, E²⁺ represents a pyridinium cation, a quarternary ammonium cation, a phosphonium cation, an oxonium cation, a sulfonium cation, or a iodonium cation. X²⁻ represents a halide ion, alkylsulfonate ion, and arylsulfonate ion.

As the concrete examples of the halide ion, alkylsulfonate ion, and arylsulfonate ion, the ions for the above X¹⁻ can be exemplified.

In the present invention, the ion pair added to the light-emitting polymer composition may be any of one kind or 2 kinds or more.

Next, the light-emitting polymer used for the present invention is explained.

The polystyrene reduced number average molecular weight of the light-emitting polymer used for the present invention is usually 10³-10⁸. Among the light-emitting polymer of the present invention, a conjugated polymer compound is preferable. The conjugated polymer compound means a polymer compound where delocalized π electron pair exists along with the main-chain of the polymer compound. As the delocalized electron, an unpaired electron or an isolated electron pair may participate in the resonance instead of a double bond.

The light-emitting polymer used for the present invention may be a homopolymer of a copolymer, and examples thereof include: polyfluorene [for example, Jpn. J. Appl. Phys., volume 30, L1941 (1991)]; poly-paraphenylene [for example, Adv. Mater., volume 4, page 36 (1992)]; polyarylenes such as polypyrrol, polypyridine, polyaniline, polythiophene, etc.; polyarylenevinylenes, such as poly para-phenylenevinylene and poly thienylenevinylene (for example, WO 98/27136); polyphenylene sulfide, polycarbazole, etc.

[for example, “Advanced Materials vol. 12 1737-1750 (2000) and “Organic EL Display Technology, Monthly Display, December issue, P. 68-73”]

Among them, the light-emitting polymer of polyarylene type is preferable.

As the repeating unit contained in the light-emitting polymer of polyarylenes, an arylene group and a divalent heterocyclic group are exemplified, and those consisting of these repeating units 20-100% by mole is preferable, and those consisting of 50-99% by mole is more preferable.

The number of carbon atoms constituting the ring of the arylene group is usually about 6 to 60. Concrete examples thereof include phenylene group, biphenylene group, terphenylene group, naphthalenediyl group, anthracenediyl group, phenanthrenediyl group, pentalene-diyl group, indene diyl group, heptalenediyl group, indacenediyl group, triphenylenediyl group, binaphthyldiyl group, phenyl naphthylenediyl group, stilbenediyl group, fluorenediyl group (for example, the case where A=—C(R′)(R′)— in the below formula (4)).

The number of carbon atoms constituting the ring of the divalent heterocyclic group is usually about 3 to 60. Concrete examples thereof include pyridinediyl group, diazaphenylene group, quinolinediyl group, quinoxalinediyl group, acridine diyl group, bipyridyldiyl group, phenanthrolinediyl group, and in the below formula (4), the case where they are X=—O—, —S—, —Se—, —NR″—, —C(R′)(R′)—, or —Si(R′)(R′)—.

Furthermore, the case where the repeating unit shown by a below formula (4) is contained, is preferable. 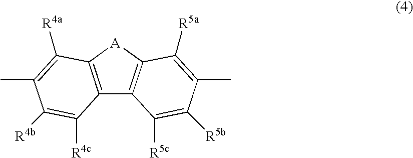
(wherein, A represents an atom or an atomic group for forming the 5 membered ring or 6 membered ring together with 4 carbon atoms on two benzene rings of the formula; R^{4a}, R^{4b}, R^{4c}, R^{5a}, R^{5b}, and R^{5c} each independently represent a hydrogen atom, a halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, acyl group, acyloxy group, amide group, acidimide group, imine residue, substituted amino group, substituted silyl group, substituted silyloxy group, substituted silylthio group, substituted silylamino group, cyano group, nitro group, monovalent heterocyclic group, heteroaryloxy group, hetero arylthio group, alkyloxy carbonyl group, aryloxy carbonyl group, arylalkyloxy carbonyl group, heteroaryloxy carbonyl group, or carboxyl group; R^{4b} and R^{4c}, and R^{4b} and R^{5c} may respectively form a ring, together.).

A represents an atom or an atomic group for forming the 5 membered ring or 6 membered ring together with 4 carbon atoms on two benzene rings of the formula, and concrete examples thereof include the followings without being limited.

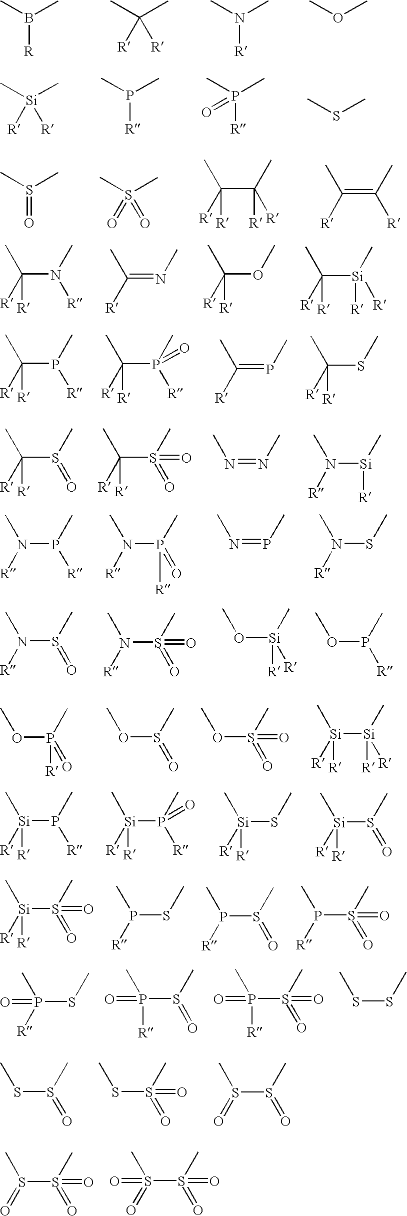

wherein, R and R′ and R″ each independently represent a halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, acyloxy group, substituted amino group, substituted silyloxy group, substituted silylthio group, substituted silylamino group, cyano group, or monovalent heterocyclic group. R′ each independently represents a hydrogen atom, halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, acyl group, acyloxy group, amide group, acid imide group, imine residue, substituted amino group, substituted silyl group, substituted silyloxy group, substituted silylthio group, substituted silylamino group, cyano group, nitro group, or monovalent heterocyclic group. R″ each independently represents a hydrogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, acyl group, substituted silyl group, substituted silyloxy group, substituted silylthio group, substituted silylamino group, or monovalent heterocyclic group.

As the halogen atom, alkyl group, the alkyloxy group, alkylthio group, aryl group, aryloxy group, arylthio group, Arylalkyl group, the arylalkyloxy group, the arylalkylthio group, Alkenyl group, alkynyl group, the arylalkenyl group, the arylalkynyl group, substituted silyl oxy group, substituted silylthio group, substituted silylamino group, substituted amino group, amide group, acid imide group, acyl group, the acyloxy group, and a monovalent heterocyclic group in R, R′, and R″, the definition and the concrete examples are the same as those of the above R³, R⁴, R⁵, and R⁶.

Among A, —O—, —S—, —Se—, —NR″—, —CR′R′— and —SiR′R′— are preferable, and —O—, —S—, and —CR′R′— are more preferable.

The halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, acyl group, acyloxy group, amide group, acid imide group, imine residue, substituted amino group, substituted silyl group, substituted silyloxy group, substituted silylthio group, substituted silylamino group, cyano group, nitro group, monovalent heterocyclic group, heteroaryloxy group, hetero arylthio group, alkyloxycarbonyl group, aryloxycarbonyl group, arylalkyloxy carbonyl group, and heteroaryloxy carbonyl group in R^{4a}, R^{4b}, R^{4c}, R^{5a}, R^{5b}, R^{5c}, are the same as those of the above.

As the repeating unit represented by the above formula (4), the following structures are exemplified. 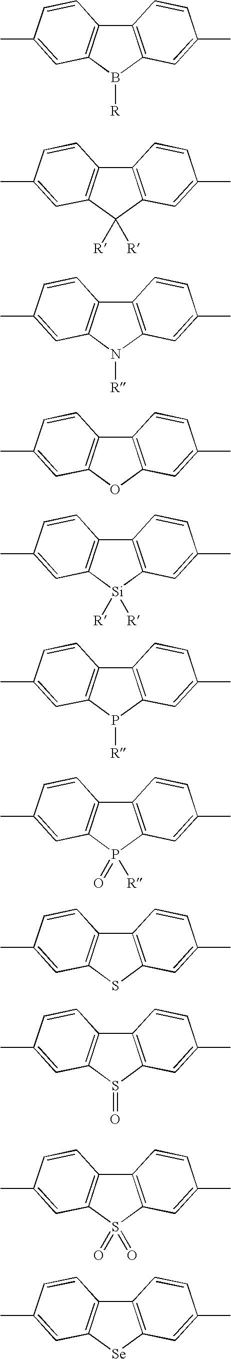 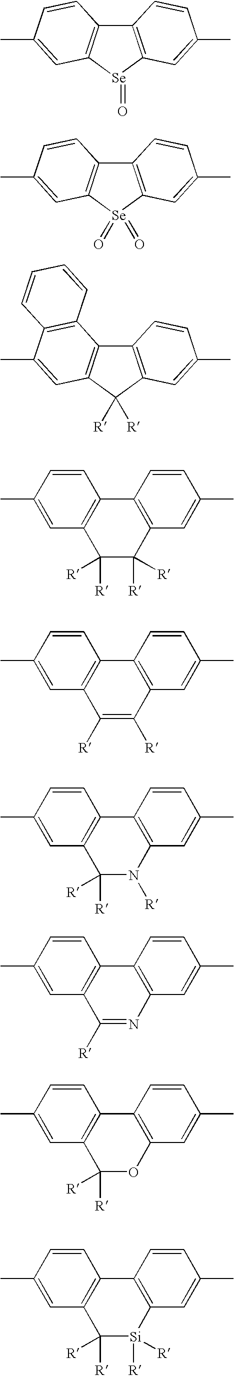 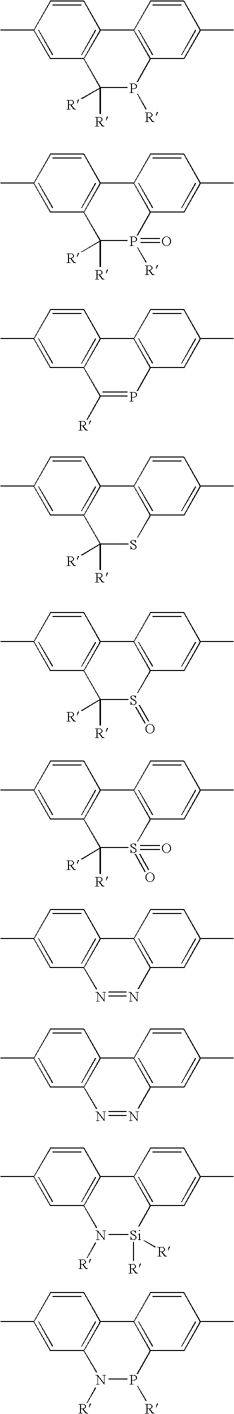 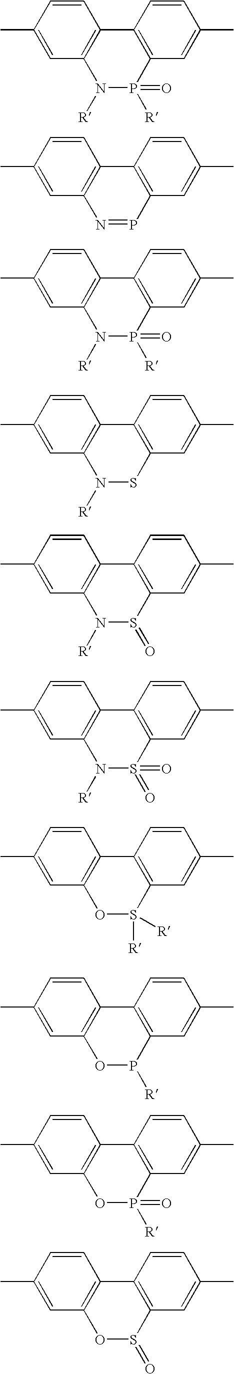 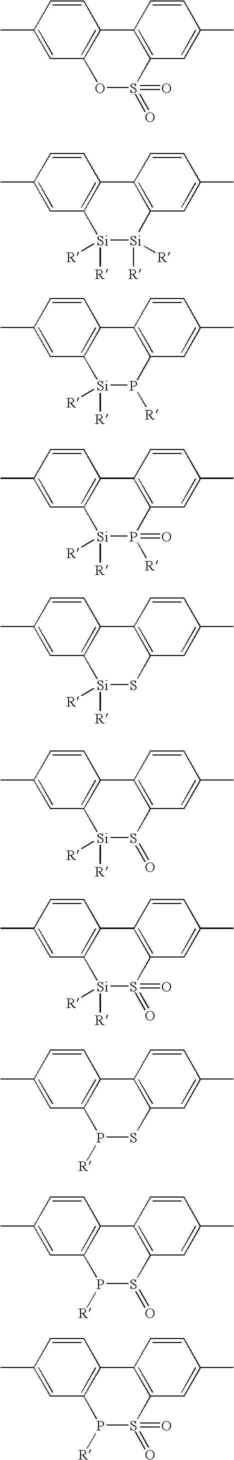 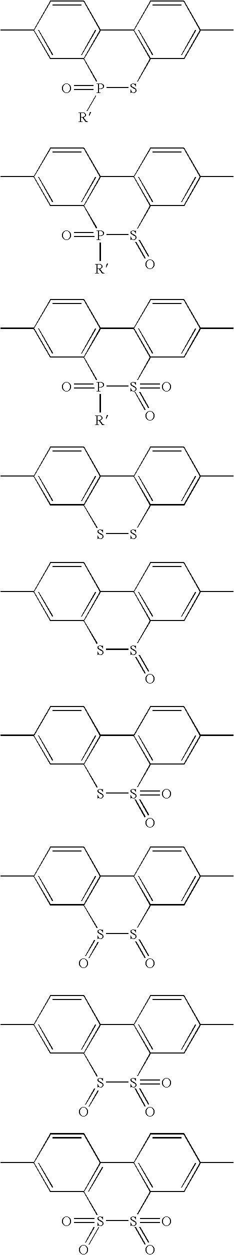
wherein, the hydrogen atom on benzene ring may be replaced with a halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, acyl group, acyloxy group, amide group, acid imide group, imine residue, substituted amino group, substituted silyl group, substituted silyloxy group, substituted silylthio group, substituted silylamino group, cyano group, nitro group, or monovalent heterocyclic group. When two substituents exist in the adjacent position of the benzene ring, they may be connected to form a ring.

The light-emitting polymer used for the present invention may comprise a repeating unit, for example, derived from an aromatic amine, besides the arylene group and the divalent heterocyclic group. In this case, a hole injection property and transportation property can be afforded.

In this case, the molar ratio of the repeting group consisting of an arylene group and a divalent heterocyclic group to the repeating unit derived from an aromatic amine is usually 99:1-20:80.

As the repeating unit derived from aromatic amine, the repeating units represented by the below formula (8) are preferable.

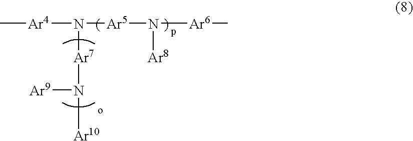

wherein, Ar⁴, Ar⁵, Ar⁶, and Ar⁷ each independently represent an arylene group or a divalent heterocyclic group. Ar⁸, Ar⁹, and Ar¹⁰ each independently represent an aryl group or a monovalent heterocyclic group. o and p each independently represent 0 or 1, and 0<=o+p<=2.

Here, the definition and the concrete examples of the arylene group and divalent heterocyclic group are the same as those of the above T. The definition and the concrete examples of the aryl group and monovalent heterocyclic group are the same as those of the above X¹ and X².

As a concrete example of the repeating unit represented by the above formula (8), the following structures are exemplified. 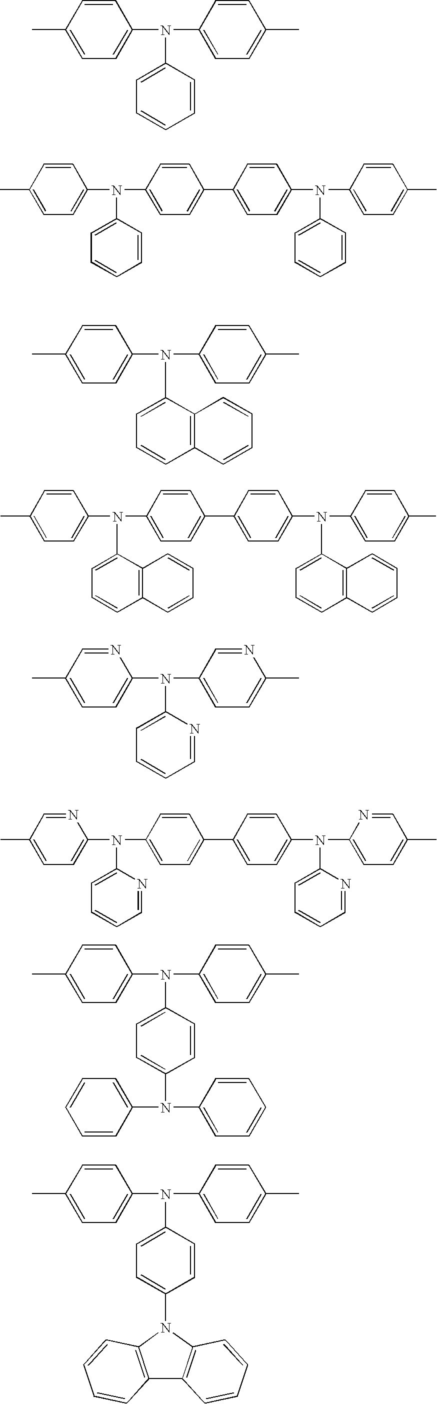 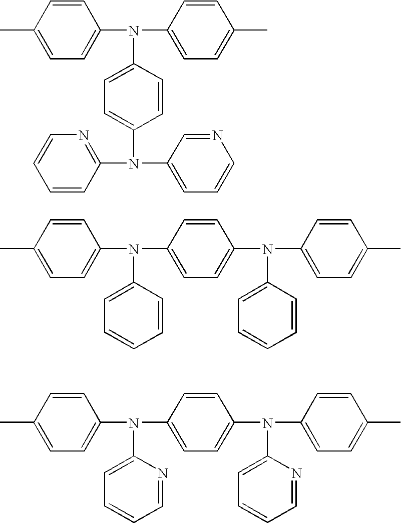
wherein, the hydrogen atom on the aromatic ring may be replaced by a halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, acyl group, acyloxy group, amide group, acid imide group, imine residue, substituted amino group, substituted silyl group, substituted silyloxy group, substituted silylthio group, substituted silylamino group, cyano group, nitro group, monovalent heterocyclic group, heteroaryloxy group, hetero arylthio group, alkyloxy carbonyl group, aryloxy carbonyl group, arylalkyloxycarbonyl group, heteroaryloxycarbonyl group, and carboxyl group.

Among the repeating unit represented by the above formula (8), the repeating units represented by the below formula (9) are especially preferable. 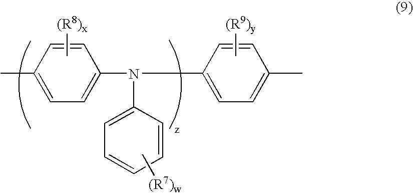
wherein, R7, R8, and R9 each independently represent a halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, The arylalkynyl group, acyl group, the acyloxy group, amide group, acid imide group, imine residue, substituted amino group, substituted silyl group, substituted silyloxy group, substituted silylthio group, substituted silylamino group, cyano group, nitro group, monovalent heterocyclic group, heteroaryloxy group, heteroarylthio group, alkyloxycarbonyl group, aryloxycarbonyl group, arylalkyloxy carbonyl group, heteroaryloxy carbonyl group, or carboxyl group. x and y each independently represent an integer of 0-4. z represents an integer of 0-2. w represents an integer of 0-5.

The light-emitting polymer used for the present invention may also be a random, block or graft copolymer, or a polymer having an intermediate structure thereof, for example, a random copolymer having block property. From the viewpoint for obtaining a polymer compound having high fluorescent quantum yield, random copolymers having block property and block or graft copolymers are preferable than complete random copolymers. Further, a polymer having a branched main chain and more than three terminals, and a dendrimer may also be included.

As for the end groups of the light-emitting polymer used for the present invention, if the polymerizable group remains intact, there is a possibility of reduction in light emitting property and life-time when made into an device, and they may be protected with a stable group. Those having a conjugated bond continuing to a conjugated structure of the main chain are preferable, and there are exemplified structures connected to an aryl group or heterocyclic compound group via a carbon-carbon bond. Specifically, substituents described as Chemical Formula 10 in JP-A-9-45478 are exemplified.

The light-emitting polymer used for the present invention, it is preferable that the polystyrene reduced number average molecular weights is about 10³-10⁸, and preferably the polystyrene reduced number average molecular weights is about 10⁴-10⁶.

Moreover, since light emission from a thin film is used, as the light-emitting polymer, those having light-emission in the solid state is used preferably.

Methods of synthesizing the light-emitting polymer used for the present invention include, for example: a method of polymerization of corresponding monomers by Suzuki coupling reaction; a method of polymerization by Grignard reaction; a method of polymerization by Ni(0) catalyst; a method of polymerization using an oxidizer, such as, FeCl₃, etc.; a method of electrochemical oxidization polymerization; and a method by decomposition of an intermediate polymer having a suitable leaving group. Among these, a method of polymerization by Suzuki coupling reaction; a method of polymerization by Grignard reaction; a method of polymerization by Ni(0) catalyst are preferable, because the reaction is easily controllable.

When the light-emitting polymer is used as a light emitting material of a polymer LED, the purity thereof exerts an influence on light emitting property, therefore, it is preferable that a monomer before polymerization is purified by a method such as distillation, sublimation purification, re-crystallization and the like before being polymerized and further, it is preferable to conduct a purification treatment such as re-precipitation purification, chromatographic separation and the like after the synthesis.

The light-emitting polymer composition of the present invention comprises a light-emitting polymer and an ion pair. The content of the ion pair is usually 0.001-10 parts by weight based on 100 parts by weight of the light-emitting polymer, preferably 0.001-5 parts by weight, more preferably 0.001-1 parts by weight, and further preferably 0.01-1 parts by weight.

Furthermore, the light-emitting polymer solution composition of the present invention comprises a light-emitting polymer, and an ion pair and a solvent.

Using this solution composition, a light emitting layer can be formed by coating method. The light emitting layer produced by using this solution composition usually contains the light-emitting polymer composition of the present invention.

As the solvent, chloroform, methylene chloride, dichloro ethane, tetrahydrofuran, toluene, xylene, mesitylene, tetralin, decalin, n-butylbenzene, etc., are exemplified.

The light-emitting polymer, although being depend the structure and the molecular weight thereof, can usually dissolve 0.1% by weight or more in these solvents.

The amount of the solvent is usually about 1000-100000 parts by weight based on 100 parts by weight of the light-emitting polymer.

The composition of the present invention may contain a coloring matter, charge transporting material, etc. according to neccessity.

The polymer LED of the present invention comprises an light emitting layer between the electrodes consisting of an anode and a cathode, and the light emitting layer contains the light-emitting polymer composition of the present invention.

Moreover, the polymer LED of the present invention comprises an light emitting layer between the electrodes consisting of an anode and a cathode, and the light emitting layer is formed by using the solution composition of the present invention.

Moreover, the polymer LED of the present invention include: a polymer LED having an electron transporting layer between a cathode and a light emitting layer; a polymer LED having an hole transporting layer between an anode and a light emitting layer; and a polymer LED having an electron transporting layer between an cathode and a light emitting layer, and a hole transporting layer between an anode and a light emitting layer.

Specifically, the following structures a)-d) are exemplified.

a) anode/light emitting layer/cathode

b) anode/hole transporting layer/light emitting layer/cathode

c) anode/light emitting layer/electron transporting layer/cathode

d) anode/hole transporting layer/light emitting layer/electron transporting layer/cathode

(wherein, “/” indicates adjacent lamination of layers. Hereinafter, the same).

Herein, the light emitting layer is a layer having function to emit a light, the hole transporting layer is a layer having function to transport a hole, and the electron transporting layer is a layer having function to transport an electron. Herein, the electron transporting layer and the hole transporting layer are generically called a charge transporting layer.

The light emitting layer, hole transporting layer and electron transporting layer also may be used each independently in two or more layers.

Charge transporting layers disposed adjacent to an electrode, that having function to improve charge injecting efficiency from the electrode and having effect to decrease driving voltage of an device are particularly called sometimes a charge injecting layer (hole injecting layer, electron injecting layer) in general.

For enhancing adherence with an electrode and improving charge injection from an electrode, the above-described charge injecting layer or insulation layer having a thickness of 2 nm or less may also be provided adjacent to an electrode, and further, for enhancing adherence of the interface, preventing mixing and the like, a thin buffer layer may also be inserted into the interface of a charge transporting layer and light emitting layer.

The order and number of layers laminated and the thickness of each layer can be appropriately applied while considering light emitting efficiency and life of the device.

In the present invention, as the polymer LED having a charge injecting layer (electron injecting layer, hole injecting layer) provided, there are listed a polymer LED having a charge injecting layer provided adjacent to a cathode and a polymer LED having a charge injecting layer provided adjacent to an anode.

For example, the following structures e) to p) are specifically exemplified.

e) anode/charge injecting layer/light emitting layer/cathode

f) anode/light emitting layer/charge injecting layer/cathode

g) anode/charge injecting layer/light emitting layer/charge injecting layer/cathode

h) anode/charge injecting layer/hole transporting layer/light emitting layer/cathode

i) anode/hole transporting layer/light emitting layer/charge injecting layer/cathode

j) anode/charge injecting layer/hole transporting layer/light emitting layer/charge injecting layer/cathode

k) anode/charge injecting layer/light emitting layer/electron transporting layer/cathode

l) anode/light emitting layer/electron transporting layer/charge injecting layer/cathode

m) anode/charge injecting layer/light emitting layer/electron transporting layer/charge injecting layer/cathode

n) anode/charge injecting layer/hole transporting layer/light emitting layer/electron transporting layer/cathode

o) anode/hole transporting layer/light emitting layer/electron transporting layer/charge injecting layer/cathode

p) anode/charge injecting layer/hole transporting layer/light emitting layer/electron transporting layer/charge injecting layer/cathode

As the specific examples of the charge injecting layer, there are exemplified layers containing an conducting polymer, layers which are disposed between an anode and a hole transporting layer and contain a material having an ionization potential between the ionization potential of an anode material and the ionization potential of a hole transporting material contained in the hole transporting layer, layers which are disposed between a cathode and an electron transporting layer and contain a material having an electron affinity between the electron affinity of a cathode material and the electron affinity of an electron transporting material contained in the electron transporting layer, and the like.

When the above-described charge injecting layer is a layer containing an conducting polymer, the electric conductivity of the conducting polymer is preferably 10⁻⁵ S/cm or more and 10³ S/cm or less, and for decreasing the leak current between light emitting pixels, more preferably 10⁻⁵ S/cm or more and 10² S/cm or less, further preferably 10⁻⁵ S/cm or more and 10¹ S/cm or less.

Usually, to provide an electric conductivity of the conducting polymer of 10⁻⁵ S/cm or more and 10³ S/cm or less, a suitable amount of ions are doped into the conducting polymer.

Regarding the kind of an ion doped, an anion is used in a hole injecting layer and a cation is used in an electron injecting layer. As examples of the anion, a polystyrene sulfonate ion, alkylbenzene sulfonate ion, camphor sulfonate ion and the like are exemplified, and as examples of the cation, a lithium ion, sodium ion, potassium ion, tetrabutyl ammonium ion and the like are exemplified.

The thickness of the charge injecting layer is for example, from 1 nm to 100 nm, preferably from 2 nm to 50 nm.

Materials used in the charge injecting layer may properly be selected in view of relation with the materials of electrode and adjacent layers, and there are exemplified conducting polymers such as polyaniline and derivatives thereof, polythiophene and derivatives thereof, polypyrrole and derivatives thereof, poly(phenylene vinylene) and derivatives thereof, poly(thienylene vinylene) and derivatives thereof, polyquinoline and derivatives thereof, polyquinoxaline and derivatives thereof, polymers containing aromatic amine structures in the main chain or the side chain, and the like, and metal phthalocyanine (copper phthalocyanine and the like), carbon and the like.

The insulation layer having a thickness of 2 nm or less has function to make charge injection easy. As the material of the above-described insulation layer, metal fluoride, metal oxide, organic insulation materials and the like are listed. As the polymer LED having an insulation layer having a thickness of 2 nm or less, there are listed polymer LEDs having an insulation layer having a thickness of 2 nm or less provided adjacent to a cathode, and polymer LEDs having an insulation layer having a thickness of 2 nm or less provided adjacent to an anode.

Specifically, there are listed the following structures q) to ab) for example.

q) anode/insulation layer having a thickness of 2 nm or less/light emitting layer/cathode

r) anode/light emitting layer/insulation layer having a thickness of 2 nm or less/cathode

s) anode/insulation layer having a thickness of 2 nm or less/light emitting layer/insulation layer having a thickness of 2 nm or less/cathode

t) anode/insulation layer having a thickness of 2 nm or less/hole transporting layer/light emitting layer/cathode

u) anode/hole transporting layer/light emitting layer/insulation layer having a thickness of 2 nm or less/cathode

v) anode/insulation layer having a thickness of 2 nm or less/hole transporting layer/light emitting layer/insulation layer having a thickness of 2 nm or less/cathode

w) anode/insulation layer having a thickness of 2 nm or less/light emitting layer/electron transporting layer/cathode

x) anode/light emitting layer/electron transporting layer/insulation layer having a thickness of 2 nm or less/cathode

y) anode/insulation layer having a thickness of 2 nm or less/light emitting layer/electron transporting layer/insulation layer having a thickness of 2 nm or less/cathode

z) anode/insulation layer having a thickness of 2 nm or less/hole transporting layer/light emitting layer/electron transporting layer/cathode

aa) anode/hole transporting layer/light emitting layer/electron transporting layer/insulation layer having a thickness of 2 nm or less/cathode

ab) anode/insulation layer having a thickness of 2 nm or less/hole transporting layer/light emitting layer/electron transporting layer/insulation layer having a thickness of 2 nm or less/cathode

In producing a light emitting layer, when a film is formed from a solution by using such light-emitting polymer solution composition of the present invention, only required is removal of the solvent by drying after coating of this solution, and even in the case of mixing of a charge transporting material and a light emitting material, the same method can be applied, causing an extreme advantage in production. As the film forming method from a solution, there can be used coating methods such as a spin coating method, casting method, micro gravure coating method, gravure coating method, bar coating method, roll coating method, wire bar coating method, dip coating method, spray coating method, screen printing method, flexo printing method, offset printing method, inkjet printing method and the like.

Regarding the thickness of the light emitting layer, the optimum value differs depending on material used, and may properly be selected so that the driving voltage and the light emitting efficiency become optimum values, and for example, it is from 1 nm to 1 μm, preferably from 2 nm to 500 nm, further preferably from 5 nm to 200 nm.

In the polymer LED of the present invention, light emitting materials other than the above light-emitting polymer can also be mixed in a light emitting layer. Further, the light emitting layer containing light emitting materials other than the above light-emitting polymer may also be laminated with a light emitting layer containing the above light-emitting polymer.

As the light emitting material, known materials can be used. In a compound having lower molecular weight, there can be used, for example, naphthalene derivatives, anthracene or derivatives thereof, perylene or derivatives thereof; dyes such as polymethine dyes, xanthene dyes, coumarine dyes, cyanine dyes; metal complexes of 8-hydroxyquinoline or derivatives thereof, aromatic amine, tetraphenylcyclopentane or derivatives thereof, or tetraphenylbutadiene or derivatives thereof, and the like.

Specifically, there can be used known compounds such as those described in JP-A Nos. 57-51781, 59-195393 and the like, for example.

When the polymer LED of the present invention has a hole transporting layer, as the hole transporting materials used, there are exemplified polyvinylcarbazole or derivatives thereof, polysilane or derivatives thereof, polysiloxane derivatives having an aromatic amine in the side chain or the main chain, pyrazoline derivatives, arylamine derivatives, stilbene derivatives, triphenyldiamine derivatives, polyaniline or derivatives thereof, polythiophene or derivatives thereof, polypyrrole or derivatives thereof, poly(p-phenylenevinylene) or derivatives thereof, poly(2,5-thienylenevinylene) or derivatives thereof, or the like.

Specific examples of the hole transporting material include those described in JP-A Nos. 63-70257, 63-175860, 2-135359, 2-135361, 2-209988, 3-37992 and 3-152184.

Among them, as the hole transporting materials used in the hole transporting layer, preferable are polymer hole transporting materials such as polyvinylcarbazole or derivatives thereof, polysilane or derivatives thereof, polysiloxane derivatives having an aromatic amine compound group in the side chain or the main chain, polyaniline or derivatives thereof, polythiophene or derivatives thereof, poly(p-phenylenevinylene) or derivatives thereof, poly(2,5-thienylenevinylene) or derivatives thereof, or the like, and further preferable are polyvinylcarbazole or derivatives thereof, polysilane or derivatives thereof and polysiloxane derivatives having an aromatic amine compound group in the side chain or the main chain. In the case of a hole transporting material having lower molecular weight, it is preferably dispersed in a polymer binder for use.

Polyvinylcarbazole or derivatives thereof are obtained, for example, by cation polymerization or radical polymerization from a vinyl monomer.

As the polysilane or derivatives thereof, there are exemplified compounds described in Chem. Rev., 89, 1359 (1989) and GB 2300196 published specification, and the like. For synthesis, methods described in them can be used, and a Kipping method can be suitably used particularly.

As the polysiloxane or derivatives thereof, those having the structure of the above-described hole transporting material having lower molecular weight in the side chain or main chain, since the siloxane skeleton structure has poor hole transporting property. Particularly, there are exemplified those having an aromatic amine having hole transporting property in the side chain or main chain.

The method for forming a hole transporting layer is not restricted, and in the case of a hole transporting layer having lower molecular weight, a method in which the layer is formed from a mixed solution with a polymer binder is exemplified. In the case of a polymer hole transporting material, a method in which the layer is formed from a solution is exemplified.

The solvent used for the film forming from a solution is not particularly restricted providing it can dissolve a hole transporting material. As the solvent, there are exemplified chlorine solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, and ester solvents such as ethyl acetate, butyl acetate, ethylcellosolve acetate and the like.

As the film forming method from a solution, there can be used coating methods such as a spin coating method, casting method, micro gravure coating method, gravure coating method, bar coating method, roll coating method, wire bar coating method, dip coating method, spray coating method, screen printing method, flexo printing method, offset printing method, inkjet printing method and the like, from a solution.

The polymer binder mixed is preferably that does not disturb charge transport extremely, and that does not have strong absorption of a visible light is suitably used. As such polymer binder, polycarbonate, polyacrylate, poly(methyl acrylate), poly(methyl methacrylate), polystyrene, poly(vinyl chloride), polysiloxane and the like are exemplified.

Regarding the thickness of the hole transporting layer, the optimum value differs depending on material used, and may properly be selected so that the driving voltage and the light emitting efficiency become optimum values, and at least a thickness at which no pin hole is produced is necessary, and too large thickness is not preferable since the driving voltage of the device increases. Therefore, the thickness of the hole transporting layer is, for example, from 1 nm to 1 μm, preferably from 2 nm to 500 nm, further preferably from 5 nm to 200 nm.

When the polymer LED of the present invention has an electron transporting layer, known compounds are used as the electron transporting materials, and there are exemplified oxadiazole derivatives, anthraquinonedimethane or derivatives thereof, benzoquinone or derivatives thereof, naphthoquinone or derivatives thereof, anthraquinone or derivatives thereof, tetracyanoanthraquinodimethane or derivatives thereof, fluorenone derivatives, diphenyldicyanoethylene or derivatives thereof, diphenoquinone derivatives, or metal complexes of 8-hydroxyquinoline or derivatives thereof, polyquinoline and derivatives thereof, polyquinoxaline and derivatives thereof, polyfluorene or derivatives thereof, and the like.

Specifically, there are exemplified those described in JP-A Nos. 63-70257, 63-175860, 2-135359, 2-135361, 2-209988, 3-37992 and 3-152184.

Among them, oxadiazole derivatives, benzoquinone or derivatives thereof, anthraquinone or derivatives thereof, or metal complexes of 8-hydroxyquinoline or derivatives thereof, polyquinoline and derivatives thereof, polyquinoxaline and derivatives thereof, polyfluorene or derivatives thereof are preferable, and 2-(4-biphenyl)-5-(4-t-butylphenyl)-1,3,4-oxadiazole, benzoquinone, anthraquinone, tris(8-quinolinol)aluminum and polyquinoline are further preferable.

The method for forming the electron transporting layer is not particularly restricted, and in the case of an electron transporting material having lower molecular weight, a vapor deposition method from a powder, or a method of film-forming from a solution or melted state is exemplified, and in the case of a polymer electron transporting material, a method of film-forming from a solution or melted state is exemplified, respectively.

The solvent used in the film-forming from a solution is not particularly restricted provided it can dissolve electron transporting materials and/or polymer binders. As the solvent, there are exemplified chlorine solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, and ester solvents such as ethyl acetate, butyl acetate, ethylcellosolve acetate and the like.

As the film-forming method from a solution or melted state, there can be used coating methods such as a spin coating method, casting method, micro gravure coating method, gravure coating method, bar coating method, roll coating method, wire bar coating method, dip coating method, spray coating method, screen printing method, flexo printing method, offset printing method, inkjet printing method and the like.

The polymer binder to be mixed is preferably that which does not extremely disturb a charge transport property, and that does not have strong absorption of a visible light is suitably used. As such polymer binder, poly(N-vinylcarbazole), polyaniline or derivatives thereof, polythiophene or derivatives thereof, poly(p-phenylene vinylene) or derivatives thereof, poly(2,5-thienylene vinylene) or derivatives thereof, polycarbonate, polyacrylate, poly(methyl acrylate), poly(methyl methacrylate), polystyrene, poly(vinyl chloride), polysiloxane and the like are exemplified.

Regarding the thickness of the electron transporting layer, the optimum value differs depending on material used, and may properly be selected so that the driving voltage and the light emitting efficiency become optimum values, and at least a thickness at which no pin hole is produced is necessary, and too large thickness is not preferable since the driving voltage of the device increases. Therefore, the thickness of the electron transporting layer is, for example, from 1 nm to 1 μm, preferably from 2 nm to 500 nm, further preferably from nm to 200 nm.

The substrate forming the polymer LED of the present invention may preferably be that does not change in forming an electrode and layers of organic materials, and there are exemplified glass, plastics, polymer film, silicon substrates and the like. In the case of a opaque substrate, it is preferable that the opposite electrode is transparent or semitransparent.

At least one of the electrodes consisting of an anode and a cathode, is transparent or semitransparent. It is preferable that the anode is transparent or semitransparent.

As the material of this anode, electron conductive metal oxide films, semitransparent metal thin films and the like are used. Specifically, there are used indium oxide, zinc oxide, tin oxide, and composition thereof, i.e. indium/tin/oxide (ITO), and films (NESA and the like) fabricated by using an electron conductive glass composed of indium/zinc/oxide, and the like, and gold, platinum, silver, copper and the like. Among them, ITO, indium/zinc/oxide, tin oxide are preferable. As the fabricating method, a vacuum vapor deposition method, sputtering method, ion plating method, plating method and the like are used. As the anode, there may also be used organic transparent conducting films such as polyaniline or derivatives thereof, polythiophene or derivatives thereof and the like.

The thickness of the anode can be appropriately selected while considering transmission of a light and electric conductivity, and for example, from 10 nm to 10 μm, preferably from 20 nm to 1 μm, further preferably from 50 nm to 500 nm.

Further, for easy charge injection, there may be provided on the anode a layer comprising a phthalocyanine derivative conducting polymers, carbon and the like, or a layer having an average film thickness of 2 nm or less comprising a metal oxide, metal fluoride, organic insulating material and the like.

As the material of a cathode used in the polymer LED of the present invention, that having lower work function is preferable. For example, there are used metals such as lithium, sodium, potassium, rubidium, cesium, beryllium, magnesium, calcium, strontium, barium, aluminum, scandium, vanadium, zinc, yttrium, indium, cerium, samarium, europium, terbium, ytterbium and the like, or alloys comprising two of more of them, or alloys comprising one or more of them with one or more of gold, silver, platinum, copper, manganese, titanium, cobalt, nickel, tungsten and tin, graphite or graphite intercalation compounds and the like. Examples of alloys include a magnesium-silver alloy, magnesium-indium alloy, magnesium-aluminum alloy, indium-silver alloy, lithium-aluminum alloy, lithium-magnesium alloy, lithium-indium alloy, calcium-aluminum alloy and the like. The cathode may be formed into a laminated structure of two or more layers.

The thickness of the cathode can be appropriately selected while considering transmission of a light and electric conductivity, and for example, from 10 nm to 10 μm, preferably from 20 nm to 1 μm, further preferably from 50 nm to 500 nm.

As the method for fabricating a cathode, there are used a vacuum vapor deposition method, sputtering method, lamination method in which a metal thin film is adhered under heat and pressure, and the like. Further, there may also be provided, between a cathode and an organic layer, a layer comprising an conducting polymer, or a layer having an average film thickness of 2 nm or less comprising a metal oxide, metal fluoride, organic insulation material and the like, and after fabrication of the cathode, a protective layer may also be provided which protects the polymer LED. For stable use of the polymer LED for a long period of time, it is preferable to provide a protective layer and/or protective cover for protection of the device in order to prevent it from outside damage.

As the protective layer, there can be used a polymeric compound, metal oxide, metal fluoride, metal borate and the like. As the protective cover, there can be used a glass plate, a plastic plate the surface of which has been subjected to lower-water-permeation treatment, and the like, and there is suitably used a method in which the cover is pasted with an device substrate by a thermosetting resin or light-curing resin for sealing. If space is maintained using a spacer, it is easy to prevent an device from being injured. If an inner gas such as nitrogen and argon is sealed in this space, it is possible to prevent oxidation of a cathode, and further, by placing a desiccant such as barium oxide and the like in the above-described space, it is easy to suppress the damage of an device by moisture adhered in the production process. Among them, any one means or more are preferably adopted.

In the devices of the present invention, preferable is a device which is produced by heat-treating at a temperature of 50° C. or more, during or after the light emitting layer is formed, in view of life time of the devices.

The condition of heat-treating is usually a condition where an onium salt is decomposed by heat-treating. The heat-treating temperature is 50° C. or more, and preferably, it is in a range of 50° C. to 300° C. The heat-treating time is usually from about 1 second to 24 hours.

The heat-treating can be performed using, for example, a hot plate, an oven, an infrared lamp, etc. The heat-treating may be under reduced pressure.

As for the heat-treating, it is preferable to carry out it after forming a light emitting layer, and more preferably, just after forming a light emitting layer.

Furthermore, the device of the present invention may be produced by radiation exposure during or after the light emitting layer is formed. As the radiation, for example, ultraviolet ray, electron beam, and X-ray are exemplified, and ultraviolet ray is preferable.

The polymer LED of the present invention can be used for a flat light source, a segment display, a dot matrix display, and a liquid crystal display as a back light, etc.

For obtaining light emission in plane form using the polymer LED of the present invention, an anode and a cathode in the plane form may properly be placed so that they are laminated each other. Further, for obtaining light emission in pattern form, there is a method in which a mask with a window in pattern form is placed on the above-described plane light emitting device, a method in which an organic layer in non-light emission part is formed to obtain extremely large thickness providing substantial non-light emission, and a method in which any one of an anode or a cathode, or both of them are formed in the pattern. By forming a pattern by any of these methods and by placing some electrodes so that independent on/off is possible, there is obtained a display device of segment type which can display digits, letters, simple marks and the like. Further, for forming a dot matrix device, it may be advantageous that anodes and cathodes are made in the form of stripes and placed so that they cross at right angles. By a method in which a plurality of kinds of polymeric compounds emitting different colors of lights are placed separately or a method in which a color filter or luminescence converting filter is used, area color displays and multi color displays are obtained. A dot matrix display can be driven by passive driving, or by active driving combined with TFT and the like. These display devices can be used as a display of a computer, television, portable terminal, portable telephone, car navigation, view finder of a video camera, and the like. Further, the above-described light emitting device in plane form is a thin self-light-emitting one, and can be suitably used as a flat light source for back-light of a liquid crystal display, or as a flat light source for illumination. Further, if a flexible plate is used, it can also be used as a curved light source or a display.

Hereafter, in order to explain the present invention in detail with showing examples, but the present invention is not limited to these.

Here, about the number average molecular weight, the polystyrene reduced number average molecular weight was obtained by gel permeation chromatography (GPC) using chloroform or tetrahydrofuran as a solvent.

### SYNTHETIC EXAMPLE 1 (SYNTHESIS OF COMPOUND A)

Inside of a 300 ml eggplant type flask was replaced by nitrogen, 5.00 g of tris(pentafluorophenyl)borane was dissolved in 200 ml dehydrated diethyl ether, and 0.31 g of potassium cyanide was added. After refluxing for 3 hours, the solvent was distilled off and 5.71 g of Compound A was obtained.

MS(ESI-negative)

m/z 1049.8([M-K]⁻)
K⁺|(C₆F₅)₃B≡N—B(C₆F₅)₃|⁻ A

### EXAMPLE 2 (SYNTHESIS OF COMPOUND B)

Inside of a 25 ml Schlenk tube was replaced by nitrogen, 1,1′-dimethyl-4,43-bipyridinium dichloride 40 mg was dissolved in 4.0 ml water, and Compound A 400 mg was added. 4.0 ml of chloroform was added, and stirred for 4.5 hours. After being filtrated and washed, the solvent was distilled off, and 288 mg of Compound B was obtained.

¹H-NMR (300 MHz, DMSO-d₆)

δ 9.30 (4H, brs), 8.78 (4H, brs), 4.47 (6H, s)

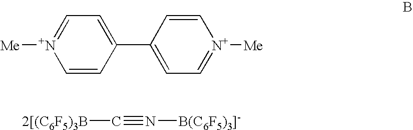

### EXAMPLE 3 (SYNTHESIS OF COMPOUND C)

Inside of a 25 ml Schlenk tube was substituted by nitrogen, bis(4-t-butylphenyl)iodonium triflate 150 mg was suspended in 4 ml water. Compound A 392 mg was added, and further toluene 3 ml was added, then the insoluble material was dissolved. After 8 hours' stirring, being partitioned and the aqueous phase was extracted with toluene. After being dried by sodium sulfate, the solvent was distilled off, and 373 mg Compound C was obtained.

¹H-NMR (DMSO-d₆, 300 MHz)

δ 8.16 (4H, d), 7.55 (4H, m), 1.26 (18H, s)

¹⁹F-NMR (DMSO-d₆, 300 MHz)

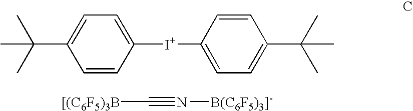

δ −132.5, −133.6, −134.1, −157.8, −159.7, −164.1, −165.2

### SYNTHETIC EXAMPLE 4 (SYNTHESIS OF COMPOUND D)

Inside of a 25 ml Schlenk tube was replaced by nitrogen, triphenylsulfonium bromide 100 mg was dissolved in 4 ml water. The solution became cloudy when Compound A 408 mg was added. After 8 hours stirring with 3 ml toluene addition, being partitioned and the aqueous phase was extracted with toluene and diethyl ether. After being dried with sodium sulfate, the solvent was distilled off, and 449 mg Compound D was obtained.

¹H-NMR (DMSO-d₆, 300 MHz)

δ 7.90-7.75 (15H, m)

¹⁹F-NMR (DMSO-d₆, 300 MHz)

δ −132.7, −133.7, −134.1, −157.9, −160.0, −164.2, −165.3

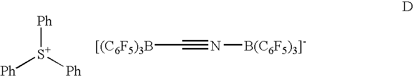

### SYNTHETIC EXAMPLE 5

<Synthesis of Light-Emitting Polymer 1>

2,7-dibromo-9,9-dioctylfluorene (26 g, 0.047 mol), 2,7-dibromo-9,9-diisopentylfluorene (5.6 g, 0.012 mol), and 2,2′-bipyridyl (22 g, 0.141 mol) were dissolved in dehydrated tetrahydrofuran 1600 mL, and the inside of the system was replaced by nitrogen bubbling. Under nitrogen atmosphere, to this solution, bis(1,5-cyclooctadiene)Ni(0){Ni(COD)₂} (40 g, 0.15 mol) was added, and the temperature was raised to 60° C., and reacted for 8 hours. After the reaction, the reaction mixture was cooled to room temperature (about 25° C.), added dropwise into a mixed solution of 25% aqueous ammonia 200 ml/methanol 1200 ml/ion-exchanged water 1200 ml, and stirred for about 30 minutes. The deposited precipitate was filtrated, and air-dried. After being dissolved in toluene 1100 mL, it was filtrated, and the filtrated solution was added dropwise in methanol 3300 mL, and was stirred for 30 minutes. The deposited precipitate was filtrated and washed by methanol 1000 mL, then dried under reduced-pressure for 5 hours. The yield of a resultant copolymer was 20 g (hereafter referred to as Light-emitting Polymer 1). The polystyrene reduced number average molecular weight and weight average molecular weight of Light-emitting Polymer 1 were Mn=9.9×10⁴ and Mw=2.0×10⁵, respectively, (mobile-phase: chloroform).

### SYNTHETIC EXAMPLE 6

<Synthesis of 4-t-butyl-2,6-dimethylbromobenzene>

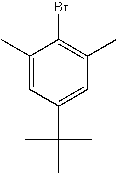

Under an inert atmosphere, 225 g of acetic acid was charged into a 500 ml three-necked flask, and 24.3 g of 5-t-butyl-m-xylene was added. Then, after adding 31.2 g of bromine, reaction was conducted at 15-20° C. for 3 hours.

The reaction liquid was added to 500 ml of water, and the deposited precipitate was filtrated. Washing with 250 ml of water twice and 34.2 g of white solid was obtained.

¹H-NMR(300 MHz/CDCl₃):

δ (ppm)=1.3 [s,9H], 2.4 [s,6H], 7.1 [s,2H]

MS(FD⁺)M⁺ 241

### SYNTHETIC EXAMPLE 7

<Synthesis of N,N′-diphenyl-N,N′-bis(4-t-butyl-2,6-dimethylphenyl)-1,4-phenylene diamine>

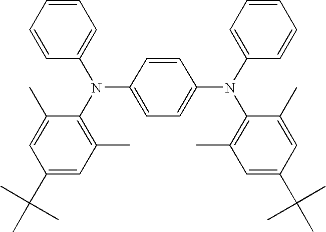

Under an inert atmosphere, deaerated and dehydrated toluene 36 ml was charged in a 10 ml three-necked flask, and 0.63 g of tri(t-butyl)phosphine was added. Then, 0.41 g of tris(dibenzylidineacetone)dipalladium, 9.6 g of the above 4-t-butyl-2,6-dimethylbromobenzene, 5.2 g of t-butoxy sodium, and 4.7 g of N,N′-diphenyl-1,4-phenylene diamine were added, and reacted at 100° C. for 3 hours.

The reaction liquid was added to 300 ml of saturated NaCl aqueous solution, and extracted by chloroform 300 ml warmed at about 50 r. After distilling off the solvent, toluene 100 ml was added and heated until the solid was dissolved. After standing to cool, precipitate was filtrated and 9.9 g of white solid was obtained.

### SYNTHETIC EXAMPLE 8

<Synthesis of N,N′-bis(4-bromophenyl)-N,N′-bis(4-t-butyl-2,6-dimethylphenyl)-1,4-phenylene diamine>

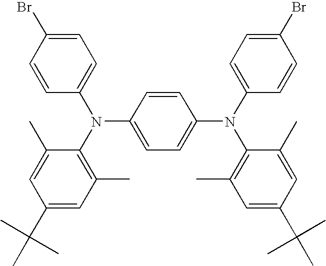

Uunder an inert atmosphere, dehydrated N,N-dimethylformamide 350 ml was charged into a 1000 ml three-necked flask and 5.2 g of the above N,N′-diphenyl-N,N′-bis(4-t-butyl-2,6-dimethylphenyl)-1,4-phenylenediamine was dissolved, then 3.5 g of N-bromosuccinimide/and N,N-dimethylformamide solution was added dropwise, and the reaction was conducted one whole day and night with colling by an ice bath.

150 ml of water was added to the reaction liquid, and the deposited precipitate was filtrated, it washed twice by methanol 50 ml, and 4.4 g of white solid was obtained.

¹H-NMR(300 MHz/THF-d8):

δ (ppm)=1.3 [s,18H], 2.0 [s,12H], 6.6 to 6.7 [d,4H], 6.8 to 6.9 [br,4H], 7.1 [s,4H], 7.2 to 7.3 [d,4H]

MS(FD⁺)M⁺ 738

### SYNTHETIC EXAMPLE 9

<Synthesis of Light-Emitting Polymer 2>

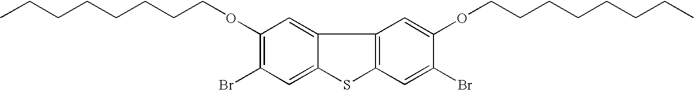

The above 2,7-dibromo-3,6-dioctyloxydibenzothiophene (5.4 g, 9 mmol, synthesized according to JP-A-2004-002703), the above N,N′-bis(4-bromophenyl)-N,N′-bis( 4-t-butyl-2,6-dimethylphenyl)-1,4-phenylene diamine (4.5 g, 6 mmol), and 2,2′-bipyridyl (5.1 g, 33 mmol) were dissolved in tetrahydrofuran 420 mL, and the inside of the system was replaced by nitrogen with nitrogen bubbling. Under nitrogen atmosphere, into the solution, bis(1,5-cyclooctadiene)Ni(0){Ni(COD)₂} (9.0 g, 33 mmol) was added, and raised the temperature to 60° C., and reacted for 3 hours with stirring. After the reaction, the reaction mixture was cooled to room temperature (about 25° C.), added dropwise into a mixed solution of 25% aqueous ammonia 150 ml/methanol 1500 ml/ion-exchanged water 600 ml, and stirred for 1 hour. The deposited precipitate was filtrated, and dried under reduced pressure for 2 hours, and then dissolved in toluene 450 mL. Then, 1N hydrogen-chloride 450 mL was added, and stirred for 1 hour, the aqueous layer was removed, 4% aqueous ammonia 450 mL was added to the organic layer, and after stirring for 1 hour, the aqueous layer was removed. The organic layer was added dropwise to methanol 1350 mL, and stirred for 1 hour, and the deposited precipitate was filtrated and dried under reduced-pressure for 2 hours, and dissolved in toluene 400 mL. Then, purification through alumina column (amount alumina of 100 g) was performed, and the collected toluene solution was added dropwise to methanol 1350 mL, stirred for 1 hour, the deposited precipitate was and dried under reduced-pressure for 2 hours.

The yield of the resultant copolymer (hereafter referred to as Light-emitting Polymer 2) was 5.5 g. The polystyrene reduced number average molecular weight and the weight average molecular weight were Mn=3.0×10⁴ and Mw=1.8×10⁵, respectively, (mobile-phase:chloroform).

### SYNTHETIC EXAMPLE 10

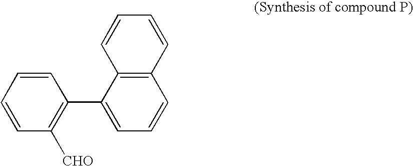

### SYNTHETIC EXAMPLE 11

Compound P

Under an inert atmosphere, into a 300 ml three-necked flask, 1-naphthalene boronic acid 5.00 g (29 mmol), 2-bromobenzaldehyde 6.46 g (35 mmol), potassium carbonate 10.0 g (73 mmol), toluene 36 ml, and ion-exchanged water 36 ml, were added, and argon bubbling was carried out for 20 minutes at room temperature, with stirring. Then, tetrakis(triphenyl phosphine)Pd 16.8 mg (0.15 mmol) was added, and argon bubbling was carried out for 10 minutes at room temperature, with stirring further. The temperature was raised to 100° C., and reacted for 25 hours. After cooling to room temperature, the organic layer was extracted with toluene, dried with sodium sulfate, and then the solvent was distilled off. By purification through silica gel column, with a mixed solvent of toluene:cyclohexane=1:2 as eluent, 5.18 g (86% of yield) of Compound P was obtained as white crystal.

¹H-NMR(300 MHz/CDCl₃):

δ 7.39-7.62 (m, 5H), 7.70 (m, 2H), 7.94 (d, 2H), 8.12 (dd, 2H), 9.63 (s, 1H)

MS(APCI(+)):(M+H)+233

### SYNTHETIC EXAMPLE 11

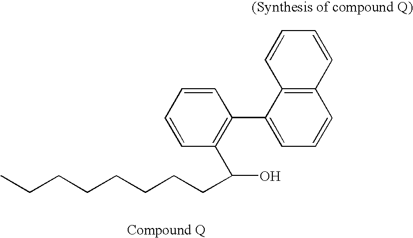

Under an inert atmosphere, 8.00 g (34.4 mmol) of Compound P and dehydrated THF 46 ml were charged into a 300 ml three-necked flask, and it was cooled to −78 r. Then, n-octyl magnesium bromide (1.0 mol/lTHF solution) 52 ml was added dropwise for 30 minutes. After the dropwise addition, the temperature was raised to 0° C., and after being stirred for 1 hour, the temperature was raised to room temperature and stirred for 45 minutes. In an ice bath, the reaction was terminated by adding 20 ml of 1N hydrogen chloride, and the organic layer was extracted with ethyl acetate, and dried with sodium sulfate.

After distilling off the solvent, by purifying through silica gel column with toluene:hexane=10:1 mixed solvent as the eluent, 7.64 g (64% of yield) of Compound Q was obtained as light yellow oil. Two peaks were observed by HPLC measurement, but these were the same mass number by LC-MS measurement, and it was regarded as a mixture of isomers.

### SYNTHETIC EXAMPLE 12

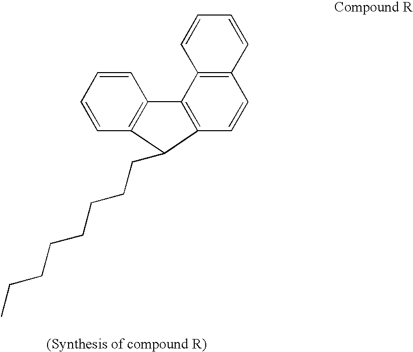

Under an inert atmosphere, into a 500 ml three-necked flask, 5.00 g (14.4 mmol) of compound Q (mixture of anisomer), and 74 ml of dehydrated dichloromethane were added, and dissolved with stirring at room temperature. Then, at room temperature, etherate complex of boron trifluoride was added dropwise for 1 hour, and after the addition, stirred for 4 hours at room. Ethanol 125 ml was added slowly with stirring, and after termination of heat generation, the organic layer was it extracted with chloroform, washed with water 2 times, and dried with magnesium sulfate.

After distilling off the solvent, by purifying through silica gel column with hexane solvent as the eluent, 3.22 g (68% of yield) of Ccompound R was obtained as colorless oil.

¹H-NMR(300 MHz/CDCl₃):

δ0.90 (t, 3H), 1.03 to 1.26 (m, 14H), and 2.13 (m - -) 2H, 4.05 (t, 1H), 7.35 (dd, 1H), 7.46 to 7.50 (m, 2H), 7.59 to 7.65 (m, 3H), 7.82 (d, 1H), 7.94 (d, 1H), 8.35 (d, 1H), 8.75 (d, 1H) MS(APCI(+)):(M+H)⁺ 329

### SYNTHETIC EXAMPLE 13

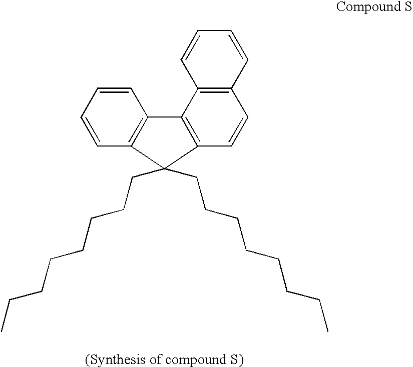

Under an inert atmosphere, in a 200 ml three-necked flask, 20 ml of ion-exchanged water was charged, and 18.9 g (0.47 mols) of sodium hydroxide was added portionally with stirring, and dissolved. After the solution was cooled to room temperature, toluene 20 ml, 5.17 g (15.7 mmol) of compound R, and 1.52 g (4.72 mmol) of bromotributyl ammonium were added, and the temperature wase raised to 50° C. n-octylbromide was added dropwise, and after the dropping addition, reacted at 50° C. for 9 hours. After the reaction, the organic layer was extracted with toluene, and washed with water twice, and dried by sodium sulfate. By purifying through silica gel column with hexane solvent as the eluent, 5.13 g (74% of yield) of Compound S was obtained as yellow oil.

¹H-NMR(300 MHz/CDCl₃):

δ 0.52 (m, 2H), 0.79 (t, 6H), and 1.00 to 1.20 (m - -) 22H, 2.05 (t, 4H), 7.34 (d, 1H), 7.40 to 7.53 (m, 2H), 7.63 (m, 3H), 7.83 (d, 1H), 7.94 (d, 1H), 8.31 (d, 1H), 8.75 (d, 1H)

MS(APCI(+)):(M+H)⁺ 441

### SYNTHETIC EXAMPLE 14

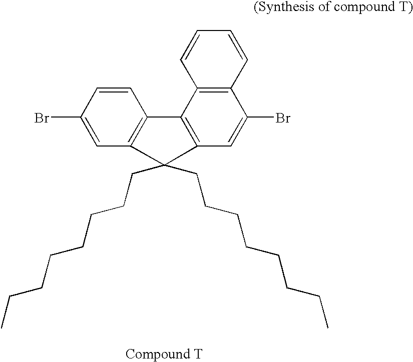

Under air atmosphere, in a 50 ml three-necked flask, 4.00 g (9.08 mmol) of Compound S, and a mixed solvent 57 ml of acetic-acid:dichloromethane=1:1 were charged, and dissolved with stirring at room temperature. Then, tribromobenzyl-trimethylammonium 7.79 g (20.0 mmol) was added with stirring, and zinc chloride was added until tribromobenzyl-trimethylammonium was completely dissolved. After 20 hours stirring at room temperature, the reaction was terminated by adding 10 ml of 5% aqueous sodium-hydrogensulfite solution, the organic layer was extracted with chloroform, washed with aqueous potassium carbonate solution twice, and dried with sodium sulfate.

After purifying through a flash column twice with hexane as the eluent, by recrystallization with a mixed solvent of ethanol:hexane=1:1, and thenethanol:hexane=10:1, 4.13 g (76% of yield) of Compound T was obtained as a white crystal.

¹H-NMR(300 MHz/CDCl₃):

δ 0.60 (m, 2H), 0.91 (t, 6H), 1.01 to 1.38 (m, 22H), 2.09 (t, 4H), 7.62 to 7.75 (m, 3H), 7.89 (s, 1H), 8.20 (d, 1H), 8.47 (d, 1H), 8.72 (d, 1H)

MS(APPI(+)):(M+H)⁺ 598

### SYNTHETIC EXAMPLE 1

<Synthesis of Light-Emitting Polymer 3>

After dissolving Compound T (8.0 g) and 2,2′-bipyridyl (5.9 g) in tetrahydrofuran 300 mL, the inside of the system was replaced by nitrogen with nitrogen bubbling. Under nitrogen atmosphere, this solution was raised to 60 AC, bis(1,5-cyclo octadiene)Ni(0){Ni(COD)₂} (10.4 g, 0.038 mol) was added and reacted for 5 hours. After the reaction, this reaction liquid was cooled to room temperature (about 25° C.), and added dropwise into a solution mixture of 25% aqueous ammonia 40 mL/methanol 300 mL/ion-exchanged water 300 mL, after stirring for 30 minutes, the deposited precipitate was air-dried. Then, after being dissolved in toluene 400 mL, it was filtrated and the filtrated solution was purified through an alumina column. About 300 mL of 1N hydrogen-chloride was added, and stirred for 3 hours, the aqueous layer was removed, about 300 mL of 4% aqueous ammonia was added to then organic layer, and the aqueous layer was removed after stirring for 2 hours. After about 300 mL of ion-exchanged-water was added to the organic layer and stirred for 1 hour, the aqueous layer was removed. After about 100 mL of methanol was added dropwise to the organic layer, stirred for 1 hour and allowed to stand, supernatant layer liquid was removed by decantation. The resultant precipitate was dissolved in toluene 100 mL, and it was added dropwise to about 200 mL of methanol, stirred for 1 hour, filtrated, and dried under reduced-pressure for 2 hours. The yield of the resultant copolymer was 4.1 g (hereafter referred to as Light-emitting Polymer 3). The polystyrene reduced number average molecular weights and the weight average molecular weight of Light-emitting Polymer 3 were Mn=1.5×10⁵ and Mw=2.7×10⁵, respectively, (mobile-phase:tetrahydrofuran).

### SYNTHETIC EXAMPLE 16

<Synthesis of Light-Emitting Polymer 4>

After dissolving Compound T (0.65 g) and N,N′-bis(4-bromo phenyl)-N,N′-bis(4-t-butyl-2,6-dimethylphenyl)-1,4-phenylene diamine (0.34 g) and 2,2′-bipyridyl (0.58 g) in tetrahydrofuran 100 mL, the inside of the system was replaced by nitrogen with nitrogen bubbling. Under nitrogen atmosphere, bis(1,5-cyclo octadiene)Ni(0){Ni(COD)₂} (10.4 g, 0.038 mol) was added, raised the temperature to 60° C., and reacted for 3 hours with stirring. After the reaction, this reaction liquid was cooled to room temperature (about 25° C.), and added dropwise into a solution mixture of 25% aqueous ammonia 10 mL/methanol 100 mL/ion-exchanged water 100 mL, after stirring for 1 hour, the deposited precipitate was dried for 6 hours under reduced pressure. Then, after being dissolved in toluene 50 mL, it was filtrated and the filtrated solution was purified through an alumina column. About 50 mL of aqueous ammonia was added, and stirred for 2 hours, the aqueous layer was removed. After about 50 mL of ion-exchanged-water was added to the organic layer and stirred for 1 hour, the aqueous layer was removed. After about 100 mL of methanol was added dropwise to the organic layer, stirred for 1 hour and allowed to stand, supernatant layer liquid was removed by decantation. The resultant precipitate was dissolved in toluene 50 mL, and it was added dropwise to about 200 mL of methanol, stirred for 1 hour, filtrated, and dried under reduced-pressure for 2 hours. The yield of the resultant copolymer was 390 mg (hereafter referred to as Light-emitting Polymer 4). The polystyrene reduced number average molecular weights and the weight average molecular weight of Light-emitting Polymer 4 were Mn=1.6×10⁴ and Mw=7.4×10⁴, respectively, (mobile-phase:tetrahydrofuran).

### SYNTHETIC EXAMPLE 17 (SYNTHESIS OF COMPOUND E)

Inside of a 200 ml four-necked flask was replaced with nitrogen, 0.486 g of tri(4-t-butylphenylsulfonium)trifluoro methane sulfonate, Compound A 0.873 g, ion-exchanged water 20 ml, and diethylether 60 ml were charged. After equipping with stirring blade, thermometer, and condenser, it was reacted at 21-23° C. for 16 hours. After the reaction, the contents of the flask were put into a 200 ml separatory funnel, and the aqueous layer was separated. The ether layer was washed 3 times by 30 ml of ion-exchanged water. The ether layer was put in a 200 ml Erlenmeyer flask, anhydrous sodium sulfate was added to dehydrate, and anhydrous sodium sulfate was filtrated of f. The ether layer was condensed at room temperature by evaporator, and dried until it became to a constant weight by a vacuum pump at 70-75° C. 1.19 g of Compound E was obtained.

¹H-NMR (300 MHz, DMSO-d₆)

δ 7.78 (12H,m), 1.32 (27H, s)

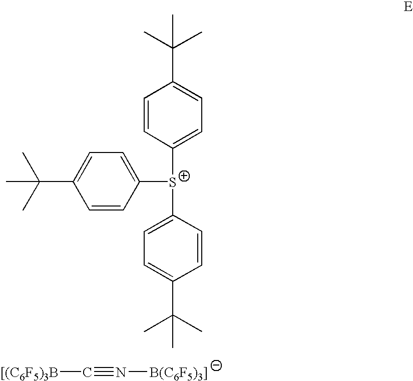

### EXAMPLE 18 (SYNTHESIS OF COMPOUND F)

Inside of a 50 ml four-necked flask was replaced with nitrogen, 0.309 g of poly(1-n-butyl-4-vinylpyridinium trifluoromethanesulfoneimide), Compound A 1.088 g, and dimethylformamide 30 ml were charged. After equipping with stirring blade, thermometer, and condenser, it was reacted at 21-23° C. for 16 hours. After the reaction, the contents of the flask were put into a 200 ml separatory funnel, 90 ml of toluene was added, and DMF was extracted with 50 ml of ion-exchanged water. The toluene layer was washed 3 times by 50 ml of ion-exchanged water. The toluene layer was put in a 200 ml Erlenmeyer flask, anhydrous sodium sulfate was added to dehydrate, and anhydrous sodium sulfate was filtrated off. The toluene layer was condensed at room temperature by evaporator, and dried until it became to a constant weight by a vacuum pump at 70-75° C. 1.08 g of Compound F was obtained.

¹H-NMR (300 MHz, DMSO-d₆)

δ 5.8, 7.4, 9.1

¹⁹F-NMR (300 MHz, DMSO-d₆)

δ −132.7, −133.6, −134.8, −157.7, −159.8, −162.5, −164.0, −165.2, −166.0

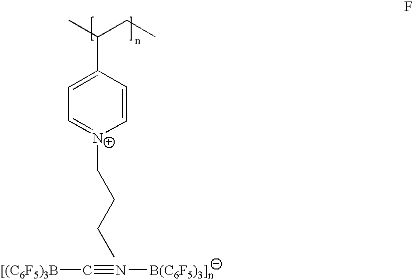

### SYNTHETIC EXAMPLE 19 (SYNTHESIS OF COMPOUND G)

Synthesis of Potassium Salt

Inside of a 200 ml four-necked flask was replaced with nitrogen, K₂[Ni(CN)₄] 3.01 g, tris(pentafluorophenyl)borane 25.5 g, and diethylether 100 ml were charged. After equipping with stirring blade, thermometer, and condenser, it was reacted at 21-23° C. for 16 hours. The deposited crystal was filtrated and the cake was washed with 100 ml of ethyl acetate. The residue K₂[Ni(CN)₄] on the filter was treated by 5% sodium hypochlorite. The filtrated solution was moved to a 500 ml separatory funnel, and it was washed with 100 ml of ion-exchanged water 3 times. The organic layer was moved to a 500 ml Erlenmeyer flask, anhydrous sodium sulfate was added to dehydrate, and anhydrous sodium sulfate was filtrated off. The solvent was condensed by an evaporator and 31.4 g of crude cake was obtained. Diethylether 60 ml and n-hexane 120 ml were added to the crude cake, and stirred for 2 hours, filtrated, and the cake was washed by n-hexane 50 ml. It was dried until it became a constant weight by drying under reduced-pressure at 70-75° C. 24.4 g of potassium salt was obtained.

### SYNTHETIC EXAMPLE 20 (SYNTHESIS of COMPOUND G)

Inside of a 200 ml four-necked flask was replaced with nitrogen, potassium salt 3.0 g, diethyl ether 100 ml and ion-exchanged water 20 ml were charged, and equipped with a stirring blade, thermometer, and condenser. With stirring at 21-23° C., 1% hydrogen chloride 15 g was added dropwise in 10 minutes, and then stirred for 1 hour.

The contents of the flask were put into a 200 ml separatory funnel, and the aqueous layer was separated. The ether layer was washed 3 times by ion-exchanged water. The ether layer was put in a 200 ml Erlenmeyer flask, anhydrous sodium sulfate was added to dehydrate, and anhydrous sodium sulfate was filtrated off. The ether layer was condensed at room temperature by evaporator, and dried until it became to a constant weight by a vacuum pump at 70-75° C. 2.81 g of Compound G was obtained.

¹⁹F-NMR (300 MHz, DMSO-d₆)

δ −132.7, −133.7, −134.3, −154.8, −157.8, −159.2, −161.0, −162.9, −164.3, −165.4, −165.8, −166.5

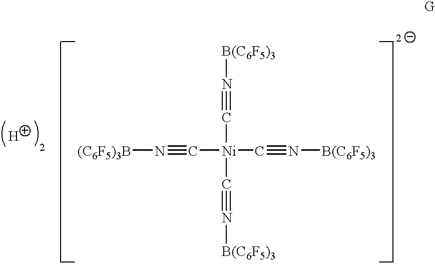

### EXAMPLE 21 (SYNTHESIS OF COMPOUND H)

Inside of a 200 ml four-necked flask was replaced with nitrogen, 1,1′-di-2-ethylhexyl-4,4′-bipyridinium diiodide 0.323 g, Compound A 1.223 g, ion-exchanged water 20 ml, and diethyl ether 60 ml were charged. After equipping with stirring blade, thermometer, and condenser, it was reacted at 21-23° C. for 22 hours.

The contents of the flask were put into a 200 ml separatory funnel, and the aqueous layer was separated. The ether layer was washed 3 times by 40 ml ion-exchanged water. The ether layer was put in a 200 ml Erlenmeyer flask, anhydrous sodium sulfate was added to dehydrate, and anhydrous sodium sulfate was filtrated off. The ether layer was condensed at room temperature by evaporator. Tolune 50 ml was added to it, stirred at 60-65° C. for 0.5 hours, and after cooling, it was filtrated. The washing procedure was repeated 3 times, dried until it became to a constant weight by a vacuum pump at 80-85° C. 1.15 g Compound H was obtained.

¹H-NMR (270 MHz, CD₃OD)

δ 9.258 (4H, m), 8.687 (4H, m), 4.665 (4H, d), 2.049 (2H, m),

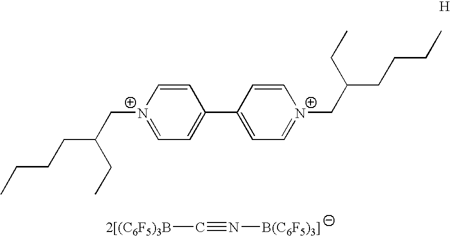

### SYNTHETIC EXAMPLE 22 (SYNTHESIS of COMPOUND I)

Synthesis of Quarternary Salt

Inside of a 50 ml four-necked flask was replaced with nitrogen, 27.4 g of 1,8-diazabicyclo[5,4,0]undeca-7-ene and 11.6 g of n-octyl bromide were charged. After equipping with stirring blade, thermometer, and condenser, it was reacted at 21-23° C. for 22 hours. After equipping with stirring blade, thermometer, and condenser, it was reacted at 110-115° C. for 5.5 hours. After cooling to 80° C., toluene 50 ml and hexane 150 ml were charged, and it was cooled to 5° C. It was stirred below 5° C. for 1 hour, and allowed to stand at this temperature, supernatant layer liquid was removed by decantation. Toluene 50 ml and hexane 150 ml were charged into the flask and stirred at 60-65° C. for 1 hour, it was cooled to 5° C. It was stirred below 5° C. for 1 hour, and allowed to stand at this temperature, supernatant layer liquid was removed by decantation. This procedure was repeated again, and the residual solvent was distilled off by evaporator. Next, it was dried to become a constant weight by a vacuum pump at 80-85° C., and 19.5 g of a quarternary salt was obtained.

Quarternary salt ¹H-NMR (270 MHz, CD₃OD)

δ 3.676 (2H, m), 3.545 (6H, m), 2.054 (2H, m), 1.722(10H, m) 1.332 (10H, m), 0.798 (3H, m)

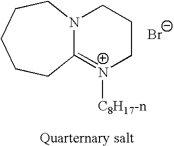

### SYNTHETIC EXAMPLE 23 (SYNTHESIS OF COMPOUND I)

Inside of a 200 ml four-necked flask was replaced with nitrogen, 0.590 g of quarternary salt, 1.240 of Compound A, 20 ml of ion exchanged water, and diethyl ether 60 ml were charged. After equipping with stirring blade, thermometer, and condenser, it was reacted at 21-23° C. for 24 hours. After the reaction, the contents of the flask were put into a 200 ml separatory funnel, the aqueous layer was removed, and the ether layer was washed 3 times by 40 ml of ion-exchanged water.

The ether layer was put in a 200 ml Erlenmeyer flask, anhydrous sodium sulfate was added to dehydrate, and anhydrous sodium sulfate was filtrated off. The ether layer was condensed by evaporator, and dried until it became to a constant weight by a vacuum pump at 80-85° C. 1.53 g Compound I was obtained.

Compound I ¹H-NMR (270 MHz, CD₃OD)

δ 3.660 (2H, m), 3.520 (6H, m), 2.064 (2H, m), 1.748(10H, m) 1.296 (10H, m), 0.867 (3H, m)

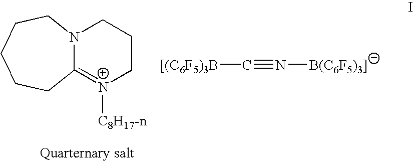

### EXAMPLE 24 (SYNTHESIS OF COMPOUND K)

Inside of a 200 ml four-necked flask was replaced with nitrogen, 0.318 g of 1,1′-di-2-ethylhexyl-4,4′-bipyridinium diiodide, 1.144 g potassium salt obtained by Synthetic Example 12 of Compound G, 20 ml of ion-exchanged water, and 60 ml of diethyl ether were charged. After equipping with stirring blade, thermometer, and condenser, it was reacted at 21-23° C. for 18 hours. After the reaction, the contents of the flask were put into a 200 ml separatory funnel, 50 ml of ethyl acetate was added to it, and the aqueous layer was removed. Next, the organic layer was washed 3 times by 30 ml of ion-exchanged water. The organic layer was put in a 200 ml Erlenmeyer flask, anhydrous sodium sulfate was added to dehydrate, and anhydrous sodium sulfate was filtrated off. The organic layer was condensed by evaporator, and dried until it became to a constant weight by a vacuum pump at 80-85° C. 1.18 g Compound K was obtained.

¹H-NMR (270 MHz, DMSO-d₆)

δ 9.385 (4H, d), 8.805 (4H, d), 4.634 (4H, m), 2.073(2H, m) 1.300 (16H, m), 0.870 (12H, m)

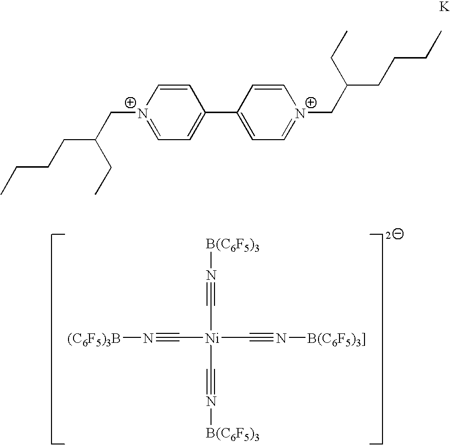

### EXAMPLE 25 (SYNTHESIS OF COMPOUND L)

Inside of a 200 ml four-necked flask was replaced with nitrogen, 0.205 g of 1,1′-dibenzyl-4,4′-bipyridinium dichloride, 1.089 g of Compound A, 20 ml of ion-exchanged water, and 60 ml of diethyl ether were charged. After equipping with stirring blade, thermometer, and condenser, it was reacted at 21-23° C. for 18 hours. After the reaction, the contents of the flask were put into a 200 ml separatory funnel, and the aqueous layer was removed. Next, the ether layer was washed 3 times by 30 ml of ion-exchanged water. The ether layer was put in a 200 ml Erlenmeyer flask, anhydrous sodium sulfate was added to dehydrate, and anhydrous sodium sulfate was filtrated off. The ether layer was condensed by evaporator, and dried until it became to a constant weight by a vacuum pump at 80-85° C. 1.21 g Compound L was obtained.

¹H-NMR (270 MHz, DMSO-d₆)

δ 9.501 (4H, d), 8.733 (4H, d), 7.606 (4H, m), 7.479 (6H, m)

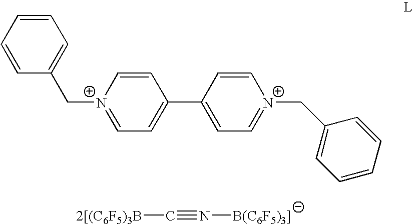

### EXAMPLE 26 (SYNTHESIS OF Compound M)

Inside of a 200 ml four-necked flask was replaced with nitrogen, 0.595 g of tri(4-t-butylphenylsulfonium)trifluoromethane sulfonate, 1.144 g of potassium salt obtained by Synthetic Example 12 of Compound G, 20 ml of ion-exchanged water, and 60 ml of diethyl ether were charged. After equipping with stirring blade, thermometer, and condenser, it was reacted at 21-23° C. for 16 hours. After the reaction, the contents of the flask were put into a 200 ml separatory funnel, 50 ml of ethyl acetate was added to it, and the aqueous layer was removed. Next, the organic layer was washed 3 times by 30 ml of ion-exchanged water. The organic layer was put in a 200 ml Erlenmeyer flask, anhydrous sodium sulfate was added to dehydrate, and anhydrous sodium sulfate was filtrated off. The organic layer was condensed by evaporator, and dried until it became to a constant weight by a vacuum pump at 80-85° C. 1.24 g compound M was obtained.

¹H-NMR (300 MHz, DMSO-d₆)

δ 7.774 (12H,m), 1.313 (27H, s)

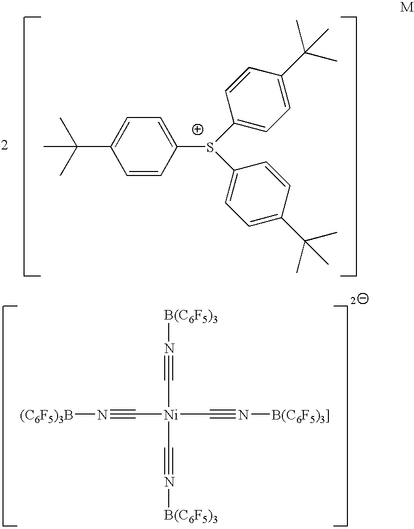

### SYNTHETIC EXAMPLE 27 (SYNTHESIS OF COMPOUND N)

Inside of a 200 ml four-necked flask was replaced with nitrogen, 1.089 g of Compound A, 20 ml of ion-exchanged water, and 50 ml of diethyl ether were charged. After equipping with stirring blade, thermometer, and condenser, 1% hydrochloric acid was added dropwise in 10 minutes with stirring. After 2 hours, the contents of the flask were put into a 200 ml separatory funnel, and the aqueous layer was removed. Next, the ether layer was washed 3 times by 30 ml of ion-exchanged water. The ether layer was put in a 200 ml Erlenmeyer flask, anhydrous sodium sulfate was added to dehydrate, and anhydrous sodium sulfate was filtrated off. The organic layer was condensed by evaporator, and dried until it became to a constant weight by a vacuum pump at 80-85° C. 1.06 g Compound N was obtained.

¹⁹F-NMR (300 MHz, DMSO-d₆)

δ −132.7, −133.7, −134.3, −154.8, −157.8, −159.2, −161.0, −162.9, −164.3, −165.4, −165.8, −166.5 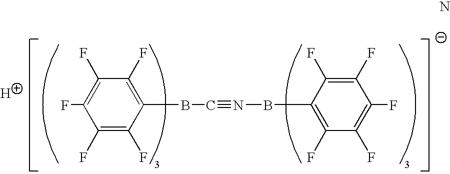
<Preparation 1 of Light-Emitting Polymer Solution Composition>

25:75 (weight ratio) mixture of Light-emitting Polymer 1 and Light-emitting Polymer 2 was dissolved in a mixed solvent of toluene/ethyl acetate=80/20 (weight ratio) in an amount to be 0.9 wt %, and further an ion pair was mixed in an amount as shown in Table 1 and dissolved. Then, it was filtrated through Teflon (registered trademark) filter having 0.2μ diameter and a coating solution was prepared. As the ion pair, those of Synthetic Examples were used. Adding amount of the ion pair is shown as the weight part to 100 parts by weight of the whole light-emitting polymer.

<Preparation of a Device, and Evaluation>

On a glass substrate on which ITO film was formed in a thickness of 150 nm by sputtering method, a film was formed by a thickness of 70 nm with a spin coat using a solution (Bayer Co., Baytron) of poly(ethylenedioxythiophene)/polystyrene sulfonic acid, and then it was dried at 200° C. for 10 minutes on a hot plate. Next, a film of about 85 nm thicknes was formed by spin-coating at a rotational rate of 1000 rpm, using the prepared coating solution of light-emitting polymer.

Furthermore, after drying this at 90° C. under reduced pressure for 1 hour, a polymer LED was fabricated, by depositing 1 nm of LiF as the cathode buffer layer, 5 nm of calcium as the cathode, and subsequently, 100 nm of aluminum. Here, all of the vacuum degree at the time of deposition were 1 to 9×10⁻⁵ Torr.

By applying a voltage to the resultant device, EL luminescence from a light emitting polymer was observed. Characteristics of the resultant device are shown in Table 1.

As the life-time test, luminance was measured about device having a 2 mm×2 mm (area 4 mm²) light-emitting part, with conducting a 10 mA constant current driving.

2000 cd/m² conversion life time is defined as that converted to a life time at the time of the initial luminance of 2000 cd/m² driving, with assuming the relation of half life-time∝(initial luminance)⁻¹. (Organic EL Material and Display, published by CMC (2001), page 107).

As for the devices of Evaluation Examples 1-12 which were prepared by using the light-emitting polymer solution compositions containing ion pair, remarkable improvement of life-time was observed, compared with the devices of Comparative Evaluation Example 1 which was prepared using a light-emitting polymer solution composition not containing an ion pair.

TABLE 1

| | | | Initial | | |
|---|---|---|---|---|---|
| | | Adding | luminance | Half life- | |
| | | amount | at 10 mA | time at 10 mA | 2000 cd/m² |
| | | (per resin | driving | driving | conversion life |
| | Kind | weight %) | (cd/m²) | (hr) | time (hr) |
| Evaluation | Compound A | 0.1 | 2200 | 1.9 | 2.1 |
| Example 1 | | | | | |
| Evaluation | Compound B | 0.1 | 2960 | 1.8 | 2.7 |
| Example 2 | | | | | |
| Evaluation | Compound B | 0.2 | 1821 | 2.4 | 2.2 |
| Example 3 | | | | | |
| Evaluation | Compound C | 0.1 | 2240 | 1.4 | 1.6 |
| Example 4 | | | | | |
| Evaluation | Compound D | 0.1 | 2620 | 1.1 | 1.4 |
| Example 5 | | | | | |
| Evaluation | Compound E | 0.1 | 2750 | 2.3 | 3.2 |
| Example 6 | | | | | |
| Evaluation | Compound F | 0.1 | 2890 | 1.5 | 2.2 |
| Example 7 | | | | | |
| Evaluation | Compound G | 0.1 | 2100 | 1.9 | 2.0 |
| Example 8 | | | | | |
| Evaluation | Compound H | 0.2 | 1640 | 4.8 | 3.9 |
| Example 9 | | | | | |
| Evaluation | Compound I | 0.2 | 1690 | 1.8 | 1.5 |
| Example 10 | | | | | |
| Evaluation | Compound K | 0.1 | 1990 | 3.1 | 3.1 |
| Example 11 | | | | | |
| Evaluation | Compound L | 0.1 | 1790 | 2.9 | 2.6 |
| Example 12 | | | | | |
| Comparative | — | 0 | 2760 | 0.85 | 1.2 |
| Evaluation | | | | | |
| Example 1 | | | | | |

<Preparation 2 of Light-Emitting Polymer Solution Composition>

70:30 (weight ratio) mixture of Light-emitting Polymer 3 and Light-emitting Polymer 4 was dissolved in a mixed solvent of toluene/ethyl acetate=80/20 (weight ratio) in an amount to be 1.2 wt %, and further an ion pair was mixed in an amount as shown in Table 2 and dissolved. Then, it was filtrated through Teflon (registered trademark) filter having 0.2μ diameter and a coating solution was prepared. As the ion pair, those of Synthetic Examples were used. Adding amount of the ion pair is shown as the weight part to 100 parts by weight of the whole light-emitting polymer.

<Preparation of a Device, and Evaluation>

On a glass substrate on which ITO film was formed in a thickness of 150 nm by sputtering method, a film was formed by a thickness of 70 nm with a spin coat using a solution (Bayer Co., Baytron) of poly(ethylenedioxythiophene)/polystyrene sulfonic acid, and then it was dried at 200° C. for 10 minutes on a hot plate. Next, a film of about 85 nm thicknes was formed by spin-coating at a rotational rate of 1000 rpm, using the prepared coating solution of light-emitting polymer.

Furthermore, after drying this at 90° C. under reduced pressure for 1 hour, a polymer LED was fabricated, by depositing 1 nm of LiF as the cathode buffer layer, 5 nm of calcium as the cathode, and subsequently, 100 nm of aluminum. Here, all of the vacuum degree at the time of deposition were 1 to 9×10⁻⁵ Torr.

By applying a voltage to the resultant device, EL luminescence from a light emitting polymer was observed. Characteristics of the resultant device are shown in Table 1.

As the life-time test, luminance was measured about device having a 2 mm×2 mm (area 4 mm²) light-emitting part, with conducting a 10 mA constant current driving.

5000 cd/m² conversion life time is defined as that converted to a life time at the time of the initial luminance of 5000 cd/m² driving, with assuming the relation of half life-time∝(initial luminance)⁻¹. (Organic EL Material and Display, published by CMC (2001), page 107).

As for the devices of Evaluation Examples 13-16 which were prepared by using the light-emitting polymer solution compositions containing ion pair, remarkable improvement of life-time was observed, compared with the device of Comparative Evaluation Example 2 which was prepared using a light-emitting polymer solution composition not containing an ion pair.

TABLE 2

| | | | Initial | Half life | |
|---|---|---|---|---|---|
| | | Adding | luminance | time at | |
| | | amount | at 10 mA | 10 mA | 5000 cd/m² |
| | | (per resin | driving | driving | conversion |
| | Kind | weight %) | (cd/m2) | (hr) | life time (hr) |
| Evaluation | Com- | 0.1 | 5830 | 6.5 | 7.6 |
| Example 13 | pound E | | | | |
| Evaluation | Com- | 0.2 | 4730 | 10 | 9.5 |
| Example 14 | pound E | | | | |
| Evaluation | Com- | 0.1 | 6260 | 2.4 | 3.0 |
| Example 15 | pound M | | | | |
| Evaluation | Com- | 0.1 | 4420 | 5.5 | 4.9 |
| Example 16 | pound N | | | | |
| Comparative | | 0 | 6070 | 1.5 | 1.8 |
| Evaluation | | | | | |
| Example 2 | | | | | |

### SYNTHETIC EXAMPLE 28

<Synthesis of Light-Emitting Polymer 5>

2,7-dibromo-9,9-dioctylfluorene (26 g, 0.047 mol), 2,7-dibromo-9,9-diisopentylfluorene (5.6 g, 0.012 mol), and 2,2′-bipyridyl (22 g, 0.141 mol) were dissolved in dehydrated tetrahydrofuran 1600 mL, and the inside of the system was replaced by nitrogen bubbling. Under nitrogen atmosphere, to this solution, bis(1,5-cyclooctadiene)Ni(0){Ni(COD)₂} (40 g, 0.15 mol) was added, and the temperature was raised to 60° C., and reacted for 8 hours. After the reaction, the reaction mixture was cooled to room temperature (about 25° C.), added dropwise into a mixed solution of 25% aqueous ammonia 200 ml/methanol 1200 ml/ion-exchanged water 1200 ml, and stirred for about 30 minutes. The deposited precipitate was filtrated, and air-dried. After being dissolved in toluene 1100 mL, it was filtrated, and the filtrated solution was added dropwise in methanol 3300 mL, and was stirred for 30 minutes. The deposited precipitate was filtrated and washed by methanol 1000 mL, then dried under reduced-pressure for 5 hours. The yield of a resultant Light-emitting Polymer 5 was 20 g. The polystyrene reduced number average molecular weight and weight average molecular weight of Light-emitting Polymer 1 were Mn=4.6×10⁴ and Mw=1.1×10⁵, respectively, (mobile-phase: chloroform).

<Preparation of Light-Emitting Polymer Solution Composition>

Light-emitting Polymer 5 was dissolved in toluene be 1.5 wt %, and further an onium salt was mixed in an amount as shown in Table 3 and dissolved. Then, it was filtrated through Teflon (registered trademark) filter having 0.29 diameter and a coating solution was prepared. As the onium salt, Rohdorsil photoinitiator PI-2074 prepared by Rohdia were used. Adding amount of the onium salt is shown as the weight part to 100 parts by weight of the whole light-emitting polymer.

TABLE 3

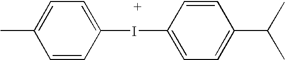

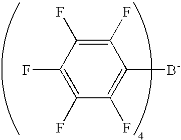

| | Adding | | Initial | Half life | |
|---|---|---|---|---|---|
| | amount | | luminance | time | 100 cd/m² |
| | of | | at 1 mA | at 1 mA | conversion |
| | onium | | driving | driving | life time |
| | salt | UV exposure | (cd/m²) | (hr) | (hr) |
| Evaluation | 0.05 | Not | 124 | 47 | 58 |
| Example 17 | | conducted | | | |
| Evaluation | 0.05 | Conducted | 223 | 24 | 54 |
| Example 18 | | | | | |
| Evaluation | 0.1 | Conducted | 93 | (78% at | >>125 |
| Example 19 | | | | 135 hr) | |
| Evaluation | 0.2 | Conducted | 70 | (93% at | >>95 |
| Example 20 | | | | 135 hr) | |
| Comparative | 0 | Not | 163 | 2.7 | 4.4 |
| Evaluation | | conducted | | | |
| Example 3 | | | | | |
| Comparative | 0 | Conducted | 256 | 2.3 | 5.9 |
| Evaluation | | | | | |
| Example 4 | | | | | |

<Preparation of a Device, and Evaluation>

On a glass substrate on which ITO film was formed in a thickness of 150 nm by sputtering method, a film was formed by a thickness of 70 nm with a spin coat using a solution (Bayer Co., Baytron) of poly(ethylenedioxythiophene)/polystyrene sulfonic acid, and then it was dried at 200° C. for 10 minutes on a hot plate. Next, a film of about 85 nm thicknes was formed by spin-coating at a rotational rate of 1400 rpm, using the prepared coating solution of light-emitting polymer.

In case of conducting UV exposure, under nitrogen atmosphere, UV exposure conducted for 10 seconds, by a high-pressure mercury lamp of 50 W/cm² illumination measured by i-line (365 nm).

Furthermore, after drying this at 90° C. under reduced pressure for 1 hour, a polymer LED was fabricated, by depositing 1 nm of LiF as the cathode buffer layer, 5 nm of calcium as the cathode, and subsequently, 100 nm of aluminum. Here, all of the vacuum degree at the time of deposition were 1 to 9×10⁻⁵ Torr.

By applying a voltage to the resultant device, EL luminescence from a light emitting polymer was observed. Characteristics of the resultant device are shown in Table 3.

As the life-time test, luminance was measured about device having a 2 mm×2 mm (area 4 mm²) light-emitting part, with conducting a 10 mA constant current driving.

100 cd/m² conversion life time is defined as that converted to a life time at the time of the initial luminance of 100 cd/m² driving, with assuming the relation of half life-time∝(initial luminance)⁻¹. (Organic EL Material and Display, published by CMC (2001), page 107).

As for the devices of Evaluation Examples 17-20 which were prepared by using the light-emitting polymer solution compositions containing ion pair, remarkable improvement of life-time was observed, compared with the devices of Comparative Evaluation Examples 3 and 4 which were prepared using a light-emitting polymer solution composition not containing an ion pair.

### SYNTHETIC EXAMPLE 29

<Synthesis of triphenylsulfonium tetrakis(pentafluoro phenyl)borate salt (TPSTB)>

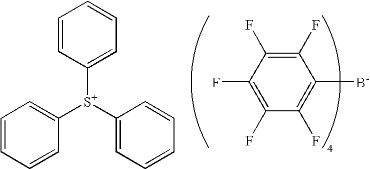

In a 100 ml three-necked flask, 0.90 g of lithium tetrakis (pentafluorophenyl)borate, and 10 ml of chloroform were mixed. Then, 10 ml aqueous solution of 0.30 g triphenyl sulfonium salt was added, and stirred for 24 hours. After removing the aqueous layer, it washed by ion-exchanged water. The chloroform solution was concentrated and dried, and recrystallized from methanol-t-butylmethyl ether, 0.80 g of white solid was obtained.

¹H-NMR (300 MHz/CDCl₃): δ (ppm) 7.50, (d, 2H) 7.70, (dd, 2H), 7.83(dd, 1H)

¹⁹F-NMR (300 MHz/CDCl₃): d (ppm)-128.85 (d, 2F), −159.28 (dd, 1F), −163.09 (dd, 2F).

### SYNTHETIC EXAMPLE 30

<Synthesis of trimethylsulfonium tetrakis(pentafluoro phenyl)borate salt (TMeSTB)>

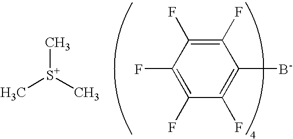

In a 100 ml three-necked flask, 0.27 g of lithium tetrakis (pentafluorophenyl)borate, and 10 ml of chloroform were mixed. Then, 10 ml aqueous solution of 0.10 g triphenyl sulfonium salt was added, and stirred for 21 hours. The deposited solid was filtrated, and washed by chloroform and water. 0.18 g of white solid was obtained.

¹H-NMR (300 MHz/DMSO-d₆) (s, 9H): δ (ppm) 2.90

¹⁹F-NMR (300 MHz/DMSO-d₆): d(ppm)-132.86 (d, 2F), −161.75 (dd, 1F), −166.41 (dd, 2F).

### SYNTHETIC EXAMPLE 31

<Synthesis of tetrabutylammonium tetrakis(pentafluoro phenyl)borate salt (N4B)>

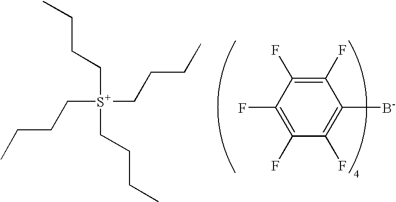

Inside of a 50 ml two-necked flask is replaced with nitrogen, 0.15 g of tetrabutylammonium chloride was dissolved in 4.4 ml water, and 0.44 g of lithium[tetrakis(pentafluorobenzene)]borate-ethyl ether complex was added. After being dissolved once, then a solid was deposited. The solid was dissolved by addition of 4.4 ml chloroform. After 5 hours stirring, it was partitioned and the aqueous phase was extracted with 5 ml chloroform twice. After drying with sodium sulfate, the solvent was distilled off, and 0.45 g of 1 was obtained.

¹H-NMR (300 MHz, CDCl₃)

δ 3.09-3.03 (8H, m), 1.62-1.51 (8H, m), 1.42-1.30 (8H, m), 0.97 (12H, t)

¹⁹F-NMR (300 MHz, CDCl₃)

δ 14.2, 10.3, −133.1

MS(ESI-positive)

m/z:242

MS(ESI-negative)

m/z:679

### EXAMPLE 32

Synthesis of 1′-diphenyl-4,4′-bipyridinium bistetrakis(pentafluorophenyl)borate

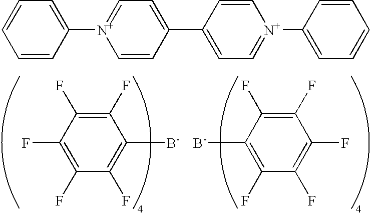

Inside of a 25 ml Schlenk tube was replaced by nitrogen, 57 mg of 1,1′-diphenyl-4,4′-bipyridinium dichloride was dissolved in 2.5 ml of water, and 250 mg of lithium[tetrakis (pentafluorobenzene)]borate-ethyl ether complex was added. 2.5 ml of chloroform was added, and it was stirred for 7 hours. It was partitioned, and the aqueous phase was filtrated and washed. The residue and the organic layer were combined and the solvent was distilled off, and then 129 mg of 1,1′-diphenyl-4,4′-bipyridinium bistetrakis(pentafluorophenyl)borate was obtained.

¹H-NMR (300 MHz, DMSO-d₆)

δ 9.71 (4H, d), 9.07 (4H, d), 7.98 (4H, d), 7.83 to 7.79 (6H, m)

¹⁹F-NMR (300 MHz, DMSO-d₆)

δ −132.8, −161.8, −166.3

### SYNTHETIC EXAMPLE 33

(Synthesis of 4-{4-(dimethylamino)Styryl}-N-methyl pyridinium tetrakis(pentafluorophenyl)borate)

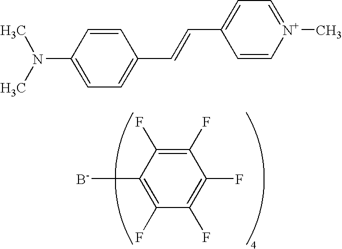

Inside of a 25 ml Schlenk tube was replaced by nitrogen, 113 mg of 4-(4-(Dimethylamino)styryl)-N-methylpyridinium iodide was suspended in 2.5 ml water, and 250 mg of lithium[tetrakis (pentafluorobenzene)]borate was added. 2.5 ml of chloroform was added, and it was stirred for 7 hours. It was partitioned, and the aqueous phase was filtrated and washed. The residue and the organic layer were combined together and the solvent was distilled off, and then 91 mg of 4-{4-(dimethylamino)styryl}-N-methylpyridinium tetrakis(pentafluorophenyl)borate was obtained.

¹H-NMR (300 MHz, DMSO-d₆)

δ 8.69 (2H, d), 8.05 (2H, d), 7.91 (1H, d), 7.60 (2H, d), 7.17 (1H, d), 6.79 (2H, d), 4.18 (3H, s), 3.03 (6H, s)

¹⁹F-NMR (300 MHz, DMSO-d₆)

δ −132.8, −161.8, −166.3

### SYNTHETIC EXAMPLE 34

(Synthesis of transformer-4-{2-(1-ferrocenyl)vinyl}-1-methylpyridinium tetrakis(pentafluorophenyl)borate)

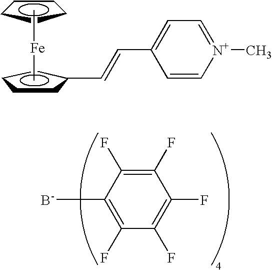

Inside of a 25 ml Schlenk tube was replaced by nitrogen, 130 mg of trans-4-[2-(1-Ferrocenyl)vinyl]-1-methylpyridinium iodide was suspended in 2.5 ml water, and 250 mg of lithium[tetrakis(pentafluorobenzene)]borate was added. 2.5 ml of chloroform was added, and it was stirred for 7 hours. It was partitioned, and the aqueous phase was filtrated and washed. The residue and the organic layer were combined together and the solvent was distilled off, and then 167 mg of trans-4-{2-(1-ferrocenyl)vinyl}-1-methypyridinium tetrakis pentafluorophenyl borate was obtained.

¹H-NMR (300 MHz, DMSO-d₆)

δ 8.73 (2H, d), 8.06 (2H, d), 7.89 (1H, d), 6.97 (2H, d), 4.75 (2H, s), 4.60 (2H, s), 4.23 (5H, s), 4.19 (3H, s)

¹⁹F-NMR (300 MHz, DMSO-d₆)

δ−132.6, −161.8, −166.1

### SYNTHETIC EXAMPLE 35

<Synthesis of tetradodecylammonium tetrakis(pentafluorophenyl)borate>

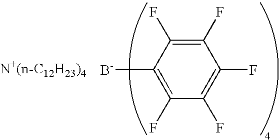

Inside of a 25 ml Schlenk tube was replaced by nitrogen, 225 mg of tetradodecylammonium chloride was dissolved in 2.5 ml water, and 250 mg of lithium[tetrakis(pentafluorobenzene)]borate was added. 2.5 ml of chloroform was added, and it was stirred for 7 hours. It was partitioned, and the aqueous phase was filtrated and extracted with chloroform, and then the solvent was distilled off. 407 mg of tetradodecylammonium tetrakis(pentafluorophenyl)borate was obtained.

¹H-NMR (300 MHz, CDCl₃)

δ 3.02 (8H, br), 1.56 (8H, br), 1.29 to 1.23 (44H, m), 0.87 (12H, t)

¹⁹F-NMR (300 MHz, CDCl₃)

δ −132.2, −162.5, −166.5

<Preparation of Light-Emitting Polymer Solution Composition>

Light-emitting Polymer 5 was dissolved in toluene in an amount to be 1.5 wt %, and further a metal salt or an onium, as additives, was mixed in an amount as shown in Table 4 and dissolved. Then, it was filtrated through Teflon (registered trademark) filter having 0.2μ diameter and a coating solution was prepared. As the metal salt or the onium, those of Synthetic Examples and commercially available reagents shown below were used. Adding amount of the metal salt or the onium is shown as the weight part to 100 parts by weight of the whole light-emitting polymer.

LiB: Lithium tetrakis(pentafluorophenyl)borate-ethylether complex (product by Tokyo-Kasei)

AB: N,N-dimethylanilinium tetrakis(pentafluorophenyl)borate (product by STREM CHEMICALS)

TB: Trityl tetrakis(pentafluorophenyl)borate (Product by STREM CHEMICALS)

TABLE 4

| | | | | Initial | Half life | 100 |
|---|---|---|---|---|---|---|
| | | | | luminance | time at | cd/m² |
| | | Adding amount | | at 10 mA | 10 mA | conversion |
| | | (per resin | | driving | driving | life time |
| | Kind | weight %) | UV exposure | (cd/m²) | (hr) | (hr) |
| Evaluation | TPSTB | 0.2 | not | 44 | 29 | 12.8 |
| Example 21 | | | conducted | | | |
| Evaluation | TPSTB | 0.2 | conducted | 55 | 15 | 8.3 |
| Example 22 | | | | | | |
| Evaluation | TMeSTB | 0.2 | not | 23 | 112 | 25.8 |
| Example 23 | | | conducted | | | |
| Evaluation | N4B | 0.2 | not | 38 | 10 | 3.8 |
| Example 24 | | | conducted | | | |
| Evaluation | LiB | 0.2 | not | 63 | 65 | 41.0 |
| Example 25 | | | conducted | | | |
| Evaluation | AB | 0.2 | conducted | 49 | 54 | 26.5 |
| Example 26 | | | | | | |
| Evaluation | TB | 0.2 | conducted | 34 | 85 | 28.9 |
| Example 27 | | | | | | |
| Evaluation | PI2074 | 0.2 | not | 54 | 70 | 37.8 |
| Example 28 | | | conducted | | | |
| Evaluation | PI2074 | 0.2 | conducted | 48 | 29 | 13.9 |
| Example 29 | | | | | | |
| Comparative | — | 0 | not | 85 | 1.5 | 1.3 |
| Evaluation | | | conducted | | | |
| Example 5 | | | | | | |
| Comparative | — | 0 | [symbol] | 113 | 1.3 | 1.5 |
| Evaluation | | | | | | |
| Example 6 | | | | | | |

<Preparation of a Device, and Evaluation>

On a glass substrate on which ITO film was formed in a thickness of 150 nm by sputtering method, a film was formed by a thickness of 50 nm with a spin coat using a solution (Bayer Co., Baytron) of poly(ethylenedioxythiophene)/polystyrene sulfonic acid, and then it was dried at 200° C. for 10 minutes on a hot plate. Next, a film of about 85 nm thicknes was formed by spin-coating at a rotational rate of 1400 rpm, using the prepared coating solution of light-emitting polymer.

In case of conducting UV exposure, under nitrogen atmosphere, UV exposure conducted for 10 seconds, by a high-pressure mercury lamp of 50 W/cm² illumination measured by i-line (365 nm).

Furthermore, after drying this at 90° C. under reduced pressure for 1 hour, a polymer LED was fabricated, by depositing 1 nm of LiF as the cathode buffer layer, 5 nm of calcium as the cathode, and subsequently, 100 nm of aluminum. Here, all of the vacuum degree at the time of deposition were 1 to 9×10⁻⁵ Torr.

By applying a voltage to the resultant device, EL luminescence from a light emitting polymer was observed. Characteristics of the resultant device are shown in Table 3.

As the life-time test, luminance was measured about device having a 2 mm×2 mm (area 4 mm²) light-emitting part, with conducting a 10 mA constant current driving.

100 cd/m² conversion life time is defined as that converted to a life time at the time of the initial luminance of 100 cd/m² driving, with assuming the relation of half life-time∝(initial luminance)⁻¹. (Organic EL Material and Display, published by CMC (2001), page 107).

As for the devices of Evaluation Examples 21-29 which were prepared by using the light-emitting polymer solution compositions containing ion pair, remarkable improvement of life-time was observed, compared with the devices of Comparative Evaluation Examples 5 and 6 which were prepared using a light-emitting polymer solution composition not containing an ion pair.

### SYNTHETIC EXAMPLE 36

(Synthesis of tri(4-t-butylphenylsulfonium)tetrakis (pentafluorophenyl)borate salt (TTBPSTB))

Inside of a 200 ml four-necked flask was replaced with nitrogen, 0.581 g of tri(4-t-butylphenylsulfonium)trifluoromethane sulfonate, and 0.834 g of lithium tetrakis(pentafluorophenyl)borate-ethyl ether complex, 20 ml of ion-exchanged water, and 60 ml of diethyl ether were charged. After equipping with stirring blade, thermometer, and condenser, it was reacted at 21-23° C. for 16 hours. After the reaction, the contents of the flask were put into a 200 ml separatory funnel, and the aqueous layer was removed. Next, the ether layer was washed 3 times by 30 ml of ion-exchanged water. The ether layer was put in a 200 ml Erlenmeyer flask, anhydrous sodium sulfate was added to dehydrate, and anhydrous sodium sulfate was filtrated off. The ether layer was condensed by evaporator at room temperature, and dried until it became to a constant weight by a vacuum pump at 70-75° C. 1.04 g of a compound (TTBPSTB) was obtained.

¹H-NMR (270 MHz, DMSO-D₆)

δ 7.78 (12H,m), 1.31 (27H, s) 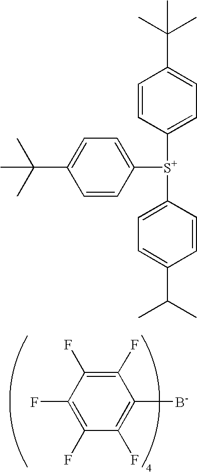
<Preparation of Light-Emitting Polymer Solution Composition>

70:30 (weight ratio) mixture of Light-emitting Polymer 3 and Light-emitting Polymer 4 was dissolved in a mixed solvent of toluene/ethyl acetate=80/20 (weight ratio) in an amount to be 1.2 wt %, and further an ion pair was mixed in an amount as shown in Table 5 and dissolved. Then, it was filtrated through Teflon (registered trademark) filter having 0.2μ diameter and a coating solution was prepared. As the ion pair, those of Synthetic Examples were used. Adding amount of the ion pair is shown as the weight part to 100 parts by weight of the whole light-emitting polymer.

<Preparation of a Device, and Evaluation>

On a glass substrate on which ITO film was formed in a thickness of 150 nm by sputtering method, a film was formed by a thickness of 50 nm with a spin coat using a solution (Bayer Co., Baytron) of poly(ethylenedioxythiophene)/polystyrene sulfonic acid, and then it was dried at 200° C. for 10 minutes on a hot plate. Next, a film of about 85 nm thicknes was formed by spin-coating at a rotational rate of 1000 rpm, using the prepared coating solution of light-emitting polymer.

Furthermore, after drying this at 90 under reduced pressure for 1 hour, a polymer LED was fabricated, by depositing 1 nm of LiF as the cathode buffer layer, 5 nm of calcium as the cathode, and subsequently, 100 nm of aluminum. Here, all of the vacuum degree at the time of deposition were 1 to 9×10⁻⁵ Torr.

By applying a voltage to the resultant device, EL luminescence from a light emitting polymer was observed. Characteristics of the resultant device are shown in Table 3.

As the life-time test, luminance was measured about device having a 2 mm×2 mm (area 4 mm²) light-emitting part, with conducting a 10 mA constant current driving.

5000 cd/m² conversion life time is defined as that converted to a life time at the time of the initial luminance of 5000 cd/m² driving, with assuming the relation of half life-time∝(initial luminance)⁻¹. (Organic EL Material and Display, published by CMC (2001), page 107).

As for the devices of Evaluation Example 30 which was prepared by using the light-emitting polymer solution compositions containing ion pair, remarkable improvement of life-time was observed, compared with the devices of Comparative Evaluation Example 7 which was prepared using a light-emitting polymer solution composition not containing an ion pair.

TABLE 5

| | | | Initial | | |
|---|---|---|---|---|---|
| | | | lumi- | Half | |
| | | | nance | reduction | |
| | | Adding | at | time at | 5000 cd/m² |
| | | amount | 10 mA | 10 mA | conversion |
| | | (weight % | driving | driving | life |
| | Kind | per resin) | (cd/m²) | (hr) | time (hr) |
| Evaluation | TTBPSTB | 0.2 | 3210 | 9 | 5.8 |
| Example 30 | | | | | |
| Comparative | — | 0 | 6070 | 1.5 | 1.8 |
| Evaluation | | | | | |
| Example 7 | | | | | |

Life time of a light-emitting device can be lengthened by using a light emitting layer containing the light-emitting polymer composition of the present invention. Therefore, the polymer LED which used the light-emitting polymer composition of the present invention can be preferably used for apparatus, such as a curved or flat light source for a liquid crystal display as a back light, a segment type display, a dot matrix flat-panel display, etc.

1. A light-emitting polymer composition comprising a light-emitting polymer and an ion pair, and the negative ion of the ion pair is represented by below formula (1a), (1b), (2) or (3), 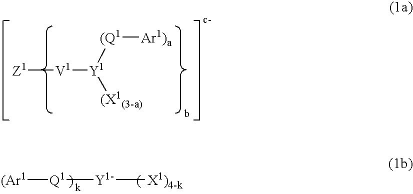
(wherein, Y¹ represents a group 13 atom; Ar¹ represents an aryl group having an electron-withdrawing group, or a monovalent heterocyclic group having an electron-withdrawing group; Q¹ represents an oxygen atom or a direct bond; X¹ represent a halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, substituted silyloxy group, substituted silylthio group, substituted silylamino group, substituted amino group, amide group, acid imide group, acyloxy group, monovalent heterocyclic group, heteroaryloxy group, heteroarylthio group, cyano group, or nitro group; a represents an integer of 1-3, k represents an integer of 1-4, V¹ represents a group 16 atom, divalent aliphatic hydrocarbon group, divalent aromatic hydrocarbon group, bidentate heterocyclic group, —C≡N—, —N═N═N—, or a direct bond; b represents an integer of 2-6; and Z¹ represents -M′(=O)p- (wherein, M′ represents an atom of group 3, group 4, group 5, group 6, group 7, group 8, group 9, group 10, group 11, group 12, group 13, group 14, group 15, group 16, or group 17; and p represents an integer of 0-2), or Z¹ represents a b-valent aliphatic hydrocarbon group, a b-valent aromatic hydrocarbon group, a bidentate heterocyclic group, —C≡N—, —N═N═N—, —NH—, —NH₂—, —OH—, or a direct bond. However, b=2 when Z¹ is —C≡N—, —N═N═N—, —NH—, —NH₂—, or —OH—; Z¹ and V¹ are different from each other, and when Q¹ and Ar¹ exist in plural, they may be the same or different from each other; a plurality of V¹ is may be the same or different; and c represents an integer of 1-6), 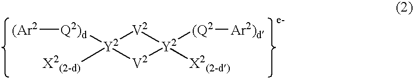
(wherein, Y² represents a group 13 atom; Ar² represents
an aryl group having an electron-withdrawing group, or a monovalent heterocyclic group having an electron-withdrawing group; Q² represents an oxygen atom or a direct bond; X² represent a halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, substituted silyl oxy group, substituted silylthio group, substituted silylamino group, substituted amino group, amide group, acid imide group, acyloxy group, monovalent heterocyclic group, heteroaryloxy group, heteroarylthio group, cyano group, or nitro group; d and d′ each independently represent 1 or 2; V² represents a group 16 atom, divalent aliphatic hydrocarbon group, divalent aromatic hydrocarbon group, bidentate heterocyclic group, —C≡N— or —N═N—; a plurality of Y², Ar², Q² and V² may be the same or different; when X² exists in plural, they may be the same or different; and e represents an integer of 1-6), 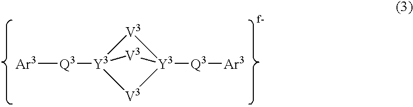
(wherein, Y³ represents a group 13 atom; Ar³ represents an aryl group having an electron-withdrawing group, or a monovalent heterocyclic group having an electron-withdrawing group; Q³ represents an oxygen atom or a direct bond; V³ represents a group 16 atom, divalent aliphatic hydrocarbon group, divalent aromatic hydrocarbon group, bidentate heterocyclic group, —C≡N—, or —N═N—; a plurality of Y³, Ar³, Q³ and V³ espectively may be the same or different; and f represents an integer of 1-6).

2. A light-emitting polymer composition according to claim 1, wherein, Ar¹ in the above formula (1a) and (1b), Ar² in the above formula (2), and Ar³ in the above formula (3) are perfluoroaryl groups.

3. A light-emitting polymer composition according to claim 1, wherein a is 2 or 3 in the above formula (1a).

4. A light-emitting polymer composition according to claim 1, wherein k is 3 or more in the above formula (1b).

5. A light-emitting polymer composition according to claim 1, wherein the above formula (1b) is the below formula (6),
[B(Ar⁴)₄]⁻ (6)
(wherein, Ar⁴ represents a phenyl group substituted with 2
or more of those selected from fluorine and trifluoromethyl group; and Ar⁴ may be mutually the same or different).

6. A light-emitting polymer composition according to claim 1, wherein, in the above formula (1a), Z¹ or V¹ is —C≡N—.

7. A light-emitting polymer composition according to claim 1, wherein the negative ion of the above formula (1a) is represented by the below formula (5-1) or (5-2),
[(C₆F₅)₃B—C≡N—B(C₆F₅)₃]⁻ (5-1)
[M{C≡N—B(C₆F₅)₃}₄]²⁻ (5-2)
(wherein, M represents a nickel atom or a palladium atom).

8. A light-emitting polymer composition according to claim 1, wherein the positive ion of the ion pair is a hydrogen ion, a metal cation, or carbocation; or an onium of the element selected from a nitrogen atom, an oxygen atom, a phosphorus atom, a sulfur atom, a chlorine atom, a selenium atom, a bromine atom, a tellurium atom, and an iodine atom.

9. A light-emitting polymer composition according to claim 8, wherein the onium of nitrogen atom is a divalent onium represented by the below formula (10), 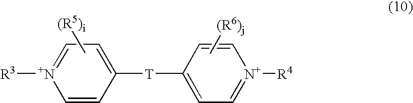
(wherein, R³ and R⁴ each independently represent an alkyl group, alkyloxy group, aryl group, aryloxy group, arylalkyl group, arylalkyloxy group, acyl group, acyloxy group, monovalent heterocyclic group, or hetero aryloxy group; R⁵ and R⁶ each independently represent a halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, substituted silyloxy group, substituted silylthio group, substituted silylamino group, substituted amino group, amide group, acidimide group, acyloxy group, monovalent heterocyclic group, hetero aryloxy group, hetero arylthio group, acyl group, imine residue, substituted silyl group, alkyloxy carbonyl group, aryloxy carbonyl group, arylalkyloxy carbonyl group, heteroaryloxy carbonyl group, carboxyl group, cyano group, or nitro group; T represents a direct bond, divalent aliphatic hydrocarbon group, divalent aromatic hydrocarbon group, alkenylene group, ethynylene group, or a divalent heterocyclic group; i and j each independently represent an integer of 0 to 4; when two or more R⁵ and R⁶ respectively exist, they may be the same or different).

10. A light-emitting polymer composition according to claim 1, wherein the light-emitting polymer comprises the repeating unit represented by the below formula (4), 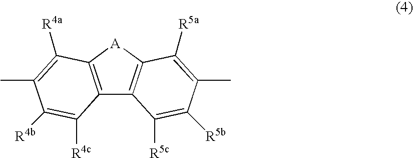
(wherein, A represents an atom or an atomic group for forming the 5 membered ring or 6 membered ring together with 4 carbon atoms on two benzene rings of the formula; R^{4a}, R^{4b}, R^{4c}, R^{5a}, R^{5b}, and R^{5c} each independently represent a hydrogen atom, a halogen atom, alkyl group, alkyloxy group, alkylthio group, aryl group, aryloxy group, arylthio group, arylalkyl group, arylalkyloxy group, arylalkylthio group, alkenyl group, alkynyl group, arylalkenyl group, arylalkynyl group, acyl group, acyloxy group, amide group, acidimide group, imine residue, substituted amino group, substituted silyl group, substituted silyloxy group, substituted silylthio group, substituted silylamino group, cyano group, nitro group, monovalent heterocyclic group, heteroaryloxy group, hetero arylthio group, alkyloxy carbonyl group, aryloxy carbonyl group, arylalkyloxy carbonyl group, heteroaryloxy carbonyl group, or carboxyl group; R^{4b} and R^{4c}, and R^{5b} and R^{5c} may respectively form a ring, together.).

11. A light-emitting polymer composition according to claim 1, wherein the content of the ion pair is 0.001-10 parts by weight based on 100 parts by weight of the light-emitting polymer.

12. A light-emitting polymer solution composition wherein the light-emitting polymer composition according to claim 1 further contains a solvent.

13. A polymer light-emitting device comprising a light emitting layer between the electrodes consisting of an anode and a cathode, wherein the light emitting layer contains the light-emitting polymer composition according to claim 1.

14. A polymer light-emitting device comprising a light emitting layer between the electrodes consisting of an anode and a cathode, wherein the light emitting layer is formed using the light-emitting polymer solution composition of claim 12.

15. A polymer light-emitting device according to claim 13, wherein the device is manufactured by being heat-treated at the temperature of 50° C. or more, after forming the light emitting layer.

16. An ion pair wherein the negative ion is represented by the below formula (5-1), and the positive ion is a pyridinium cation, phosphonium cation, or iodonium cation,
[(C₆F₅)₃B—C≡N—B(C₆F₅)₃]⁻ (5-1)

17. An ion pair wherein the negative ion is represented by the below formula (5-2), and the positive ion is a pyridinium cation, quarternary ammonium cation, a phosphonium cation, oxonium cation, sulfonium cation, or iodonium cation.
[M{C≡N—B(C₆F₅)₃}₄]²⁻ (5-2)
(wherein, M represents a nickel atom or a palladium atom.).

18. An ion pair represented by the below formula (12), 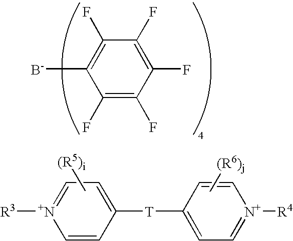
(wherein, R³, R⁴, R⁵, R⁶, and T represent the same meaning as the above.)
